(19) United States
(12) Patent Application Publication
(10) Pub. No.: US 2026/0101625 A1
(43) Pub. Date: Apr. 9, 2026

(54) PEROVSKITE SOLAR CELL AND ITS PREPARATION

(71) Applicant: City University of Hong Kong, Kowloon (HK)

(72) Inventors: Zonglong Zhu, Kowloon (HK); Danpeng Gao, Kowloon (HK); Bo Li, Kowloon (HK)

(21) Appl. No.: 19/219,029

(22) Filed: May 27, 2025

Related U.S. Application Data
(60) Provisional application No. 63/704,652, filed on Oct. 8, 2024.

(51) Int. Cl. H10K 30/85; C23C 16/44; C23C 16/455; H10K 30/50; H10K 30/82; H10K 30/88; H10K 71/12; H10K 71/40; H10K 85/50

(52) U.S. Cl. CPC H10K 30/85; C23C 16/4408; C23C 16/45527; C23C 16/45557; H10K 30/50; H10K 30/82; H10K 30/88; H10K 71/12; H10K 71/40; H10K 85/50

(57) ABSTRACT

A perovskite solar cell includes an electron transport layer between an anode and a cathode, wherein the electron transport layer comprises of first and second portions of tin oxide (SnOₓ). A method for preparing the perovskite solar cell includes depositing an electron transport layer having first and second portions of tin oxide (SnOₓ) on a surface passivated perovskite active layer.

### TECHNICAL FIELD

The present invention relates to a perovskite solar cell, for example, particularly, but not exclusively, a perovskite solar cell comprising an electron transport layer comprising of first and second portions of tin oxide (SnOₓ). The present invention also relates to the preparation of the perovskite solar cell.

### BACKGROUND OF THE INVENTION

It is believed that the power conversion efficiency (PCE) of perovskite solar cells (PSCs) has surpassed many traditional thin-film solar technologies. However, typical PSCs include fragile interfaces, rendering them challenges, particularly in achieving long-term stability. Some contact points may even degrade under various environmental stresses such as humidity, oxygen, temperature changes, and light exposure, leading to a decline in cell performance and lifespan.

In inverted p-i-n PSCs, it is believed that fullerene electron transport layers (ETLs) are commonly used and that the perovskite/electron transport layer (ETL) interface significantly causes efficiency loss, forming deep trap states. The high cost and poor mechanical properties associated with fullerene ETLs have driven the search for alternatives.

One possible solution may be replacing fullerenes with metal oxides. However, high-temperature requirement for depositing metal oxides on perovskite, particularly hybrid perovskite, can be problematic due to the thermal sensitivity of the perovskite. Although sputtering the metal oxides on or direct atomic layer deposition (ALD) of the metal oxides on the perovskite are the alternative option for replacing fullerenes with metal oxides, it is believed that the former could damage the perovskite surface whereas the latter could result in chemical reactions and interface barriers, leading to device PCEs below 1%.

The present invention thus seeks to eliminate or at least mitigate such shortcomings by providing a new or otherwise improved perovskite solar cell (PSC) such as a new or otherwise improved inverted PSC.

### SUMMARY OF THE INVENTION

In a first aspect of the present invention, there is provided a perovskite solar cell comprising an electron transport layer between an anode and a cathode, wherein the electron transport layer comprises of first and second portions of tin oxide (SnOₓ).

In an optional embodiment, the first and the second portions of tin oxide (SnOₓ) have different stoichiometry.

Optionally, the x of SnOₓ in the first and second portions is from about 1.81 to 1.98.

It is optional that the first portion of tin oxide is arranged on the second portion of tin oxide.

In an optional embodiment, the first and second portions of tin oxide have different thickness.

Optionally, the thickness of the first and second portions of tin oxide is in the range from about 2 nm to about 50 nm.

In an option embodiment, the thickness of the first portion of tin oxide is less than that of the second portion.

In an optional embodiment, x of SnOₓ in the first portion is smaller than that of the second portion.

It is optional that x of SnOₓ in the first portion is about 1.83 and x of SnOₓ in the second portion is about 1.96.

Optionally, the thickness of the first portion is about 2 nm to about 10 nm and the thickness of the second portion is about 15 nm to about 50 nm.

In an optional embodiment, the perovskite solar cell further comprises a passivation layer between the electron transport layer and a perovskite active layer.

Optionally, the passivation layer is arranged under the first portion of the electron transport layer.

It is optional that the passivation layer comprises phenylethylamine salt and perylene diimide-based compound.

Optionally, the phenylethylamine salt is selected from the group consisting of PEAI (phenylethylammonium iodide), PEABr (phenylethylammonium bromide), PEACl (phenylethylammonium chloride), mF-PEAI (meta-fluorophenylethylammonium iodide), o-F-PEAI (ortho-fluorophenylethylammonium iodide), CF₃-PEAI (trifluoromethylphenylethylammonium iodide), CH₃O-PEAI (4-methoxyphenylethylammonium iodide), and 4F-PEAI (4-fluorophenylethylammonium iodide), and a combination thereof.

Optionally, the perylene diimide-based compound is selected from the group consisting of PDINN (N,N′-bis{3-[3-(dimethylamino)propylamino]propyl}perylene-3,4,9,10-tetracarboxylic diimide), PDIN (N,N′-bis{3-[3-(dimethylamino)propyl]amino}perylene-3,4,9,10-tetracarboxylic diimide), PDINO (N,N′-bis{3-[3-(dimethylamino)propyl]amino}perylene-3,4,9,10-tetracarboxylic diimide N-oxide), NDI-N(N,N′-bis{3-[3-(dimethylamino)propyl]amino}naphthalene-1,4,5,8-tetracarboxylic diimide), and a combination thereof.

It is optional that the phenylethylamine salt and the perylene diimide-based compound have a molar concentration ratio from about 4:1 to about 1:4.

In optional embodiment, the perovskite active layer comprises a perovskite material having a formula of CsₓMA_{y}FA_{1-x-y}Sn_{z}Pb_{1-z}I₃₋ₘBrₘ, with x being 0-0.5, y being 0-0.5, z being 0-0.5, m being 0-1.5.

It is optional that the perovskite material is doped with a hole transport material selected from the group consisting of 2PACz, MeO-2PACz (methoxy-2PACz), Me-4PACz (methyl-4PACz), Br-2PACz (bromo-2PACz), CbzBF, 4PADBC, and CbzBT, and a combination thereof.

In an optional embodiment, the anode comprises a conductive material deposited on a transparent substrate, the conductive material is selected from the group consisting of indium tin oxide (ITO), fluorine-doped tin oxide (FTO), niobium-doped titanium dioxide (NTO), aluminum-doped zinc oxide (AZO), gallium-doped zinc oxide (GZO), and a combination thereof.

In an optional embodiment, the cathode comprises a metal selected from the group consisting of gold, silver, copper, aluminium, nickel, and a combination thereof.

Optionally, the perovskite solar cell is an inverted perovskite solar cell.

In a second aspect of the present invention, there is provided with a method for preparing the perovskite solar cell in accordance with the first aspect, comprising the step of depositing an electron transport layer which comprises of first and second portions of tin oxide (SnOₓ) on a surface passivated perovskite active layer.

In an optional embodiment, the deposition is conducted by way of atomic layer deposition.

Optionally, the atomic layer deposition comprises the steps of: (a) contacting the surface passivated perovskite active layer with a pulse of tin in vapor phase in a reaction space followed by contacting the surface passivated perovskite active layer with a pulse of oxygen in vapor phase in the reaction space to form the first portion of tin oxide; and (b) contacting the first portion of tin oxide with a pulse of tin in vapor phase in the reaction space followed by contacting the first portion of tin oxide with a pulse of oxygen in vapor phase in the reaction space to form the second portion of tin oxide.

It is optional that step (a) is repeated for 10 to 50 cycles.

Optionally, step (b) is repeated for 50 cycles to 500 cycles.

It is optional that the pulse of tin in vapor phase is in contact with the surface passivated perovskite active layer in step (a) for about 120 ms to about 400 ms.

Optionally, the pulse of oxygen in vapor phase is in contact with the surface passivated perovskite active layer in step (a) for about 5 ms to about 20 ms.

It is optional that the pulse of tin in vapor phase is in contact with the first portion of tin oxide in step (b) for about 20 ms to about 100 ms.

Optionally, the pulse of oxygen in vapor phase is in contact with the first portion of tin oxide in step (b) for about 10 ms to about 40 ms.

In an optional embodiment, each of step (a) and step (b) further includes the step of purging the reaction space.

Optionally, the step of purging the reaction space comprises of performing purging after application of the pulse of tin in vapor phase and before application of the pulse of oxygen in vapor phase; and performing purging after the application of the pulse of oxygen in vapor phase.

In an optional embodiment, purging the reaction space in step (a) is different between a first cycle and a second cycle.

Optionally, the number of cycles is divided into a first set, a second set and a third set, the time for purging the reaction space increases from the first set to the third set.

In an optional embodiment, time for purging the reaction space after application of the pulse of tin in vapor phase in step (a) is about 20 seconds.

Optionally, the atomic layer deposition is conducted at a temperature from about 85° C. to about 125° C.

It is optional that the tin in vapor phase comprises tetrakis(dimethylamino)tin and the oxygen in vapor phase comprises water.

In an optional embodiment, the method further comprises the steps of: (i) providing an anode including a conductive material; (ii) depositing a perovskite active layer on the anode; (iii) subjecting the perovskite active layer to surface passivation treatment; and (iv) providing the cathode on the electron transport layer by way of thermal evaporation.

Optionally, step (ii) includes the steps of: providing a precursor solution comprising CsI, FAI, MAI, MABr, PbBr₂, PbI₂, and SnI₂ according to the formula of CsₓMA_{y}FA_{1-x-y}Sn_{z}Pb_{1-z}I₃₋ₘBrₘ, with x being 0-0.5, y being 0-0.5, z being 0-0.5, m being 0-1.5, and a hole transport material; spin-coating the precursor solution on the anode; and annealing the spin-coated anode to form the perovskite active layer thereon.

Optionally, the hole transport material has a concentration of about 0.15 mg/ml to about 1.2 mg/mL in the precursor solution.

It is optional that step (iii) comprising the steps of: spin-coating a surface passivating solution including a phenylethylamine salt and a perylene diimide-based compound on the perovskite active layer obtained in step (ii); and annealing the spin-coated perovskite active layer to form a passivation layer thereon.

Optionally, the phenylethylamine salt has an initial concentration of about 0.5 mg/mL to about 4 mg/mL, and the perylene diimide-based compound has an initial concentration of about 0.5 mg/mL to about 8 mg/mL.

It is optional that the phenylethylamine salt and the perylene diimide-based compound have a volume ratio of 1:1.

### BRIEF DESCRIPTION OF DRAWINGS

The patent or application file contains at least one drawing executed in color. Copies of this patent or patent application publication with color drawing(s) will be provided by the Office upon request and payment of the necessary fee.

The invention will now be more particularly described, by way of example only, with reference to the accompanying drawings, in which:

FIG. 1 is a schematic diagram illustrating a perovskite solar cell in accordance with an exemplary embodiment of the present invention;

FIG. 2 is a schematic illustration of the in accordance with an embodiment of the present invention;

FIG. 3 shows the XPS spectra of SnOₓ films obtained using different ALD dosing ratios of TDMASn:H₂O, with H₂O fixed at 20 ms a.u., arbitrary units;

FIG. 4 shows the Sn3d5/2 peak in the XPS spectra of SnOₓ films obtained with different ALD flow ratios of TDMASn to H₂O (H₂O fixed at 20 ms);

FIG. 5 shows the O1s peak in the XPS spectra of SnOₓ films obtained with different ALD flow ratios of TDMASn to H₂O (H₂O fixed at 20 ms);

FIG. 6 shows the x value of SnOₓ obtained by XPS analysis under different ALD flow ratios of TDMASn to H₂O (H₂O fixed at 20 ms);

FIG. 7 is table summarizing the fitting parameters of Sn3d5/2 peak and O1s peak in the XPS spectra of SnOₓ films;

FIG. 8 shows the impact of SnOₓ transport layer on device performance under different ALD dosing ratios of TDMASn:H₂O (H₂O fixed at 20 ms) and different ALD cycles;

FIG. 9A shows the ALD gas flow monitoring during the fabrication of SnOₓ transport layer with the ALD flow ratio of TDMASn to H₂O is 25:20 and the thickness of 200 cycles;

FIG. 9B shows the J-V curves of the best-performing device with the structure of ITO/active layer/passivation layer/SnOₓ (TDMASn:H₂O is 25:20)/Ag;

FIG. 9C shows the statistical histogram of PCE distribution of the device with the structure of ITO/active layer/passivation layer/SnOₓ (TDMASn:H₂O is 25:20)/Ag;

FIG. 10A shows the ALD gas flow monitoring during the fabrication of SnOₓ transport layer with the ALD flow ratio of TDMASn to H₂O is 50:20 and the thickness of 200 cycles;

FIG. 10B shows the J-V curves of the best-performing device with the structure of ITO/active layer/passivation layer/SnOₓ (TDMASn:H₂O is 50:20)/Ag;

FIG. 10C shows the statistical histogram of PCE distribution of the device with the structure of ITO/active layer/passivation layer/SnOₓ (TDMASn:H₂O is 50:20)/Ag;

FIG. 11A shows the ALD gas flow monitoring during the fabrication of SnOₓ transport layer with the ALD flow ratio of TDMASn to H₂O is 100:20 and the thickness of 200 cycles;

FIG. 11B shows the J-V curves of the best-performing device with the structure of ITO/active layer/passivation layer/SnOₓ (TDMASn:H₂O is 100:20)/Ag;

FIG. 11C shows the statistical histogram of PCE distribution of the device with the structure of ITO/active layer/passivation layer/SnOₓ (TDMASn:H₂O is 100:20)/Ag;

FIG. 12A shows the ALD gas flow monitoring during the fabrication of SnOₓ transport layer with the ALD flow ratio of TDMASn to H₂O is 150:20 and the thickness of 200 cycles;

FIG. 12B shows the J-V curves of the best-performing device with the structure of ITO/active layer/passivation layer/SnOₓ (TDMASn:H₂O is 150:20)/Ag;

FIG. 12C shows the statistical histogram of PCE distribution of the device with the structure of ITO/active layer/passivation layer/SnOₓ (TDMASn:H₂O is 150:20)/Ag;

FIG. 13A shows the ALD gas flow monitoring during the fabrication of SnOₓ transport layer with the ALD flow ratio of TDMASn to H₂O is 200:20 and the thickness of 200 cycles;

FIG. 13B shows the J-V curves of the best-performing device with the structure of ITO/active layer/passivation layer/SnOₓ (TDMASn:H₂O is 200:20)/Ag;

FIG. 13C shows the statistical histogram of PCE distribution of the device with the structure of ITO/active layer/passivation layer/SnOₓ (TDMASn:H₂O is 200:20)/Ag;

FIG. 14A shows the ALD gas flow monitoring during the fabrication of SnOₓ transport layer with the ALD flow ratio of TDMASn to H₂O is 250:20 and the thickness of 200 cycles;

FIG. 14B shows the J-V curves of the best-performing device with the structure of ITO/active layer/passivation layer/SnOₓ (TDMASn:H₂O is 250:20)/Ag;

FIG. 14C shows the statistical histogram of PCE distribution of the device with the structure of ITO/active layer/passivation layer/SnOₓ (TDMASn:H₂O is 250:20)/Ag;

FIG. 15 shows the statistical distribution of V_{OC}, J_{SC}, and FF of device with the structure of ITO/active layer/passivation layer/SnOₓ/Ag under different ALD flow ratio of TDMASn to H₂O;

FIG. 16 shows the J-V curves of the best-performing device under difference thickness of SnOₓ transport layer;

FIG. 17 shows the statistical distribution of device PCE under difference thickness of SnOₓ transport layer;

FIG. 18A shows the J-V curves of the best-performing device with the structure of ITO/active layer/passivation layer/200 cycles SnOₓ (TDMASn:H₂O is 50:20)/Ag obtained with different concentrations of PDINN mixed with 1 mg/ml mF-PEAI;

FIG. 18B shows the J-V curves of the best-performing device with the structure of ITO/active layer/passivation layer/200 cycles SnOₓ (TDMASn:H₂O is 50:20)/Ag obtained with different concentrations of PDINN mixed with 2 mg/ml mF-PEAI;

FIG. 18C shows the J-V curves of the best-performing device with the structure of ITO/active layer/passivation layer/200 cycles SnOₓ (TDMASn:H₂O is 50:20)/Ag obtained with different concentrations of PDINN mixed with 3 mg/mL mF-PEAI;

FIG. 18D shows the J-V curves of the best-performing device with the structure of ITO/active layer/passivation layer/200 cycles SnOₓ (TDMASn:H₂O is 50:20)/Ag obtained with different concentrations of PDINN mixed with 4 mg/mL mF-PEAI;

FIG. 19 shows the peak force infrared (PFIR) maps of the active layer with and without the passivation layer. The PFIR mapping shows the intensity and distribution of the stretching vibrations of C═O at 1650 cm⁻¹ for PDINN molecules;

FIG. 20 shows the J-V curves of the best-performing device with the structure of ITO/active layer/passivation layer/300 cycles SnOₓ (TDMASn:H₂O is 50:20)/Ag;

FIG. 21 shows the J-V curves of the best-performing device with the structure of ITO/active layer/passivation layer/C₆₀/BCP/Ag;

FIG. 22 shows the space-charge limited current (SCLC) measurement of electron-only devices with the configuration of ITO/ZnO/C₆₀/BCP/Ag or ITO/ZnO/SnOₓ/Ag;

FIG. 23A shows the UV-Vis spectra of the perovskite film and the passivated perovskite film;

FIG. 23B shows the Tauc plot of the perovskite film;

FIG. 23C shows the Tauc plot of the passivated perovskite film;

FIG. 23D shows the UV-Vis spectra of the SnOₓ₍ᵢ₎ and SnOₓ films;

FIG. 23E shows the Tauc plot of the SnOₓ film;

FIG. 23F shows the Tauc plot of the SnOₓ₍ᵢ₎ film;

FIG. 24A shows the UPS spectra of perovskite film;

FIG. 24B shows the Tauc plot of the perovskite film;

FIG. 24C shows the Tauc plot of the SnOₓ film;

FIG. 24D shows the UPS spectra of the SnOₓ film;

FIG. 24E shows the energy level diagram of ETL/perovskite. The LUMO level of C₆₀ is generally around-4.3 eV;

FIG. 25 shows the effect of SnOₓ₍ᵢ₎ interlayer on device performance under different ALD dosing ratios of TDMASn:H₂O (H₂O fixed at 20 ms) and varied ALD cycles;

FIG. 26 shows the J-V curves of the best-performing device based on SnOₓ₍ᵢ₎ interlayer fabricated by different ALD flow ratio of TDMASn to H₂O;

FIG. 27 shows the statistical distribution of performance parameters of device with the different ALD processes for the SnOₓ₍ᵢ₎ interlayer;

FIG. 28 shows the ALD gas flow monitoring of SnOₓ₍ᵢ₎ interlayer;

FIG. 29 shows the J-V curves of the best-performing SnOₓ-based device with the structure of ITO/active layer/passivation layer/30 cycles SnOₓ₍ᵢ₎ (ALD dosing ratio of TDMASn:H₂O is 200:20) interlayer/300 cycles SnOₓ (ALD dosing ratio of TDMASn:H₂O is 50:20)/Ag;

FIG. 30 shows the MPP of the SnOₓ-based device;

FIG. 31 shows the EQE curves and integrated J_{SC} for SnOₓ-based device;

FIG. 32 shows the statistical distribution of SnOₓ-based devices performance parameters (V_{OC}, J_{SC}, FF, and PCE);

FIG. 33A shows the J-V curves of the device with structure of ITO/active layer/BCP/Ag;

FIG. 33B shows the J-V curves of the device with structure of ITO/active layer/SnOₓ (TDMASn:H₂O is 50:20)/Ag;

FIG. 33C shows the J-V curves of the device with structure of ITO/active layer/mF-PEAI/SnOₓ (TDMASn:H₂O is 50:20)/Ag;

FIG. 33D shows the J-V curves of the device with structure of ITO/active layer/mF-PEAI/SnOₓ₍ᵢ₎ (TDMASn:H₂O is 200:20)/SnOₓ (TDMASn:H₂O is 50:20)/Ag;

FIG. 33E shows the J-V curves of the device with structure of ITO/active layer/PDINN/SnOₓ (TDMASn:H₂O is 50:20)/Ag;

FIG. 33F shows the J-V curves of the device with structure of ITO/active layer/PDINN/SnOₓ₍ᵢ₎ (TDMASn:H₂O is 200:20)/SnOₓ (TDMASn:H₂O is 50:20)/Ag;

FIG. 33G shows the J-V curves of the device with structure of ITO/active layer/mF-PEAI+PDINN/BCP/Ag;

FIG. 33H shows the J-V curves of the device with structure of ITO/active layer/mF-PEAI+PDINN/SnOₓ (TDMASn:H₂O is 50:20)/Ag;

FIG. 33I shows the J-V curves of the device with structure of ITO/active layer/mF-PEAI+PDINN/C₆₀/BCP/Ag;

FIG. 33J shows the J-V curves of the device with structure of ITO/active layer/mF-PEAI+PDINN/SnOₓ₍ᵢ₎ (TDMASn:H₂O is 200:20)/SnOₓ (TDMASn:H₂O is 50:20)/Ag;

FIG. 34 shows the EQE-EL, V_{TFL}, and PL intensity of the SnOₓ₍ᵢ₎ interlayer obtained with different pulse time of TDMASn source (the pulse time of H₂O sources is fixed at 20 ms);

FIG. 35 shows EQE-EL of SnOₓ-based devices with SnOₓ₍ᵢ₎ interlayer obtained with different ALD flow ratios of TDMASn:H₂O;

FIG. 36A shows the SCLC of electron-only device (ITO/SnO₂ (spin-coating)/active layer/passivation layer/SnOₓ₍ᵢ₎ (ALD)/SnOₓ (ALD)/Ag) without SnOₓ₍ᵢ₎ interlayer;

FIG. 36B shows the SCLC of electron-only device (ITO/SnO₂ (spin-coating)/active layer/passivation layer/SnOₓ₍ᵢ₎ (ALD)/SnOₓ (ALD)/Ag) with SnOₓ₍ᵢ₎ interlayer obtained with TDMASn:H₂O ALD flow ratio of 25:20;

FIG. 36C shows the SCLC of electron-only device (ITO/SnO₂ (spin-coating)/active layer/passivation layer/SnOₓ₍ᵢ₎ (ALD)/SnOₓ (ALD)/Ag) with SnOₓ₍ᵢ₎ interlayer obtained with TDMASn:H₂O ALD flow ratio of 50:20;

FIG. 36D shows the SCLC of electron-only device (ITO/SnO₂ (spin-coating)/active layer/passivation layer/SnOₓ₍ᵢ₎ (ALD)/SnOₓ (ALD)/Ag) with SnOₓ₍ᵢ₎ interlayer obtained with TDMASn:H₂O ALD flow ratio of 100:20;

FIG. 36E shows the SCLC of electron-only device (ITO/SnO₂ (spin-coating)/active layer/passivation layer/SnOₓ₍ᵢ₎ (ALD)/SnOₓ (ALD)/Ag) with SnOₓ₍ᵢ₎ interlayer obtained with TDMASn:H₂O ALD flow ratio of 150:20;

FIG. 36F shows the SCLC of electron-only device (ITO/SnO₂ (spin-coating)/active layer/passivation layer/SnOₓ₍ᵢ₎ (ALD)/SnOₓ (ALD)/Ag) with SnOₓ₍ᵢ₎ interlayer obtained with TDMASn:H₂O ALD flow ratio of 200:20;

FIG. 36G shows the SCLC of electron-only device (ITO/SnO₂ (spin-coating)/active layer/passivation layer/SnOₓ₍ᵢ₎ (ALD)/SnOₓ (ALD)/Ag) with SnOₓ₍ᵢ₎ interlayer obtained with TDMASn:H₂O ALD flow ratio of 250:20;

FIG. 37 shows the PL spectrum of active layer/SnOₓ₍ᵢ₎/SnOₓ films with SnOₓ₍ᵢ₎ interlayer obtained with different ALD flow ratios of TDMASn:H₂O;

FIG. 38 shows the PL mapping (incident from the SnOₓ side) of the films, including the pristine SnOₓ/active layer;

FIG. 39 shows the PL mapping (incident from the SnOₓ side) of the films, including the SnOₓ/SnOₓ₍ᵢ₎/active layer;

FIG. 40 shows the SEM images of film surfaces under different stacking;

FIG. 41 shows the SEM cross-sectional image of ITO/Perovskite/SnOₓ₍ᵢ₎/SnOₓ/Ag device;

FIG. 42 shows the thickness profile analysis of SnOₓ₍ᵢ₎ films deposited by 150 cycles of ALD using a mechanical profiler. (The average thickness of the SnOₓ₍ᵢ₎ film after 150 cycles is 18.3 nm, which implies that the thickness of the SnOₓ₍ᵢ₎ film after 30 cycles is approximately 3.7 nm.);

FIG. 43A shows the thickness profile analysis of SnOₓ films deposited by 300 of ALD using a mechanical profiler. (The thickness of the deposited 300 cycles SnOₓ films to be approximately 37˜38 nm);

FIG. 43B shows the thickness profile analysis of SnOₓ films deposited by 600 cycles of ALD using a mechanical profiler;

FIG. 43C shows the thickness profile analysis of SnOₓ films deposited by 900 cycles of ALD using a mechanical profiler;

FIG. 44A shows illustration of the simulated charge distribution (corresponding to CBM) at the pristine SnO₂/perovskite interface;

FIG. 44B shows illustration of the simulated charge distribution (corresponding to CBM) at the SnOₓ₍ᵢ₎ (V_{O})/perovskite interface;

FIG. 44C shows illustration of the simulated charge distribution (corresponding to CBM) at the SnO₂/PDINN/perovskite interface;

FIG. 44D shows illustration of the simulated charge distribution (corresponding to CBM) at the SnOₓ₍ᵢ₎ (V_{O})/PDINN/perovskite interface;

FIG. 45A shows the computed pDOS plots of the pristine SnO₂/perovskite interface;

FIG. 45B shows the computed pDOS plots of the SnOₓ₍ᵢ₎ (V_{O})/perovskite interface;

FIG. 45C shows the computed pDOS plots of the SnO₂/PDINN/perovskite interface;

FIG. 45D shows the computed pDOS plots of the SnOₓ₍ᵢ₎ (V_{O})/PDINN/perovskite interface;

FIG. 46 shows the DFT structural optimization of SnO₂/perovskite interface and SnO₂/PDINN/perovskite interface;

FIG. 47A shows the computed pDOS curves of SnO₂/perovskite interface;

FIG. 47B shows the computed pDOS curves of SnOₓ₍ᵢ₎ (V_{O})/perovskite interface;

FIG. 47C shows the computed pDOS curves of SnO₂/PDINN/perovskite interface;

FIG. 47D shows the computed pDOS curves of SnOₓ₍ᵢ₎ (V_{O})/PDINN/perovskite interface;

FIG. 48A shows the computed pDOS curves of SnO₂/PDINN/perovskite interface, where SnO₂ was extracted separately;

FIG. 48B shows the computed pDOS curves of SnO₂/PDINN/perovskite interface, where SnO₂+PDINN was extracted separately;

FIG. 48C shows the computed pDOS curves of SnO₂/PDINN/perovskite interface, where PDINN was extracted separately;

FIG. 49A shows the computed pDOS curves of SnOₓ₍ᵢ₎ (V_{O})/PDINN/perovskite interface, where SnOₓ₍ᵢ₎ (V_{O}) was extracted separately;

FIG. 49B shows the computed pDOS curves of SnOₓ₍ᵢ₎ (V_{O})/PDINN/perovskite interface, where SnOₓ₍ᵢ₎ (V_{O})+PDINN was extracted separately;

FIG. 49C shows the computed pDOS curves of SnOₓ₍ᵢ₎ (V_{O})/PDINN/perovskite interface, where PDINN was extracted separately;

FIG. 50A shows the I 3d core levels of perovskite, perovskite/SnOₓ and perovskite/PDINN/SnOₓ;

FIG. 50B shows the FWHM of I 3d corresponding to FIG. 50A;

FIG. 50C shows the Pb 4f core levels of perovskite, perovskite/SnOₓ and perovskite/PDINN/SnOₓ;

FIG. 50D shows the binding energy of Pb 4f corresponding to FIG. 50C;

FIG. 51A shows the illustration of the simulated charge distribution (corresponding to CBM level) at the SnOₓ₍ᵢ₎ (V_{O})/PDINN/perovskite interface;

FIG. 51B shows the top view of FIG. 51A;

FIG. 51C shows the illustration of the simulated charge distribution (corresponding to CBM level) at the SnOₓ₍ᵢ₎ (V_{O})/mF-PEAI/perovskite interface;

FIG. 51D shows the top view of FIG. 51C;

FIG. 51E shows the illustration of the simulated charge distribution (corresponding to CBM level) at the SnOₓ₍ᵢ₎ (V_{O})/PDINN+mF-PEAI/perovskite interface;

FIG. 51F shows the top view of FIG. 51E;

FIG. 52 shows the operational stability of devices at temperature of 65° C.;

FIG. 53 is a table summarizing the device operational stability (MPP tracking under heating above 50° C.) from representative n-i-p and p-i-n PSCs;

FIG. 54 shows the comparison of the stability of SnOₓ-based, and C₆₀/BCP-based devices under 85° C. heating and 1 sun illumination;

FIG. 55A shows the TOF-SIMS characterization of original device without stability test;

FIG. 55B shows TOF-SIMS characterization of device after the operational stability test corresponding to FIG. 54;

FIG. 56A shows the TOF-SIMS characterization of C₆₀-based device without stability test;

FIG. 56B shows the TOF-SIMS characterization of C₆₀-based device after the operational stability test;

FIG. 57A shows the TOF-SIMS characterization of SnOₓ-based device without stability test;

FIG. 57B shows the TOF-SIMS characterization of SnOₓ-based device after the stability test;

FIG. 58 shows the devices' efficiency evolution under repeated thermal cycling (−40° C. to 85° C.) in the dark in air (ISOS-T-3). Thermal cycling tests were conducted using eight individual devices and obtained the average performance change along with the SD as the error measure;

FIG. 59 shows the devices' efficiency evolution under storage in dark under indoor air conditions (ISOS-D-1). 10 to 14 individual devices were used to conduct the stability tests and the average performance change was obtained along with the SD as the error measure;

FIG. 60 shows the efficiency evolution for unencapsulated and encapsulated SnOₓ-based devices under storage in dark in indoor air condition (ISOS-D-1);

FIG. 61 shows the devices' efficiency evolution under damp heat testing at 85° C. and 85% RH in the dark in air (ISOS-D-3). 10 to 14 individual devices were used to conduct the stability tests and the average performance change was obtained along with the SD as the error measure;

FIG. 62 shows the efficiency evolution for unencapsulated and encapsulated SnOₓ-based devices under damp heat testing at 85° C. and 85% relative humidity in the dark in air (ISOS-D-3);

FIG. 63 shows the devices' efficiency evolution under light on-off cycle test (12 hours-12 hours) using light-emitting diode (LED) lamps simulated 1-sun illumination (ISOS-LC-1). 10 to 14 individual devices were used to conduct the stability tests and the average performance change was obtained along with the SD as the error measure;

FIG. 64 shows the devices' efficiency evolution under storage in sunlight under outdoor condition (ISOS-O-1). (The devices are in an open-circuit state. Environmental data are quoted from the Hong Kong Observatory, https://www.hko.gov.hk/tc/wxinfo/pastwx/mws2023/mws202309.htm.). 10 to 14 individual devices were used to conduct the stability tests and the average performance change was obtained along with the SD as the error measure;

FIG. 65 shows the solar radiation intensity tracking curve. (Data quoted from Hong Kong Observatory https://www.hko.gov.hk/tc/wxinfo/pastwx/mws2023/mws202309.htm);

FIG. 66A is a schematic illustration of self-encapsulation of SnOₓ-based device;

FIG. 66B is a schematic illustration of the physical encapsulation effect of the control (C₆₀-based) device; and

FIG. 67 shows the photos of the original device (left), the device with mask (middle), and the encapsulated device (right) before and after stability testing.

### DETAILED DESCRIPTION OF OPTIONAL EMBODIMENT

As used herein, the forms “a”, “an”, and “the” are intended to include the singular and plural forms unless the context clearly indicates otherwise.

The words “example” or “exemplary” used in this invention are intended to serve as an example, instance, or illustration. Any aspect or design described in this disclosure as “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise or clear from context, “X employs A or B” is intended to mean any of the natural inclusive permutations. That is, if X employs A, X employs B, or X employs both A and B, then “X employs A or B” is satisfied under any of the foregoing instances.

As used herein, the phrase “about” is intended to refer to a value that is slightly deviated from the value stated herein. Examples have been described throughout the present disclosure.

Without wishing to be bound by theory, the inventors have, through their own researches, trials and experiments devised a strategy that may enhance the performance and stability of a perovskite solar cell, particularly an inverted p-i-n perovskite solar cell. In particular, the inventors have devised a solar cell configuration that may avoid using fullerene electron transport layer (ETL), eliminate the detrimental chemical reaction at the perovskite/inorganic ETL interface, and may facilitate electron transport/electron extraction between the perovskite and the ETL. Advantageously, as illustrated in the later part of the present disclosure, the perovskite solar cell as described herein may have a power conversion efficiency of at least 25%, T₉₅ aging lifetime of at least 2000 hours even without any encapsulation, etc.

In the first aspect of the present invention, there is provided a perovskite solar cell comprising an electron transport layer between an anode and a cathode, wherein the electron transport layer comprises of first and second portions of tin oxide (SnOₓ). The first portion of tin oxide may be arranged on the second portion of tin oxide. For example, depending on the type of the perovskite solar cell, such as n-i-p type (i.e., direct type), p-i-n type (i.e., inverted type) and the like, the first portion may be arranged on a bottom of the second portion or on a top of the second portion.

In particular, the first portion of tin oxide and a second portion of tin oxide may have different stoichiometry. For example, in some embodiments, the x of SnOₓ in the first and the second portions may be from about 1.81 to 1.98, such as 1.81, 1.82, 1.83, 1.84, 1.85, 1.86 . . . 1.90, 1.91, 1.92, 1.93 . . . 1.96, 1.97, 1.98 and the like. The first and the second portions of tin oxide may also have different thickness. For example, in some embodiments, the thickness of the first and second portions of tin oxide is in the range from about 2 nm to about 50 nm, such as from about 1.95 nm to about 50 nm, from about 1.98 nm to about 50.1 nm, from about 1.98 nm to about 49.8 nm, from about 1.99 nm to about 50 nm, from about 2.01 nm to about 50.2 nm, from about 2.05 nm to about 50.3 nm and the like.

In some particular embodiments, the thickness of the first portion of tin oxide may be less than that of the second portion. For example, the thickness of the first portion may be about 2 nm to about 10 nm (such as 1.98 nm, 1.99 nm, 2 nm . . . 2.05 nm . . . 2.1 nm . . . 3.1 nm . . . 3.7 nm, 3.8 nm . . . 5 nm . . . 5.12 nm . . . 6.2 nm . . . 6.64 nm . . . 9.8 nm . . . 9.9 nm . . . 10 nm . . . 10.2 nm and the like) and the thickness of the second portion is about 15 nm to about 50 nm (such as 14.8 nm, 14.9 nm, 15 nm . . . 15.6 nm . . . 16.3 nm . . . 20 nm . . . 25.1 nm . . . 30 nm . . . 32 nm . . . 37 nm . . . 38 nm . . . 40 nm . . . 54 nm . . . 50 nm . . . 50.2 nm, and the like).

In some other particular embodiments, the x of SnOₓ in the first portion may be smaller than that of the second portion. For example, the x of SnOₓ in the first portion may be about 1.83 and the x of SnOₓ in the second portion may be about 1.96.

In some preferred embodiments, the thickness of the first portion of tin oxide is less than that of the second portion and the x of SnOₓ in the first portion is smaller than that of the second portion. Without wishing to be bound by theory, it is believed that with both the thickness and x of SnOₓ of the first portion being less and smaller than those of the second portion, it may induce oxygen defects (V_{O} defects) within the electron transport layer, thereby increasing the carrier transfer between the perovskite active layer and the electron transport layer. Further details will be discussed in the later part of the present disclosure.

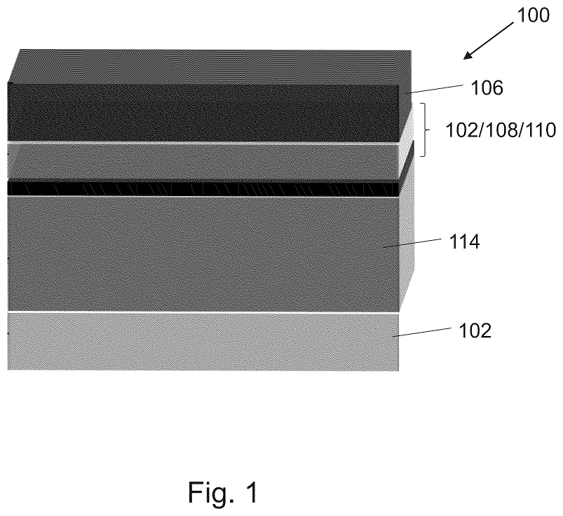

With reference to FIG. 1, there is provided an exemplary perovskite solar cell 100 comprising an electron transport layer 102 between an anode 104 and a cathode 106, wherein the electron transport layer comprises a first portion of tin oxide 108 and a second portion of tin oxide 110. In this embodiment, the perovskite solar cell 100 may be an inverted perovskite solar cell. The first portion of tin oxide 108 may therefore be arranged on the bottom of the second portion of tin oxide 110. The first portion of tin oxide may have a different O:Sn stoichiometry as compared with the second portion of tin oxide. In particular, the first portion of tin oxide may have a lower O:Sn stoichiometry such as 1.83 (i.e., the x value of SnOₓ is 1.83) as compared with that of the second portion of tin oxide such as a O:Sn stoichiometry of 1.96 (i.e., the x value of SnOₓ is 1.96). The first portion of tin oxide may also have a different thickness particularly a lower thickness than the second portion of tin oxide. For example, the first portion of tin oxide may have a thickness of about 2 nm, about 3 nm, about 3.7 nm, about 3.8 nm, about 5 nm, about 10 nm and the like; whereas the second portion of tin oxide may have a thickness of about 15 nm, such as about 15 nm, about 25 nm, about 30 nm, about 35 nm, about 37 m, about 38 nm, about 40 nm, about 50 nm and the like.

As shown in FIG. 1, the perovskite solar cell 100 may further comprise a passivation layer 112 positioned between the electron transport layer 102 and a perovskite active layer 114. In particular, the passivation layer may be arranged under the first portion of the electron transport layer, such as to be arranged in direct contact with the bottom of the first portion of the electron transport layer. Without wishing to be bound by theory, it is believed that on the one hand, the passivation layer may act to passivate the perovskite surface forming a molecule passivation layer or 2D perovskite layer to prevent direct interaction with oxygen vacancy defect-bearing first portion of tin oxide, thereby optimizing interfacial charge transfer and preventing structural mismatch. On the other hand, the passivation layer may also act as a buffering layer that may enable atomic layer deposition of the electron transport layer by preventing H₂O (an oxygen source for the ALD of the electron transport layer) from directly contacting and reacting with the perovskite active layer.

The passivation layer 112 may comprise a phenylethylamine salt and a perylene diimide-based compound. In particular, in some embodiments, the phenylethylamine salt may be selected from the group consisting of PEAI (phenylethylammonium iodide), PEABr (phenylethylammonium bromide), PEACl (phenylethylammonium chloride), mF-PEAI (meta-fluorophenylethylammonium iodide), o-F-PEAI (ortho-fluorophenylethylammonium iodide), CF₃-PEAI (trifluoromethylphenylethylammonium iodide), CH₃O-PEAI (4-methoxyphenylethylammonium iodide), and 4F-PEAI (4-fluorophenylethylammonium iodide), and a combination thereof. In some embodiments, the perylene diimide-based compound may be selected from the group consisting of PDINN (N,N′-bis{3-[3-(dimethylamino)propylamino]propyl}perylene-3,4,9,10-tetracarboxylic diimide), PDIN (N,N′-bis{3-[3-(dimethylamino)propyl]amino}perylene-3,4,9,10-tetracarboxylic diimide), PDINO (N,N′-bis{3-[3-(dimethylamino)propyl]amino}perylene-3,4,9,10-tetracarboxylic diimide N-oxide), NDI-N(N,N′-bis{3-[3-(dimethylamino)propyl]amino}naphthalene-1,4,5,8-tetracarboxylic diimide), and a combination thereof.

The phenylethylamine salt and the perylene diimide-based compound may have a molar concentration ratio from about 4:1 to about 1:4, such as about 1:1, about 1:1.5, about 1:2, about 1:3, about 1:4 and the like.

The perovskite active layer 114 may comprise a perovskite material doped with a hole transport material. In other words, the perovskite active layer may be a single layer of co-deposited perovskite material and hole transport material. In some embodiments, the perovskite material may have a formula of CsₓMA_{y}FA_{1-x-y}Sn_{z}Pb_{1-z}I₃₋ₘBrₘ, with x being 0-0.5, y being 0-0.5, z being 0-0.5, m being 0-1.5. For example, in particular the be some embodiments, perovskite material may Cs_{0.05}MA_{0.5}FA_{0.45}Sn_{0.2}Pb_{0.8}I₃, Cs_{0.05}FA_{0.95}PbI_{2.94}Br_{0.06}, MA_{0.5}FA_{0.5}Sn_{0.5}Pb_{0.5}I_{2.25}Br_{0.75}, Cs_{0.3}FA_{0.7}PbI_{2.4}Br_{0.6}, Cs_{0.5}FA_{0.5}Sn_{0.5}Pb_{0.5}I_{1.5}Br_{1.5}, FAPbI₃, Cs_{0.05}FA_{0.95} PbI_{2.94}Br_{0.06} and the like. The hole transport material may be selected from the group consisting of 2PACz, MeO-2PACz (methoxy-2PACz), Me-4PACz (methyl-4PACz), Br-2PACz (bromo-2PACz), CbzBF, 4PADBC, and CbzBT, and a combination thereof. Without wising to be bound by theory, it is believed that the use of such a perovskite active layer may simplify the manufacturing process of the perovskite solar cell.

Referring to FIG. 1, the anode 104 may be positioned under the perovskite active layer 114, particularly in direct contact with the bottom of the perovskite active layer. The anode 104 may comprise a conductive material deposited on a transparent substrate such as a glass and the like. In some embodiments, the conductive material may be selected from the group consisting of indium tin oxide (ITO), fluorine-doped tin oxide (FTO), niobium-doped titanium dioxide (NTO), aluminum-doped zinc oxide (AZO), gallium-doped zinc oxide (GZO), and a combination thereof.

The cathode 106, which may be positioned above the electron transport layer 102, particularly in direct contact with the top of the second portion of the electron transport layer. The cathode may comprise a metal selected from the group consisting of gold, silver, copper, aluminium, nickel, and a combination thereof.

The method for preparing the perovskite solar cell as described herein is now disclosed. The method may comprise the step of depositing an electron transport layer which comprises of first and second portions of tin oxide (SnOₓ) on a surface passivated perovskite active layer. In particular, the deposition may be conducted by way of atomic layer deposition.

In some embodiments, the atomic layer deposition may comprise the steps of: (a) contacting the surface passivated perovskite active layer with a pulse of tin in vapor phase in a reaction space followed by contacting the surface passivated perovskite active layer with a pulse of oxygen in vapor phase in the reaction space to form the first portion of tin oxide; and (b) contacting the first portion of tin oxide with a pulse of tin in vapor phase in the reaction space followed by contacting the first portion of tin oxide with a pulse of oxygen in vapor phase in the reaction space to form the second portion of tin oxide. As used herein, the term “reaction space” generally denotes a reaction chamber, or a defined volume therein, in which the conditions can be adjusted so that the atomic layer deposition is enabled.

As mentioned herein, in some embodiments, the thickness of the first portion of tin oxide may be less than that of the second portion. Without wising to be bound by theory, it is believed that the deposition thickness may be adjusted by the numbers of deposition cycle. In particular, it is believed that the less the number of deposition cycle, the less the thickness of the resultant layer. Thus, in the embodiments where the thickness of the first portion of tin oxide is less than that of the second portion, the number of deposition cycle in step (a) may be less than that in step (b). For example, step (a) may be repeated for 10 cycles to 50 cycles (e.g., 15 cycles . . . 18 cycles . . . 30 cycles . . . 50 cycles and the like) whereas step (b) may be repeated for 50 cycles to 500 cycles (e.g., 120 cycles . . . 200 cycles . . . 240 cycles . . . 280 cycles . . . 320 cycles . . . 400 cycles and the like).

As also mentioned herein, in some embodiments, the x of SnOₓ in the first portion may be smaller than that of the second portion. Without wishing to be bound by theory, it is believed that the value of x (i.e., the O:Sn stoichiometry) may be adjusted by the feeding ratio (or dosing ratio) of the pulse of tin in vapor phase and the pulse of oxygen in vapor phase. For example, in these embodiments where the x of SnOₓ of the first portion is smaller than that of the second portion, the pulse of tin in vapor phase may be in contact with the surface passivated perovskite active layer in step (a) for about 120 ms to about 400 ms whereas the pulse of oxygen in vapor phase may be in contact with the surface passivated perovskite active layer in step (a) for about 5 ms to about 20 ms. In other words, the feeding ratio (or dosing ratio) of the pulse of tin in vapor phase and the pulse of oxygen in vapor phase in step (a) may be of about 120 ms-400 ms:5 ms-20 ms (e.g., 120 ms:10 ms, 180 ms:5 ms, 200 ms:20 ms, 300 ms:20 ms, 400 ms:10 ms and the like). Similarly, the value of x (i.e., the O:Sn stoichiometry) of the second portion may be adjusted by the feeding ratio (or dosing ratio) of the pulse of tin in vapor phase and the pulse of oxygen in vapor phase when conducting step (b). For example, in these embodiments, the pulse of tin in vapor phase may be in contact with the first portion of tin oxide in step (b) for about 20 ms to about 100 ms whereas the pulse of oxygen in vapor phase may be in contact with the surface passivated perovskite active layer in step (b) for about 10 ms to about 40 ms. In other words, the feeding ratio (or dosing ratio) of the pulse of tin in vapor phase and the pulse of oxygen in vapor phase in step (b) may be of about 20 ms-100 ms:10 ms-40 ms (e.g., 20 ms:10 ms, 50 ms:20 ms, 50 ms:30 ms, 100 ms:20 ms, 100 ms:40 ms and the like).

The atomic layer deposition process as described herein may further include the step of purging the reaction space in each of step (a) and step (b). In particular, the step of purging the reaction space may comprise of performing purging after application of the pulse of tin in vapor phase and before application of the pulse of oxygen in vapor phase; and performing purging after the application of the pulse of oxygen in vapor phase. For example, in each cycle of step (a), after applying the pulse of tin in vapor phase in accordance with the feeding/dosing time as described herein, the reaction space may be purged with the aid of an inert gas such as nitrogen or argon to remove excess/unreacted tin in vapor phase and reaction by-products from the reaction space, before the application of the pulse of oxygen in vapor phase. Similarly, after applying the pulse of oxygen in vapor phase in accordance with the feeding/dosing time as described herein, the reaction space may be purged with the aid of an inert gas such as nitrogen or argon to remove excess/unreacted oxygen in vapor phase and reaction by-products from the reaction space, before commencing the next cycle or next step (i.e., step (b).

Similarly, for each cycle of step (b), after applying the pulse of tin in vapor phase in accordance with the feeding/dosing time as described herein, the reaction space may be purged with the aid of an inert gas such as nitrogen or argon to remove excess/unreacted tin in vapor phase and reaction by-products from the reaction space, before the application of the pulse of oxygen in vapor phase. After applying the pulse of oxygen in vapor phase in accordance with the feeding/dosing time as described herein, the reaction space may be purged with the aid of an inert gas such as nitrogen or argon to remove excess/unreacted oxygen in vapor phase and reaction by-products from the reaction space, before commencing the next cycle.

In some embodiments, purging the reaction space in step (a) may remain unchanged between a first cycle and a second cycle. For example, the time for purging the reaction space after application of the pulse of tin in vapor phase in step (a) may be identical in the first cycle and the second cycle, e.g., assuming that the time for purging the reaction space after application of the pulse of tin in vapor phase in step (a) is about 20 seconds, then in both the first and the second cycles, the time for purging the reaction space after application of the pulse of tin in vapor phase will be about 20 seconds.

In some other embodiments, purging the reaction space after application of the pulse of tin in vapor phase in step (a) may be different between a first cycle and a second cycle. In these embodiments, the number of cycles may be divided into three or more sets, such as a first set, a second set and a third set, and the time for purging the reaction space may increase from the first set to the third set. For example, assuming the time for purging the reaction space after application of the pulse of tin in vapor phase in step (a) is about 20 seconds and step (a) is repeated for 30 cycles, the 30 cycles may be divided into three sets of cycles (e.g., a first set=first 10 cycles; a second set=11-20 cycles; a third set=21-30 cycles) and the time for purging the reaction space in each set of cycles increases in gradient (e.g. first 10 cycles: 6 seconds; 11-20 cycles: 13 seconds; 21-30 cycles: 20 seconds).

Without wishing to be bound by theory, it is believed that in addition to the feed ratio of the tin in vapor phase (i.e. the gaseous tin source) to the oxygen in vapor phase (i.e. the gaseous oxygen source), the adjustment of the time for purging the reaction space after application of the pulse of tin in vapor phase in step (a) may facilitate the introduction of oxygen vacancies in the first portion of the electron transport layer. In particular, it is believed that the shorter the time for purging the reaction space after application of the pulse of tin in vapor phase in step (a), the higher the likelihood of oxygen vacancies in the first portion of the electron transport layer. Details of this reaction mechanism will be discussed in the later part of the present disclosure.

In some embodiments, the atomic layer deposition may be conducted at a temperature from about 85° C. to about 125° C. For example, the atomic layer deposition may be conducted at a temperature of about 85° C. (e.g., 83° C. . . . 83.5° C. . . . 83.8° C. . . . 84.2° C. . . . 84.6° C. . . . 85° C. . . . 85.2° C. and the like), about 95° C. (e.g., 93° C. . . . 93.5° C. . . . 93.8° C. . . . 94.2° C. . . . 94.6° C. . . . 95° C. . . . 95.2° C. and the like), about 105° C. (e.g., 103° C. . . . 103.5° C. . . . 103.8° C. . . . 104.2° C. . . . 104.6° C. . . . 105° C. . . . 105.2° C. and the like), about 110° C. (e.g., 108° C. . . . 108.5° C. . . . 108.8° C. . . . 109.2° C. . . . 109.6° C. . . . 110° C. . . . 110.2° C. and the like), about 125° C. (e.g., 123° C. . . . 123.5° C. . . . 123.8° C. . . . 124.2° C. . . . 124.6° C. . . . 125° C. . . . 125.2° C. and the like) and the like.

In some embodiments, the tin in vapor phase may comprise tetrakis(dimethylamino)tin and the oxygen in vapor phase may comprise water. It is appreciated that any other suitable gaseous tin source and gaseous oxygen source for atomic layer deposition may be adopted in accordance with practical needs.

The method for preparing the perovskite solar cell as described herein may further comprise the steps of: (i) providing an anode including a conductive material; (ii) depositing a perovskite active layer on the anode; (iii) subjecting the perovskite active layer to surface passivation treatment; and (iv) providing the cathode on the electron transport layer by way of thermal evaporation.

In some embodiments, the anode may be a transparent conductive substrate such as a glass deposited with the conductive material as described herein. In these embodiments, step (i) may commence with cleaning the transparent conductive substrate with one or more suitable reagents or solvents such as detergent, deionized water, acetone, isopropanol and the like, under ultrasonication, each for e.g., about 20 to about 30 minutes. After that, the cleaned transparent conductive substrate may be dried optionally in an oven at, e.g., about 100° C., followed by subjecting to oxygen plasma treatment for, e.g. about 10 minutes to about 42 minutes.

Step (ii) may include the steps of: providing a precursor solution comprising CsI, FAI, MAI, MABr, PbBr₂, PbI₂, and SnI₂ according to the formula of CsₓMA_{y}FA_{1-x-y}Sn_{z}Pb_{1-z}I₃₋ₘBrₘ, with x being 0-0.5, y being 0-0.5, z being 0-0.5, m being 0-1.5, and a hole transport material; spin-coating the precursor solution on the anode; and annealing the spin-coated anode to form the perovskite active layer thereon.

In some embodiments, the perovskite precursor materials (i.e., CsI, FAI, MAI, MABr, PbBr₂, PbI₂, and SnI₂) may be mixed in a suitable solvent or solvent mixture such as a mixture of DMF and DMSO, with a volume ratio of, for example about 2:1 to about 15:1, to obtain a perovskite precursor solution. After that, the hole transport material may be mixed with the perovskite precursor solution, with the concentration of the hole transport material being about 0.15 mg/mL to about 1.2 mg/mL (e.g., about 0.15 mg/mL (e.g., 0.13 mg/mL . . . 0.135 mg/mL . . . 0.14 mg/mL . . . 0.146 mg/mL, 0.15 mg/mL . . . 0.151 mg/mL . . . 0.152 mg/mL . . . 0.16 mg/mL and the like), about 0.25 mg/mL (e.g., 0.23 mg/mL . . . 0.235 mg/mL . . . 0.24 mg/mL . . . 0.246 mg/mL, 0.25 mg/mL . . . 0.251 mg/mL . . . 0.252 mg/mL . . . 0.26 mg/mL and the like), about 0.32 mg/mL (e.g., 0.30 mg/mL . . . 0.306 mg/mL . . . 0.31 mg/mL . . . 0.313 mg/mL . . . 0.317 mg/mL . . . 0.32 mg/mL . . . 0.324 mg/mL . . . 0.33 mg/mL and the like), about 0.5 mg/mL (e.g., 0.46 mg/mL . . . 0.484 mg/mL . . . 0.49 mg/mL . . . 0.493 mg/mL . . . 0.497 mg/mL . . . 0.5 mg/mL . . . 0.504 mg/mL . . . 0.51 mg/mL and the like), about 0.8 mg/mL (e.g., 0.75 mg/mL . . . 0.764 mg/mL . . . 0.77 mg/mL . . . 0.773 mg/mL . . . 0.797 mg/mL . . . 0.8 mg/mL . . . 0.804 mg/mL . . . 0.81 mg/mL and the like), about 1.2 mg/mL (e.g., 1.1 mg/mL . . . 1.15 mg/mL . . . 1.18 mg/mL . . . 1.2 mg/mL . . . 1.24 mg/mL . . . 1.26 mg/mL . . . 1.3 mg/mL and the like) and the like) to form the precursor solution. It is believed that by using the precursor solution as described herein, the deposition of both the perovskite material and the hole transport material can completed in one single step. This not only simplifies the fabrication process but also reduces production costs, offering greater scalability and industrialization potential. Furthermore, incorporating the hole transport material into the precursor solution may promote uniform perovskite crystal growth and reduce grain boundary defects during the deposition, ultimately improving the stability and optoelectronic performance of the resulting perovskite active layer.

The precursor solution may then be spin-coated on the anode. In particular, the precursor solution may be added dropwise onto the anode and may be allowed to stand for, e.g., about 5 seconds to about 30 seconds before commencing the spin-coating process. In some embodiments, the spin-coating process may be conducted at about 1000 rpm to about 3500 rpm (such as 990 rpm . . . 1000 rpm . . . 1010 rpm . . . 1100 rpm . . . 1500 rpm . . . 1505 rpm . . . 3460 rpm . . . 3490 rpm . . . 3500 rpm . . . 3530 rpm and the like), followed by being conducted at about 4000 rpm to about 7500 rpm (such as 3970 rpm . . . 3980 rpm . . . 4000 rpm . . . 4010 rpm . . . 4400 rpm . . . 4950 rpm . . . 5000 rpm . . . 5020 rpm . . . 5470 rpm . . . 5500 rpm . . . 7500 rpm . . . 7530 rpm and the like). In particular, about 10 seconds to about 25 seconds before the end of the spin-coating process, chlorobenzene (CB) or ethyl acetate (EA) may be added to the center of the anode. The spin-coated anode may then be annealed on a hotplate at, e.g., about 80° C. to about 150° C. (e.g., 77° C. . . . 80° C. . . . 84° C. . . . 96° C. . . . 100° C. . . . 101° C. . . . 105° C. . . . 117° C. . . . 120° C. . . . 123° C. . . . 125° C. . . . 146° C. . . . 150° C. . . . 153° C. and the like) for, e.g. about 10 minutes to about 90 minutes to form the perovskite active layer.

Step (iii) may comprise the steps of: spin-coating a surface passivating solution including a phenylethylamine salt and a perylene diimide-based compound on the perovskite active layer obtained in step (ii); and annealing the spin-coated perovskite active layer to form a passivation layer thereon.

In some embodiments, the surface passivating solution may be prepared by: dissolving the phenylethylamine salt as described herein, such as with a (initial) concentration of about 0.5 mg/mL to about 4 mg/mL, in a suitable solvent mixture such as IPA:DMF (v/v=about 50:1 to about 300:1) to form a first solution; dissolving the perylene diimide-based compound as described herein, such as with a (initial) concentration of about 0.5 mg/mL to about 8 mg/mL, in a suitable solvent mixture such as IPA:DMF (v/v=about 50:1 to about 300:1) to form a second solution; mixing the first and the second solutions at a volume ratio of about 1:1 to form the surface passivating solution.

The surface passivating solution may then be spin-coated on the perovskite active layer at about 4000 rpm to about 6000 rpm (e.g., 3910 rpm . . . 3950 rpm . . . 3980 rpm . . . 4000 rpm . . . 4030 rpm . . . 4600 rpm . . . 4850 rpm . . . 5000 rpm . . . 5240 rpm . . . 5580 rpm . . . 6000 rpm . . . 6080 rpm and the like) for e.g., about 20 to about 40 seconds. After that, the spin-coated perovskite active layer may be annealed on a hotplate at about 75° C. to about 120° C. (e.g., 73.5° C. . . . 74.4° C. . . . 74.8° C. . . . 75° C. . . . 75.8° C. . . . 97.5° C. . . . 99.1° C. . . . 100° C. . . . 108° C. . . . 108.7° C. . . . 110° C. . . . 110.6° C. . . . 111° C. . . . 118.2° C. . . . 119° C. . . . 120° C. . . . 120.9° C. . . . 121° C. and the like) for, e.g., about 1 minute to about 15 minutes to form the passivation layer.

In step (iv), the cathode may be provided by thermally evaporating a metal as described herein with a thickness of about 50 nm to about 250 nm (e.g., 48.5 nm . . . 49 nm . . . 49.4 nm . . . 49.8 nm . . . 50 nm . . . 50.3 nm . . . 51 nm . . . 73.8 nm . . . 74.5 nm . . . 75 nm . . . 75.7 nm . . . 76 nm . . . 98 nm . . . 98.8 nm . . . 99.1 nm . . . 100 nm . . . 100.2 nm . . . 101 nm . . . 149 nm . . . 149.6 nm . . . 150 nm . . . 150.7 nm . . . 151 nm . . . 248 nm . . . 248.9 nm . . . 249.6 nm . . . 250 nm . . . 250.2 nm . . . 252 nm and the like) at a rate of about 0.2 Å/s to about 3 Å/s (e.g., 0.17 Å/s . . . 0.19 Å/s . . . 0.2 Å/s . . . 0.21 Å/s . . . 0.23 Å/s . . . 0.78 Å/s . . . 0.8 Å/s . . . 0.94 Å/s . . . 1 Å/s . . . 1.05 Å/s . . . 1.1 Å/s . . . 1.7 Å/s . . . 1.88 Å/s . . . 2 Å/s . . . 2.09 Å/s . . . 2.82 Å/s . . . 3 Å/s . . . 3.06 Å/s . . . 3.1 Å/s and the like) under a reduced pressure, such as less than 4×10⁻⁶ Torr, on the top of the second portion of the electron transport layer.

Hereinafter, the present invention is described more specifically by way of examples, but the present invention is not limited thereto.

### EXAMPLES

### Materials and Methods

### Materials

Trifluoromethylphenylethylammonium iodide (CF₃-PEAI) was purchased from Lumtec (Taiwan Luminescence Technology) and Dyenamo (Sweden). Perylene diimide derivative (PDIN) and naphthalenediimide derivative (NDI-N) were purchased from Sigma-Aldrich and TCI (Tokyo Chemical Industry). Tin(II) iodide (SnI₂) was purchased from Alfa Aesar, Sigma-Aldrich, and Strem Chemicals. Carbazole phosphonic acid (2PACz) was purchased from Lumtec and Merck. Methoxy-substituted 2PACz (MeO-2PACz) was purchased from Lumtec and TCI. Fluorine-doped tin oxide conductive glass (FTO) and niobium-doped titanium oxide (NTO) were purchased from NSG Group (Nippon Sheet Glass, Japan) and Xoptica (AGC, China). Methylammonium bromide (MABr) was purchased from TCI and Greatcell Solar Materials (Australia). Bromo-substituted 2PACz (Br-2PACz) and Tetraphenyl-dibromo-carbazole derivative (4PADBC) were purchased from Lumtec. Methoxyphenylethylammonium iodide (CH₃O-PEAI) and tetrafluorophenylethylammonium iodide (4F-PEAI) were purchased from Xi'an Polymer Light Technology (China) and Dyenamo (Sweden). Perylene diimide N-oxide (PDINO) was purchased from Sigma-Aldrich and 1-Material (Canada). Aluminum-doped zinc oxide (AZO) was purchased from AGC (Asahi Glass, Japan) and Umicore (Belgium). Carbazole-based compounds (CbzBF/CbzBT) were purchased from Lumtec and Ossila (UK). Ethyl Acetate (EA) was purchased from Fisher Chemical, Sinopharm Group (China). Gallium-doped zinc oxide (GZO) was purchased from Mitsubishi Materials (Japan). Phenylethylammonium chloride (PEACl) was purchased from TCI and Aladdin Reagent (China). Phenylethylammonium iodide (PEAI) was purchased from Greatcell Solar Materials, Xi'an Polymer Light Technology.

Formamidinium iodide (FAI) and cesium iodide (CsI) were purchased from Dysol (Australia). Lead iodide (PbI₂), lead bromide (PbBr₂) and [4-(3,6-Dimethyl-9H-carbazol-9-yl)butyl]phosphonic acid (Me-4PACz) were purchased from TCI (Japan). aliphatic amine-functionalized perylene-diimide (PDINN) was purchased from Beijing Organtec Co., Ltd (China). C60, bathocuproine (BCP), 3-fluoro-phenethylammonium iodide (m-F-PEAI), methylammonium chloride (MACI), and propylammonium chloride (PACl) were purchased from Xi'an Polymer Light Technology Corporation (China). Tetrakis(dimethylamino)tin (TDMASn) was purchased from Shanghai Oriphant Chemistry Co., Ltd (China). The solvents, including dimethylformamide (DMF), dimethyl sulfoxide (DMSO), isopropanol (IPA) and chlorobenzene (CB) were purchased from J&K (China) and used as received. High purity silver and gold were purchased from commercial sources. 1.1 mm glass substrates patterned with indium tin oxide (ITO) (15 Ωsq⁻¹) were received from Mishi Tech. Co., Ltd. (China).

### Characterization

The X-ray photo-electron spectroscopy (XPS) measurements were conducted by AXIS Supra XPS system. The system was equipped with a monochromatic Al Kα X-ray source (1486.6 eV). The base pressure during the measurements was maintained at approximately 10⁻⁹ mbar. Survey scans were performed to identify the elemental composition, while high-resolution scans were used to analyze the chemical states of specific elements. The binding energies were calibrated using the C Is peak at 284.8 eV as a reference.

The steady-state photoluminescence (PL) spectra were obtained by Edinburgh FLS980 applied with an excitation wavelength of 375 nm. The system was equipped with a photomultiplier tube (PMT) detector for steady-state measurements and a time-correlated single photon counting (TCSPC) module for time-resolved measurements. The emission spectra were recorded in the range of 600˜900 nm with a step size of 1 nm.

The film thickness of SnOₓ and SnOₓ₍ᵢ₎ was obtained by DektakXT stylus profiler. The sample preparation involved adhering tape to half of the substrate, and removing it after the deposition of SnOₓ. This process creates a thickness step at the regions with and without tape, allowing for the measurement of SnOₓ deposition thickness. The probe scanning distance was set to 1000 μm to ensure the probe could traverse the thickness step.

The UV-vis spectrometer (Perkin Elmer model Lambda 2S) system was used to record ultraviolet-visible (UV-vis) absorptions of films. The measurements were conducted over a wavelength range of 300˜900 nm with a step size of 1 nm. The system was equipped with a double-beam optical configuration to ensure high stability and accuracy. The baseline correction was performed using a reference sample to account for any background noise. The scan speed was set to 240 nm/min.

Ultraviolet photoelectron spectroscopy (UPS) was performed in Thermo ESCALAB 250XI equipped with a helium discharge lamp (hv=21.22 eV). The chamber was evacuated to a base pressure of approximately 10⁻⁹ mbar to ensure minimal contamination during the measurements. The analyzer was calibrated using a clean Au sample to ensure accurate energy measurements. UPS spectra were recorded in the binding energy range of 0 to 25 eV with a step size of 0.05 eV. The work function of the samples was determined by measuring the secondary electron cut-off, while the valence band structure was analyzed starting from the photoemission.

Peak force infrared (PFIR) measurements were performed using a commercial Bruker NanoIR2-FS unit operating in the test range of 900 to 1800 cm⁻¹. The unit integrates an atomic force microscope (AFM) microscope operating in contact mode, which allows high-resolution topographic and chemical mapping of the sample surface. In addition, Fourier transform infrared (FTIR) spectroscopy analysis was performed using a Tensor 27 spectrometer from Bruker, Germany. This technique involves collecting infrared spectra of the intensity and distribution of the C═O stretching vibration of the PDINN molecule at 1650 cm⁻¹.

Space charge limited current (SCLC) were measured on electron-only devices with the configuration of ITO/SnO₂ (spin-coating)/active layer/passivation layer/SnOₓ₍ᵢ₎) (ALD)/SnOₓ (ALD)/Ag, according to the previous reported methods. The J-V characteristics of SCLC measurements were recorded from 0 to 3 V with a 0.02 V step size under dark conditions by using a Keithley 2400 source/meter unit.

Time-of-flight secondary-ion mass spectrometry (TOF-SIMS) measurements were performed using a TOF-SIMS instrument (IonTof M6, Germany). The primary ion used for analysis was Bi³⁺ with an energy of 30 keV and a current of 0.80 pA. The primary ion dose (PID) was 4.09E+12 ions/cm². For sputtering, O²⁺ ions were used with an energy of 1 keV and a current of 400 nA. The sputter area was 400×400 μm², and the sputter ion dose density (SpIDD) was 2.11E+18 ions/cm². The intensity of the detected ions was recorded in arbitrary units (a.u.) over the sputter time, which was measured in seconds. The analysis included various ions such as Sn⁺, Pb⁺, I⁺, CH₅N₂+, In⁺, InO⁺, Ag⁺ and Br⁺, with their intensities plotted against the sputter time to provide insights into the composition and distribution of elements within the sample surface layers.

The photovoltaic performance characteristics (J-V curves) of perovskite solar cells were conducted in a N₂-filled glovebox at room temperature using a Xenon lamp solar simulator (Enlitech, SS-F5, Taiwan). The light power was calibrated to 100 mW cm⁻² by a silicon reference cell (with a KG2 filter). Before J-V measurements, a 125-nm thick magnesium fluoride layer was deposited on the back of ITO substrate for transmittance enhancement. All the devices were measured using a Keithley 2400 source meter under a sweep mode of reverse scan (from 1.20 V to −0.01 V) and forward scan (from −0.01 V to 1.20 V) with the scan rate of 0.01 V s⁻¹, and the delay time was 10 ms. No pre-condition was needed before measurement. The active area was defined and characterized as 0.0510 cm² by metal shadow mask. The stabilized power output was conducted by monitoring the stabilized current density output at the MPP bias (extracted from the reverse scan J-V curves). External quantum efficiency (EQE) measurements were carried out using a QE-R EQE system (Enlitech, Taiwan). Highly sensitive EQE was measured by an integrated system (PECT-600, Enlitech, Taiwan), where the photocurrent was amplified and modulated by a lock-in instrument. Electroluminescence (EL) quantum efficiency (EQEEL) was conducted by applying an external voltage/current source through the instrument (ELCT-3010, Enlitech, Taiwan).

### Stability Tests

Damp heat stability test: The damp heat test was conducted by putting devices at 85° C./85% RH in the environment test chamber. The devices were taken out for J-V measurement after cooling down to room temperature.

Outdoor stability test: For the devices for outdoor testing, the devices were periodically taken back indoors, and measured in air under simulated 1-sun AM1.5 G illumination.

On-off light cycle test: a LED lamp simulated 1-sun AM1.5 G illumination diurnal cycle test (with 12-hour light on and 12-hour light off cycles) was conducted with 42 cycles for about 1008 h.

The long-term operational stability test: the device was operated under 1 sun equivalent LED lamp in an air environment (22±3° C., 46±8% RH). The PSCs were biased at maximum-power-point (MPP) voltage and the power output was tracked by using a multi-potentiostat (CHI1040C, CH Instruments, Inc.). During the MPP test, the current density-voltage (J-V) curves of the devices were obtained every 12 h to get the proper loads for the MPP. For testing at 65° C., the devices were mounted on hotplate. The temperature of the devices was monitored by thermometer regularly.

Thermal cycling test: the devices were placed in the thermal cycling test chamber (Shenzhen Hongruida Environmental Technology Co., Ltd), and underwent temperature cycling from −40° C. (5 minute) to 85° C. (5 minute), at a ramp rate of 200° C. per hour. The devices were taken out the chamber after 50, 100, 200, 400, 600, and 800 cycles, to take the J-V measurements.

The devices requiring encapsulation were sealed using UV encapsulation adhesive (LT-U001, Luminescent Technology Corp.) and glass covered (0.7 mm).

### Density Functional Theory (DFT) Calculations

First-principles density functional theory (DFT) computations were performed with the Vienna Ab Initio Simulation Package (VASP 6.4) to study the geometric, electronic structures of pristine and defect-induced FAPbI₃/SnO_{2±x} heterostructures. The projector augmented wave (PAW) pseudopotentials with the cut-off energy of 600 eV were employed. The generalized gradient approximation (GGA) exchange-correlation functional, Perdew-Burke-Ernzerhof (PBE), with the DFT-D3 dispersion correction method of Grimme with zero-damping was applied to optimize the geometrical structures. During the optimization of the geometries, all structures were allowed to relax until each atom was in mechanical equilibrium without any residual force greater than 10⁻⁴ eV/A. For all the heterojunction systems, we adopted a 20-angstrom vacuum slab to keep the structure largely isolated in the stacking direction. For all the pristine and defect-induced surface calculations, we used the PBE level of theory and 4×4×1 gamma-centered Monkhost-Pack k-point meshing grid. The spin-orbit coupling (SOC) effect was taken into consideration for the strong relativistic effect of the Pb-based perovskite structures.

The electronic orbital constitution are 1s for H, 2s2p for C N and O, 4d5p for Sn and I, Sd6p for Pb. The defect formation energy (DFE) was considered as DFE=E_{def}−(Eₚᵣᵢₛₜᵢₙₑ+Σεᵢ)+q(E_{f}+VBM+V_{corr}), where the E_{def} represents the defect-induced structures and Eₚᵣᵢₛₜᵢₙₑ represents the pristine benchmark structure, and the Σεᵢ means a summation energy of the defect-induced interactions. The latter 3 terms are charge-related corrections, which are the Fermi-level, valence band maximum, and potential corrections. Since VASP 6.4 package cannot deal with the charged heterostructures within vacuum layers accurately, all the defects were considered neutrally-charged (q=0) and the charge-related corrections were negated.

Due to the obvious lattice mismatch between the SnOₓ crystals, PDINN layers and the perovskite frameworks, it is also considered using larger supercells for additional DFT computation for which the data analysis is only based on the PBE+SOC level of theory. For the ultra-large geometric size of PDINN molecule (largest intramolecular distance reaches 52 angst.), which may give very large supercell and strong lattice mismatch, only one amino side chain was kept instead of the two side chains in the original designation, a methyl group was adopted as the other side instead.

Specifically, the combined perovskite-SnOₓ interface system consists of 4-layer SnOₓ slab and 3-layer perovskite frameworks, with a 20-angst. vacuum layer being appended above the heterostructure. The PDINN-containing structures were double-optimized within the sandwich-like insertion of PDINN molecule. For geometrical optimization, the central metal atoms in two terminal layers adjacent to the vacuum slab were fixed and these cores would be excluded from the electronic property calculation of the heterostructure system. As such, the minimum common multiple supercell crystal exhibited a planar mismatch of <1%.

### Example 1

Fabrication of PSC 1 (FTO/Cs_{0.05}MA_{0.5}FA_{0.45}Sn_{0.2}Pb_{0.8}I₃:MeO-2PACz/CF₃-PEAI: PDIN/SnOₓ₍ᵢ₎/SnOₓ/Au)
1. Substrate Treatment: The patterned fluorine-doped tin oxide (FTO) conductive substrate is sequentially ultrasonically cleaned with detergent, deionized water, acetone, and isopropanol, each for 20 minutes. After drying the cleaned substrate in an oven at 100° C., the substrate surface is treated with oxygen plasma for 40 minutes and transferred into a N₂-filled glovebox prior to use.
2. Preparation of Perovskite Solution: CsI, FAI, MAI, PbI₂, and SnI₂ are added together into a DMF:DMSO (volume ratio of 3:1) mixed solvent according to the chemical formula Cs_{0.05}MA_{0.5}FA_{0.45}Sn_{0.2}Pb_{0.8}I₃ to prepare the perovskite precursor solution. After thorough stirring for 1 h, MeO-2PACz is added to the perovskite precursor solution, with its the final concentration in the perovskite precursor solution being 0.15 mg/ml. After thorough mixing, the perovskite solution is formed.
3. Preparation of Perovskite Thin Film: The perovskite solution (100 μL) obtained in step (2) is dropped onto the transparent conductive substrate obtained in step (1) and left to stand for 10 seconds. It is then spin-coated at 2000 rpm for 15 seconds, followed by 6000 rpm for 90 seconds. Chlorobenzene (CB) (300 μL) is dropped onto the center of the film 15 seconds before the final spin-coating ends. The spin-coated perovskite thin film is then annealed on a hotplate at 150° C. for 10 minutes.
4. Surface Passivation Treatment: CF₃-PEAI (concentration of 2 mg/ml) and PDIN (concentration of 6 mg/ml) are separately dissolved in an IPA:DMF (volume ratio of 300:1) mixed solvent. The two solutions are then mixed at a volume ratio of 1:1 and spin-coated onto the perovskite thin film prepared in step (3) under spin-coating conditions of 6000 rpm for 20 seconds, followed by annealing at 120° C. for 10 minutes.
5. Deposition of SnOₓ Electron Transport Layer: SnOₓ and SnOₓ₍ᵢ₎ layers was sequentially deposited on the surface-passivated perovskite thin film obtained in step (4) by atomic layer deposition (ALD) at 95° C. from TDMASn and water. The pulse time for TDMASn:H₂O is 120 ms:10 ms for the deposition of the SnOₓ₍ᵢ₎ interlayer, with a deposition thickness of 5 nm. The pulse time for TDMASn:H₂O is 100 ms:40 ms for the deposition of the SnOₓ transport layer, with a deposition thickness of 25 nm.
6. Electrode Deposition: Under high vacuum (<4×10⁻⁶ Torr), 150 nm of gold is thermally evaporated at a rate of 2 Å/s to form the top electrode of the perovskite solar cell.

### Example 2A

Fabrication of PSC 2A (ITO/Cs_{0.05}FA_{0.95}PbI_{2.94}Br_{0.06}: Me-4PACz/m-F-PEAI: PDINN/SnOₓ₍ᵢ₎/SnOₓ/Ag)
1. Substrate Treatment: The patterned indium tin oxide (ITO) conductive substrate is sequentially ultrasonically cleaned with detergent, deionized water, acetone, and isopropanol, each for 30 minutes. After drying the cleaned substrate in an oven at 100° C., the substrate surface is treated with oxygen plasma for 20 minutes and transferred into a N₂-filled glovebox prior to use.
2. Preparation of Perovskite Solution: CsI, FAI, PbBr₂, and PbI₂ are added together into a DMF:DMSO (volume ratio of 5:1) mixed solvent according to the chemical formula Cs_{0.05}FA_{0.9}PbI_{2.94}Br_{0.06} to prepare the perovskite precursor solution. After thorough stirring for 1 h, Me-4PACz is added to the perovskite precursor solution, with its final concentration in the perovskite precursor solution being 0.32 mg/ml. After thorough mixing, the perovskite solution is formed.
3. Preparation of Perovskite Thin Film: The perovskite solution obtained in step (2) is dropped onto the transparent conductive substrate obtained in step (1) and left to stand for 30 seconds. It is then spin-coated at 1500 rpm for 5 seconds, followed by 5500 rpm for 45 seconds. Chlorobenzene (CB) is dropped onto the center of the film 15 seconds before the final spin-coating ends. The spin-coated perovskite thin film is then annealed on a hotplate at 100° C. for 40 minutes.
4. Surface Passivation Treatment: m-F-PEAI (concentration of 2 mg/ml) and PDINN (concentration of 2 mg/ml) are separately dissolved in an IPA:DMF (volume ratio of 150:1) mixed solvent. The two solutions are then mixed at a volume ratio of 1:1 and spin-coated onto the perovskite thin film prepared in step (3) under spin-coating conditions of 5000 rpm for 30 seconds, followed by annealing at 100° C. for 30 minutes.

In any case if the PDINN precipitates out of solution or if the PDINN film exhibits aggregation (under an optical microscope) then trifluoroethanol may be substituted for IPA to increase solubility. The spin-coating processes were conducted in N₂-filled glovebox with a controlled temperature of 19˜24° C. by the integrated air-conditioner, and the water and oxygen level should be both controlled at less than 5 ppm.
5. Deposition of SnOₓ Electron Transport Layer: SnOₓ and SnOₓ₍ᵢ₎ layers was deposited on the surface-passivated perovskite thin film obtained in step (4) by atomic layer deposition (ALD) at 95° C. from TDMASn and water. The pulse time for TDMASn:H₂O is 200 ms:20 ms for the deposition of the SnOₓ₍ᵢ₎ interlayer, with a deposition thickness of 3 nm. The pulse time for TDMASn:H₂O is 50 ms:20 ms for the deposition of the SnOₓ transport layer, with a deposition thickness of 35 nm.
6. Electrode Deposition: Under high vacuum (<4×10⁻⁶ Torr), 100 nm of silver is thermally evaporated at a rate of 1 Å/s to form the top electrode of the perovskite solar cell.

### Example 2B

Fabrication of PSC 2B (ITO/Cs_{0.05}FA_{0.95}PbI_{2.94}Br_{0.06}: Me-4PACz/m-F-PEAI: PDINN/SnOₓ₍ᵢ₎/SnOₓ/Ag or Au)

This example is slightly modified from Example 2 Å.
1. Substrate Treatment: Glass/ITO substrates (15 Ωsq⁻¹) were sequentially cleaned by sonication with detergent, deionized water, acetone, and isopropyl alcohol for 20 min, respectively. Then, the glass/ITO substrates were dried at 100° C. in an oven, and then were treated with oxygen plasma for 15 min and transferred into a N₂-filled glovebox prior to use.
2. Preparation of Perovskite Solution: The perovskite solution (1.55 M) was prepared by mixing CsI, FAI, PbI₂ and PbBr₂ in 1 ml mixed DMF:DMSO (5:1 in volume) solvent for a chemical formula Cs_{0.05}FA_{0.95}PbI_{2.94}Br_{0.06}. Optionally, 10 mol % of excess PbI₂ was added to improve the device performance, and optionally 10.5 mol % MACI and 3.2 mol % PACl, were added to the perovskite precursor solution and stirred for 1 h. Me-4PACz was then added to the perovskite precursor at a concentration of 0.32 mg/ml, followed by shaking for 30 seconds to form the perovskite solution.
3. Preparation of Perovskite Thin Film: Drop 100 μL of the perovskite solution onto the ITO substrate, allowing it to settle undisturbed for a duration of 15 seconds, and then spin-coated at 1000 rpm for 10 s, subsequently at 5000 rpm for 40 s. 300 μL CB was dripped onto the center of film at 10 s before the end of spin-coating. The deposited perovskite films were subsequently annealed on a hotplate at 100° C. for 35 min.
4. Surface Passivation Treatment: m-F-PEAI (concentration of 2 mg/ml) and PDINN (concentration of 2 mg/ml) are respectively dissolved in a mixed solvent of IPA:DMF (200:1 in volume) and stirred for 1 h. The two solutions were then mixed at a volume ratio of 1:1 and dynamic spun on the as-prepared perovskite films at 5000 rpm for 30 s, then annealing at 100° C. for 10 min.

In any case if the PDINN precipitates out of solution or if the PDINN film exhibits aggregation (under an optical microscope) then trifluoroethanol may be substituted for IPA to increase solubility. The spin-coating processes were conducted in N₂-filled glovebox with a controlled temperature of 19˜24° C. by the integrated air-conditioner, and the water and oxygen level should be both controlled at less than 5 ppm.
5. Deposition of SnOₓ Electron Transport Layer: SnOₓ and SnOₓ₍ᵢ₎ layer were deposited by atomic layer deposition (ALD) at 105° C. from TDMASn and water. The TDMASn precursor was heated to 60° C. and the water source was unheated. Nitrogen chamber and process flow rates were set to 200 and 30 sccm, respectively. The TDMASn was dosed according to a charge-pulse procedure consisting of a 0.3 s nitrogen charge and 0.5 s pulse. a) For the SnOₓ₍ᵢ₎ interlayer, the tin oxide growth consisted of 30 cycles process of the TDMASn dose (200 ms), a purge (the first 10 cycles are 6 s, the 10˜20 cycles are 13 s, and the last 10 cycles are 20 s.), a water dose (20 ms) and a purge (20 s). b) For the SnOₓ transport layer, the tin oxide growth consisted of 300 cycles process of the TDMASn dose (50 ms), a purge (10 s), a water dose (20 ms) and a purge (20 s).
6. Electrode Deposition: 100 nm silver or gold electrode were thermally evaporated at a rate of 1.0 Å/s, respectively, under high vacuum (<4×10⁻⁶ Torr).

### Example 3

Fabrication of PSC 3 (NTO/MA_{0.5}FA_{0.5}Sn_{0.5}Pb_{0.5}I_{2.25}Br_{0.75}: Br-2PACz/CH₃O-PEAI: PDINO/SnOₓ₍ᵢ₎/SnOₓ/Cu)
1. Substrate Treatment: The patterned niobium-doped titanium dioxide (NTO) conductive substrate is sequentially ultrasonically cleaned with detergent, deionized water, acetone, and isopropanol, each for 25 minutes. After drying the cleaned substrate in an oven at 100° C., the substrate surface is treated with oxygen plasma for 10 minutes and transferred into a N₂-filled glovebox prior to use.
2. Preparation of Perovskite Solution: CsI, FAI, MAI, MABr, PbBr₂, PbI₂, and SnI₂ are added together into a DMF:DMSO (volume ratio of 15:1) mixed solvent according to the chemical formula MA_{0.5}FA_{0.5}Sn_{0.5}Pb_{0.5}I_{2.25}Br_{0.75} to prepare the perovskite precursor solution. After thorough stirring for 1 h, Br-2PACz is added to the perovskite precursor solution, with its final concentration in the perovskite precursor solution being 1.2 mg/ml. After thorough mixing, the perovskite solution is formed.
3. Preparation of Perovskite Thin Film: The perovskite solution (100 μL) obtained in step (2) is dropped onto the transparent conductive substrate obtained in step (1) and left to stand for 5 seconds. It is then spin-coated at 3500 rpm for 5 seconds, followed by 7500 rpm for 40 seconds. Chlorobenzene (CB) (300 μL) is dropped onto the center of the film 10 seconds before the final spin-coating ends. The spin-coated perovskite thin film is then annealed on a hotplate at 125° C. for 20 minutes.
4. Surface Passivation Treatment: CH₃O-PEAI (concentration of 0.5 mg/ml) and PDINO (concentration of 0.5 mg/ml) are separately dissolved in an IPA:DMF (volume ratio of 50:1) mixed solvent. The two solutions are then mixed at a volume ratio of 1:1 and spin-coated onto the perovskite thin film prepared in step (3) under spin-coating conditions of 6000 rpm for 20 seconds, followed by annealing at 75° C. for 15 minutes.
5. Deposition of SnOx Electron Transport Layer: SnOₓ and SnOₓ₍ᵢ₎ layers was sequentially deposited on the surface-passivated perovskite thin film obtained in step (4) by atomic layer deposition (ALD) at 85° C. from TDMASn and water. The pulse time for TDMASn:H₂O is 400 ms:10 ms for the deposition of the SnOₓ₍ᵢ₎ interlayer, with a deposition thickness of 5 nm. The pulse time for TDMASn:H₂O is 20 ms:10 ms for the deposition of the SnOₓ transport layer, with a deposition thickness of 50 nm.
6. Electrode Deposition: Under high vacuum (<4×10⁻⁶ Torr), 75 nm of copper is thermally evaporated at a rate of 0.2 Å/s to form the top electrode of the perovskite solar cell.

### Example 4

Fabrication of PSC 4 (AZO/Cs_{0.3}FA_{0.7}PbI_{2.4}Br_{0.6}: CbzBF/4F-PEAI: NDI-N/SnOₓ₍ᵢ₎/SnOₓ/Ni)
1. Substrate Treatment: The patterned aluminum-doped zinc oxide (AZO) conductive substrate is sequentially ultrasonically cleaned with detergent, deionized water, acetone, and isopropanol, each for 30 minutes. After drying the cleaned substrate in an oven, the substrate surface is treated with oxygen plasma for 30 minutes and transferred into a N₂-filled glovebox prior to use.
2. Preparation of Perovskite Solution: CsI, FAI, PbBr₂, and PbI₂ are added together into a DMF:DMSO (volume ratio of 9:1) mixed solvent according to the chemical formula Cs_{0.3}FA_{0.7}PbI_{2.4}Br_{0.6} to prepare the perovskite precursor solution. After thorough stirring for 1 h, CbzBF is added to the perovskite precursor solution, with its final concentration in the perovskite precursor solution being 0.8 mg/ml. After thorough mixing, the perovskite solution is formed.
3. Preparation of Perovskite Thin Film: The perovskite solution (100 μL) obtained in step (2) is dropped onto the transparent conductive substrate obtained in step (1) and left to stand for 20 seconds. It is then spin-coated at 1000 rpm for 10 seconds, followed by 4000 rpm for 30 seconds. Ethyl acetate (EA) is dropped onto the center of the film 15 seconds before the final spin-coating ends. The spin-coated perovskite thin film is then annealed on a hotplate at 80° C. for 90 minutes.
4. Surface Passivation Treatment: 4F-PEAI (concentration of 4 mg/ml) and NDI-N (concentration of 8 mg/ml) are separately dissolved in an IPA:DMF (volume ratio of 250:1) mixed solvent. The two solutions are then mixed at a volume ratio of 1:1 and spin-coated onto the perovskite thin film prepared in step (3) under spin-coating conditions of 4000 rpm for 40 seconds, followed by annealing at 110° C. for 1 minute.
5. Deposition of SnOₓ Electron Transport Layer: SnOₓ and SnOₓ₍ᵢ₎ layers was sequentially deposited on the surface-passivated perovskite thin film obtained in step (4) by atomic layer deposition (ALD) at 125° C. from TDMASn and water. The pulse time for TDMASn:H₂O is 180 ms:5 ms for the deposition of the SnOₓ₍ᵢ₎ interlayer, with a deposition thickness of 10 nm. The pulse time for TDMASn:H₂O is 50 ms:30 ms for the deposition of the SnOₓ transport layer, with a deposition thickness of 15 nm.
6. Electrode Deposition: Under high vacuum (<4×10⁻⁶ Torr), 250 nm of nickel is thermally evaporated at a rate of 3 Å/s to form the top electrode of the perovskite solar cell.

### Example 5

Fabrication of PSC 5 (GZO/Cs_{0.5}FA_{0.5}Sn_{0.5}Pb_{0.5}I_{1.5}Br_{1.5}: CbzBT/PEACl: PDINN/SnOₓ₍ᵢ₎/SnOₓ/Al)
1. Substrate Treatment: The patterned gallium-doped zinc oxide (GZO) conductive substrate is sequentially ultrasonically cleaned with detergent, deionized water, acetone, and isopropanol, each for 20 minutes. After drying the cleaned substrate in an oven, the substrate surface is treated with oxygen plasma for 15 minutes and transferred into a N₂-filled glovebox prior to use.
2. Preparation of Perovskite Solution: CsI, FAI, PbBr₂, PbI₂, and SnI₂ are added together into a DMF:DMSO (volume ratio of 2:1) mixed solvent according to the chemical formula Cs_{0.5}FA_{0.5}Sn_{0.5}Pb_{0.5}I_{1.5}Br_{1.5} to prepare the perovskite precursor solution. After thorough stirring for 1 h, CbzBT is added to the perovskite precursor solution, with its final concentration in the perovskite precursor solution being 0.5 mg/ml. After thorough mixing, the perovskite solution is formed.
3. Preparation of Perovskite Thin Film: The perovskite solution obtained in step (2) is dropped onto the transparent conductive substrate obtained in step (1) and left to stand for 10 seconds. It is then spin-coated at 1500 rpm for 10 seconds, followed by 5000 rpm for 50 seconds. Ethyl acetate (EA) is dropped onto the center of the film 25 seconds before the final spin-coating ends. The spin-coated perovskite thin film is then annealed on a hotplate at 100° C. for 50 minutes.
4. Surface Passivation Treatment: PEACl (concentration of 2 mg/ml) and PDINN (concentration of 3 mg/ml) are separately dissolved in an IPA:DMF (volume ratio of 200:1) mixed solvent. The two solutions are then mixed at a volume ratio of 1:1 and spin-coated onto the perovskite thin film prepared in step (3) under spin-coating conditions of 5000 rpm for 30 seconds, followed by annealing at 100° C. for 5 minutes.

In any case if the PDINN precipitates out of solution or if the PDINN film exhibits aggregation (under an optical microscope) then trifluoroethanol may be substituted for IPA to increase solubility. The spin-coating processes were conducted in N₂-filled glovebox with a controlled temperature of 19˜24° C. by the integrated air-conditioner, and the water and oxygen level should be both controlled at less than 5 ppm.
5. Deposition of SnOₓ Electron Transport Layer: SnOₓ and SnOₓ₍ᵢ₎ layers was deposited on the surface-passivated perovskite thin film obtained in step (4) by atomic layer deposition (ALD) at 105° C. from TDMASn and water. The pulse time for TDMASn:H₂O is 300 ms:20 ms for the deposition of the SnOₓ₍ᵢ₎ interlayer, with a deposition thickness of 2 nm. The pulse time for TDMASn:H₂O is 100 ms:20 ms for the deposition of the SnOₓ transport layer, with a deposition thickness of 30 nm.
6. Electrode Deposition: Under high vacuum (<4×10⁻⁶ Torr), 50 nm of aluminum is thermally evaporated at a rate of 1 Å/s to form the top electrode of the perovskite solar cell.

### Example 6

Fabrication of PSC 6 (ITO/FAPbI₃:4PADBC/PEAI: PDINN/SnOₓ₍ᵢ₎/SnOₓ/Ag)
1. Substrate Treatment: The patterned indium tin oxide (ITO) conductive substrate is sequentially ultrasonically cleaned with detergent, deionized water, acetone, and isopropanol, each for 30 minutes. After drying the cleaned substrate in an oven, the substrate surface is treated with oxygen plasma for 45 minutes and transferred into a N₂-filled glovebox prior to use.
2. Preparation of Perovskite Solution: FAI and PbI₂ are added together into a DMF:DMSO (volume ratio of 4:1) mixed solvent according to the chemical formula FAPbI₃ to prepare the perovskite precursor solution. After thorough stirring for 1 h, 4PADBC is added to the perovskite precursor solution, with its final concentration in the perovskite precursor solution being 0.25 mg/ml. After thorough mixing, the perovskite solution is formed.
3. Preparation of Perovskite Thin Film: The perovskite solution obtained in step (2) is dropped onto the transparent conductive substrate obtained in step (1) and left to stand for 15 seconds. It is then spin-coated at 1000 rpm for 10 seconds, followed by 5000 rpm for 40 seconds. Ethyl acetate (EA) is dropped onto the center of the film 20 seconds before the final spin-coating ends. The spin-coated perovskite thin film is then annealed on a hotplate at 120° C. for 40 minutes.
4. Surface Passivation Treatment: PEAI (concentration of 1 mg/ml) and PDINN (concentration of 4 mg/ml) are separately dissolved in an IPA:DMF (volume ratio of 100:1) mixed solvent. The two solutions are then mixed at a volume ratio of 1:1 and spin-coated onto the perovskite thin film prepared in step (3) under spin-coating conditions of 5000 rpm for 30 seconds, followed by annealing at 120° C. for 5 minutes.

In any case if the PDINN precipitates out of solution or if the PDINN film exhibits aggregation (under an optical microscope) then trifluoroethanol may be substituted for IPA to increase solubility. The spin-coating processes were conducted in N₂-filled glovebox with a controlled temperature of 19˜24° C. by the integrated air-conditioner, and the water and oxygen level should be both controlled at less than 5 ppm.
5. Deposition of SnOₓ Electron Transport Layer: SnOₓ and SnOₓ₍ᵢ₎ layers was deposited on the surface-passivated perovskite thin film obtained in step (4) by atomic layer deposition (ALD) at 110° C. from TDMASn and water. The pulse time for TDMASn:H₂O is 200 ms:20 ms for the deposition of the SnOₓ₍ᵢ₎ interlayer, with a deposition thickness of 2 nm. The pulse time for TDMASn:H₂O is 50 ms:20 ms for the deposition of the SnOₓ transport layer, with a deposition thickness of 40 nm.
6. Electrode Deposition: Under high vacuum (<4×10⁻⁶ Torr), 150 nm of silver is thermally evaporated at a rate of 1 Å/s to form the top electrode of the perovskite solar cell.

### Example 7

Fabrication of Comparative PSC 7 (ITO/Cs_{0.05}FA_{0.95} PbI_{2.94}Br_{0.06}:Me-4PACz/m-F-PEAI: PDINN/C60/BCP/Ag or Au)
1. Substrate Treatment: The patterned indium tin oxide (ITO) conductive substrate is sequentially ultrasonically cleaned with detergent, deionized water, acetone, and isopropanol, each for 30 minutes. After drying the cleaned substrate in an oven, the substrate surface is treated with oxygen plasma for 20 minutes and transferred into a N₂-filled glovebox prior to use.
2. Preparation of Perovskite Solution: CsI, FAI, PbBr, and PbI₂ are added together into a DMF:DMSO (volume ratio of 5:1) mixed solvent according to the chemical formula Cs_{0.05}FA_{0.95} PbI_{2.94}Br_{0.06} to prepare the perovskite precursor solution. After thorough stirring for 1 h, Me-4PACz is added to the perovskite precursor solution, with its final concentration in the perovskite precursor solution being 0.32 mg/ml. After thorough mixing, the perovskite solution is formed.
3. Preparation of Perovskite Thin Film: The perovskite solution obtained in step (2) is dropped onto the transparent conductive substrate obtained in step (1) and left to stand for 30 seconds. It is then spin-coated at 1500 rpm for 5 seconds, followed by 5500 rpm for 45 seconds. Chlorobenzene (CB) is dropped onto the center of the film 15 seconds before the final spin-coating ends. The spin-coated perovskite thin film is then annealed on a hotplate at 100° C. for 40 minutes.
4. Surface Passivation Treatment: m-F-PEAI (concentration of 2 mg/ml) and PDINN (concentration of 2 mg/ml) are separately dissolved in an IPA:DMF (volume ratio of 150:1) mixed solvent. The two solutions are then mixed at a volume ratio of 1:1 and spin-coated onto the perovskite thin film prepared in step (3) under spin-coating conditions of 5000 rpm for 30 seconds, followed by annealing at 100° C. for 30 minutes.

In any case if the PDINN precipitates out of solution or if the PDINN film exhibits aggregation (under an optical microscope) then trifluoroethanol may be substituted for IPA to increase solubility. The spin-coating processes were conducted in N₂-filled glovebox with a controlled temperature of 19˜24° C. by the integrated air-conditioner, and the water and oxygen level should be both controlled at less than 5 ppm.
5. Deposition of C₆₀/BCP Electron Transport Layer: Under high vacuum (<4×10⁻⁶ Torr), 25 nm of C₆₀ is thermally evaporated at a rate of 0.5 Å/s, followed by 6 nm of BCP at a rate of 0.2 Å/s.
6. Electrode Deposition: Under high vacuum (<4×10⁻⁶ Torr), 100 nm of silver or gold is thermally evaporated at a rate of 1 Å/s to form the top electrode of the perovskite solar cell.

### Example 8

### PSC Structural Characterization and Electrochemical Performance

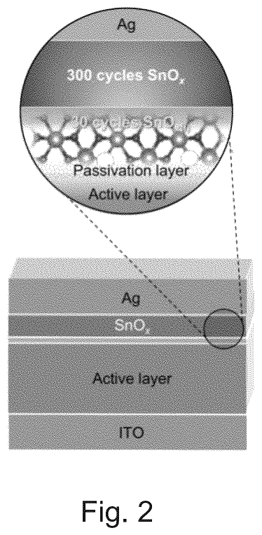

The device structure of the PSCs is a simple stack of glass/ITO/active layer/passivation layer/SnOₓ/Ag (FIG. 2). In this structure, the active layers are composed of Cs_{0.05}FA_{0.95}PbI_{2.94}Br_{0.06} (where FA is formamidinium) doped with [4-(3,6-dimethyl-9H-carbazol-9-yl)butyl]phosphonic acid (Me-4PACz), which was prepared by a one-step chemical deposition that is particularly effective for constructing inverted PSCs. The ETL SnOₓ was deposited on the active layer with ALD.

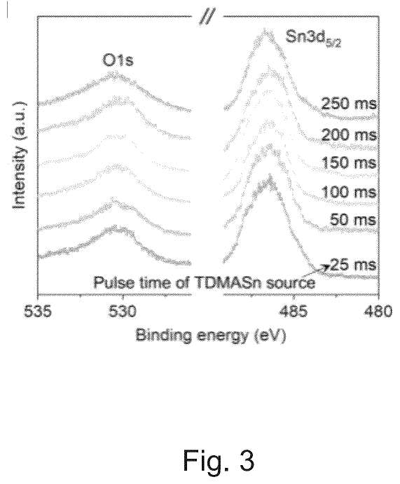

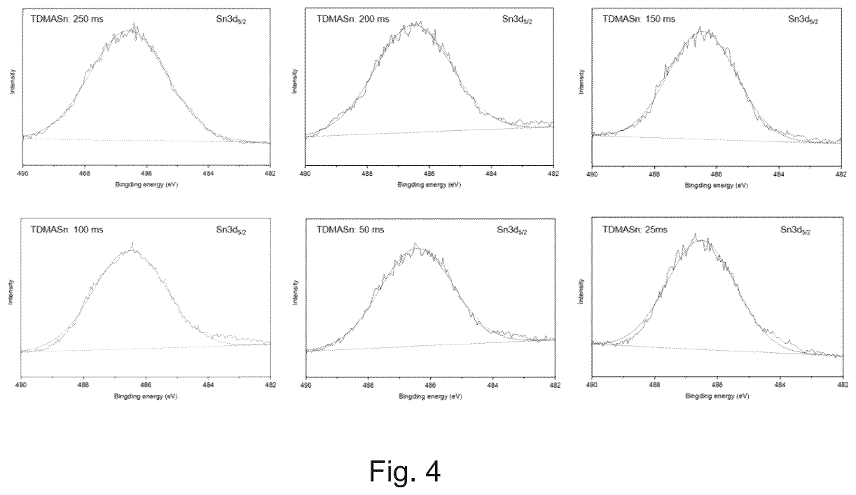

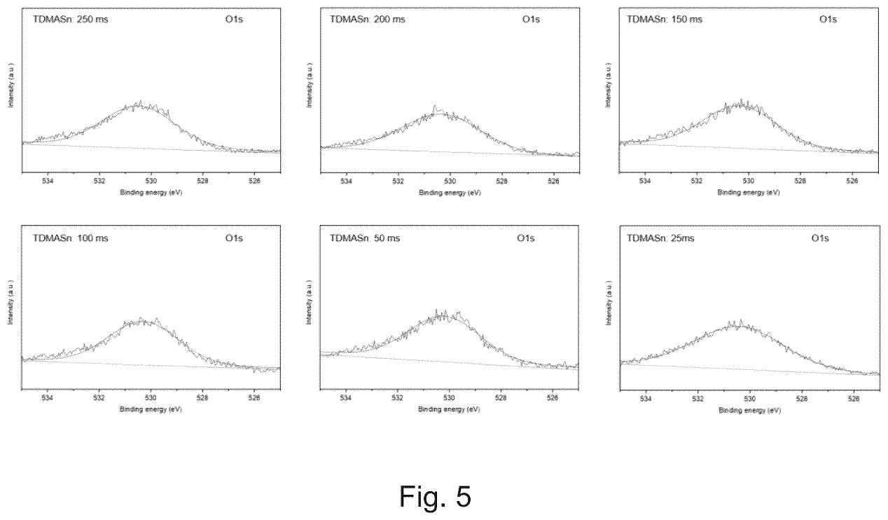

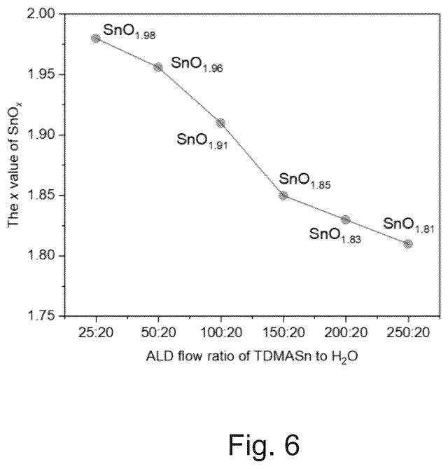

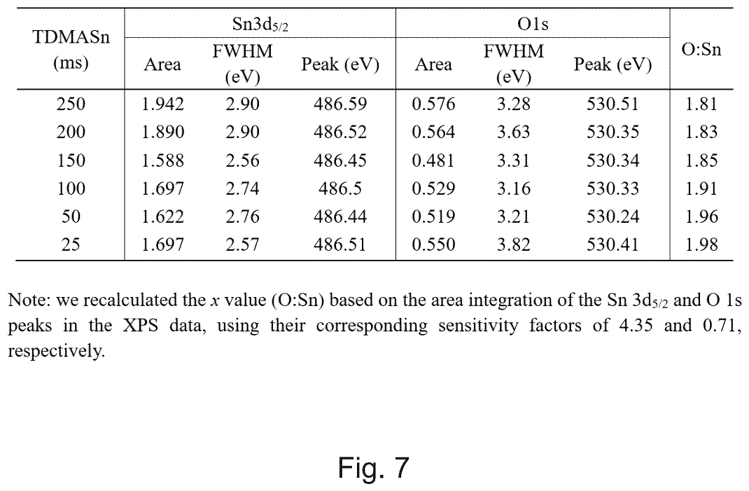

To achieve efficient electron transport, the tetrakisdimethylamino tin(IV) (TDMASn) to water dosing ratios [TDMASn dose (ms):H₂O dose (ms); 25:20, 50:20, 100:20, 150:20, 200:20, and 250:20] and deposition cycles (from 50 to 500 cycles) were modulated. As shown by X-ray photoelectron spectroscopy (XPS) in FIGS. 3 to 7, SnOₓ at the 25:20 ratio was closest to the stoichiometric ratio of SnO₂. As the TDMASn:H₂O ratio increased, the x value of SnOₓ gradually decreased.

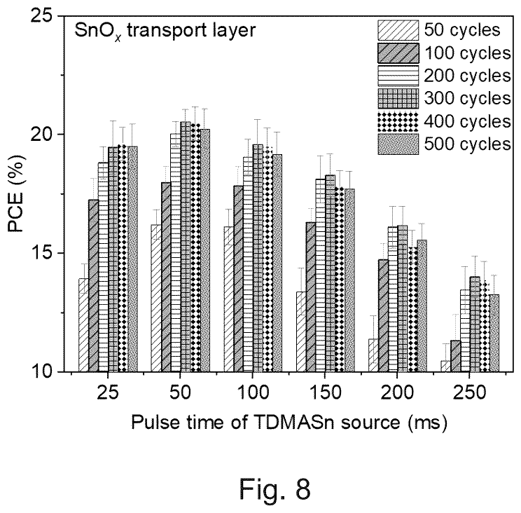

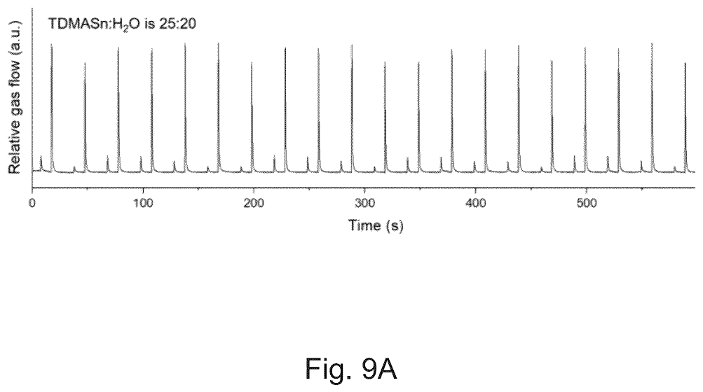

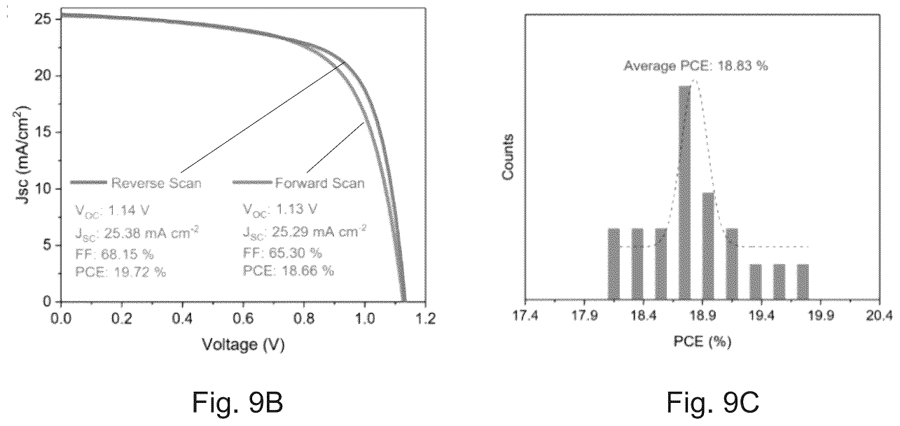

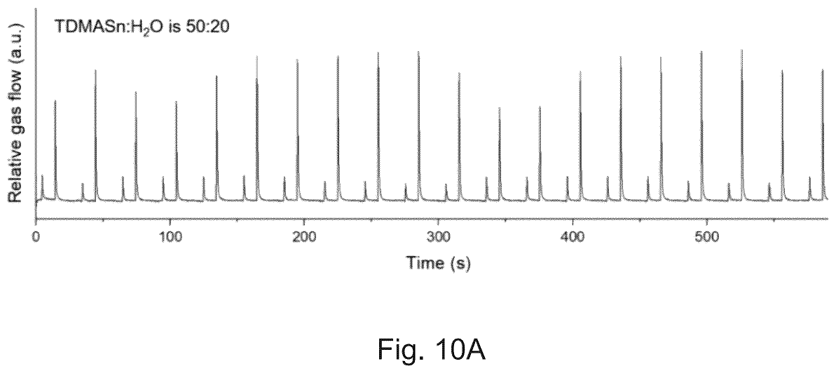

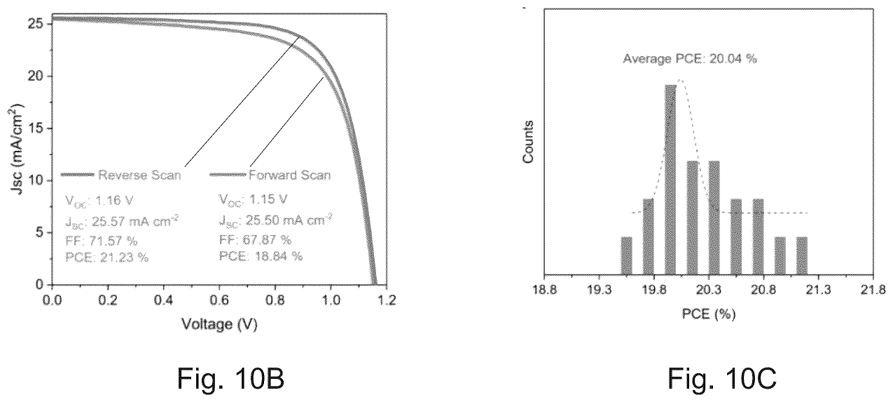

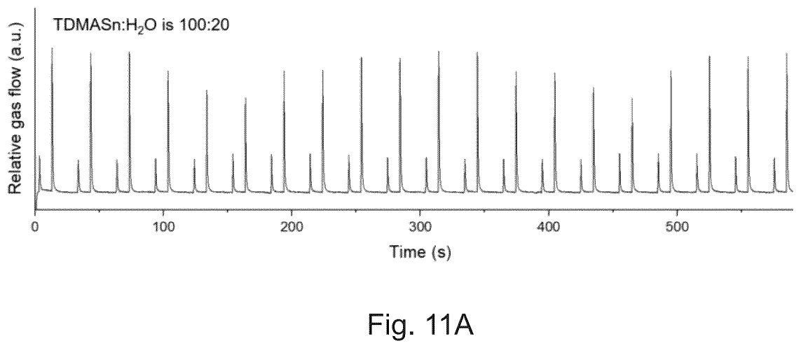

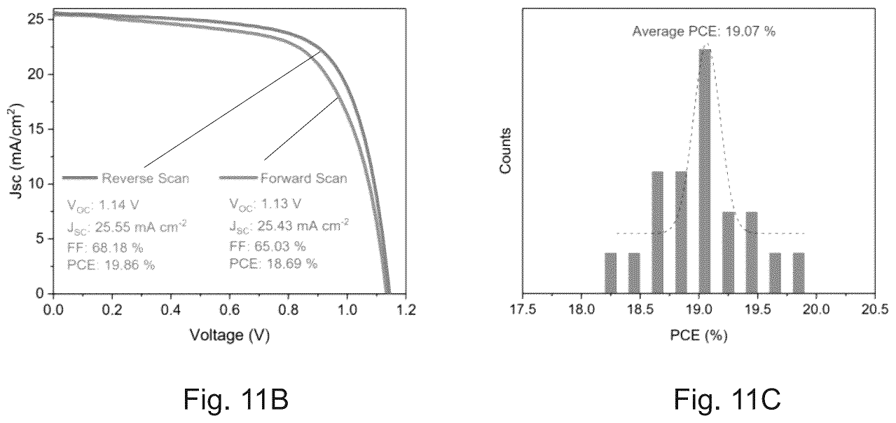

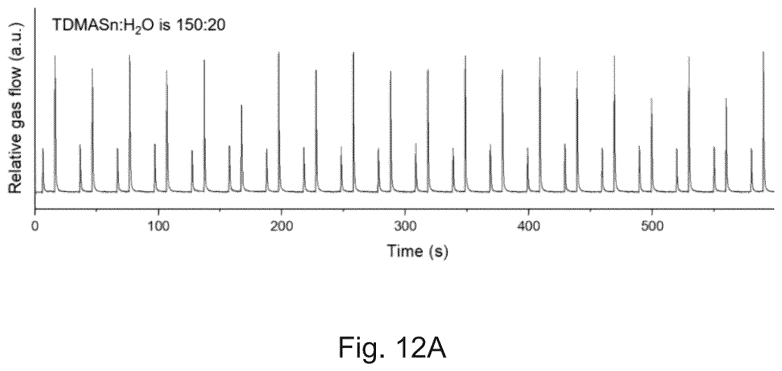

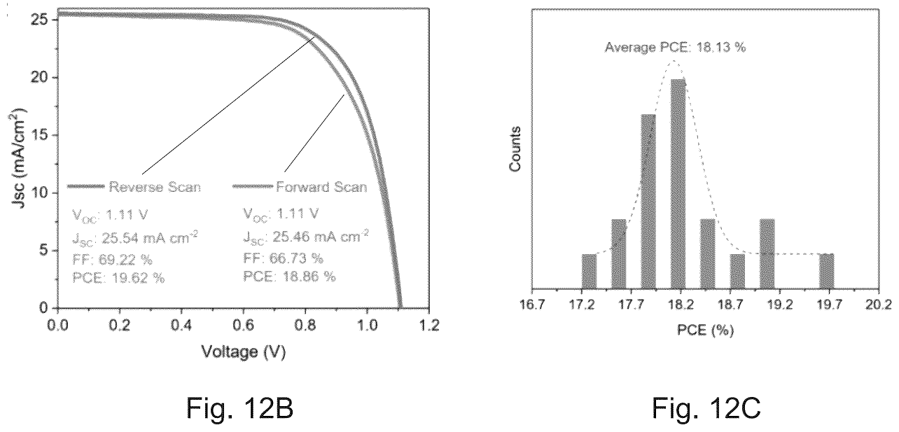

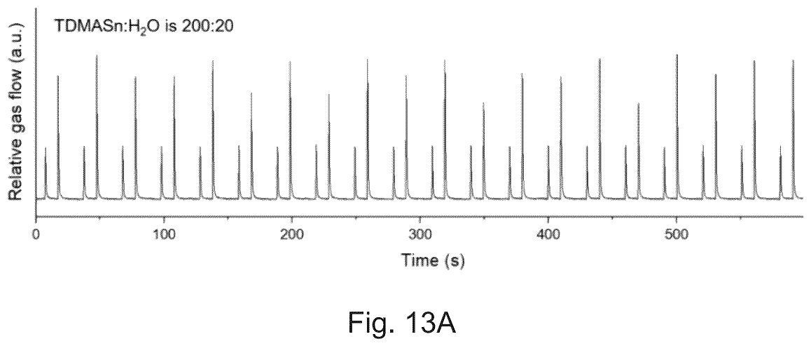

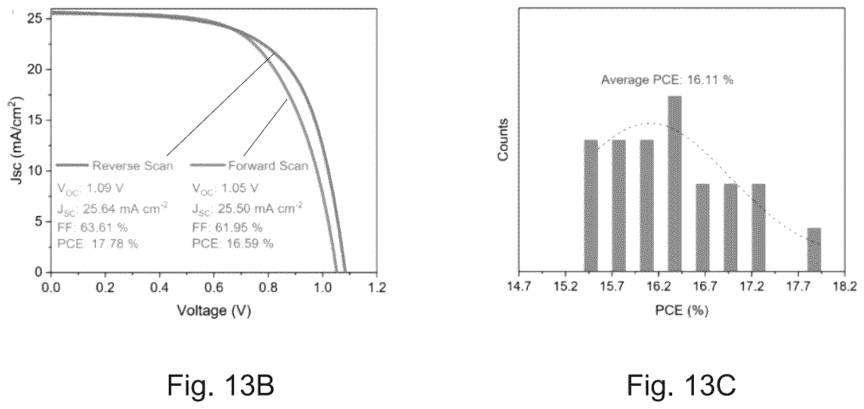

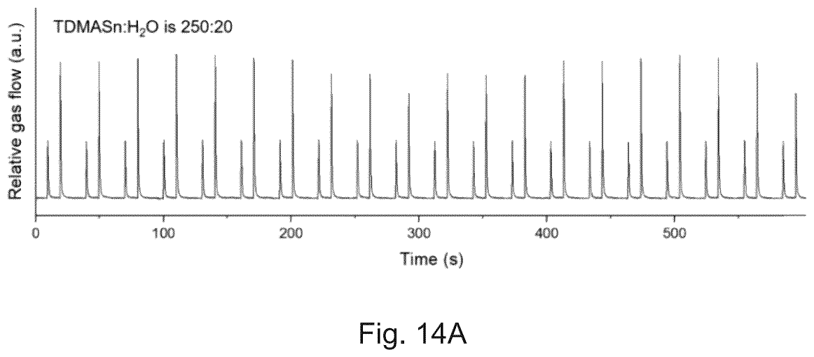

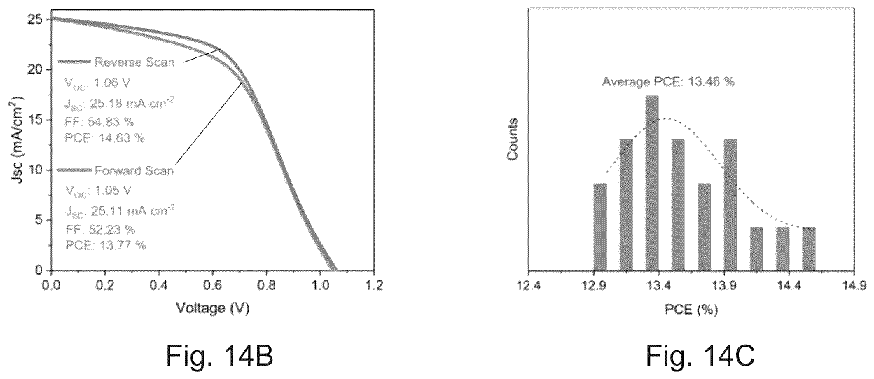

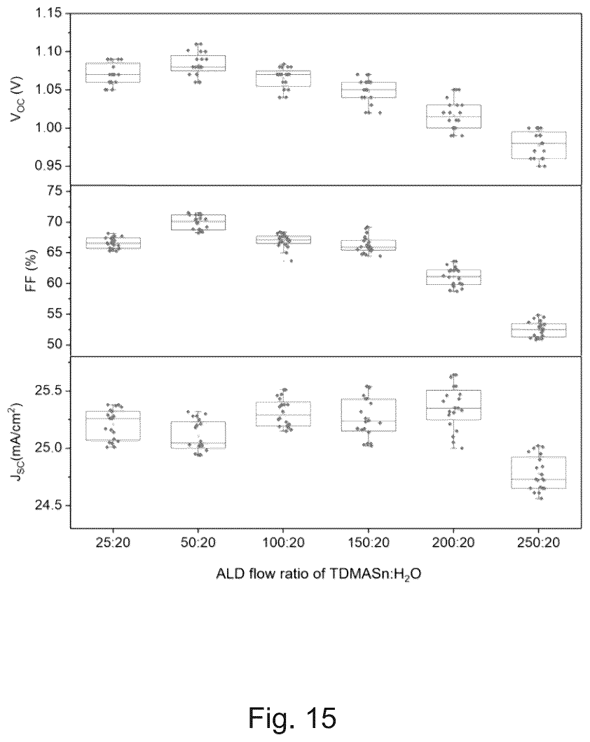

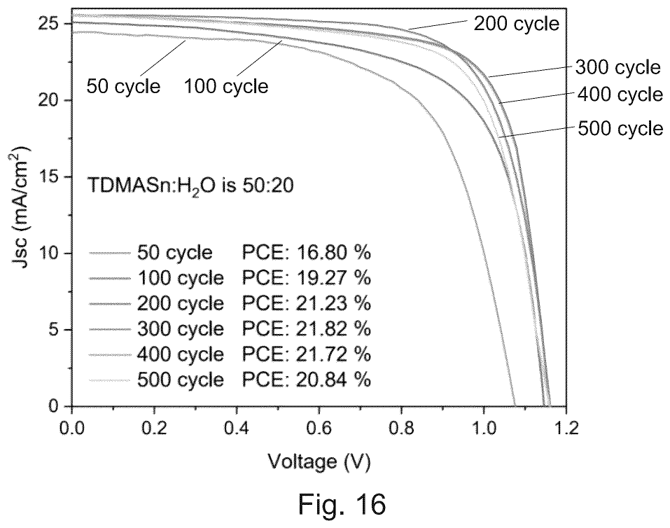

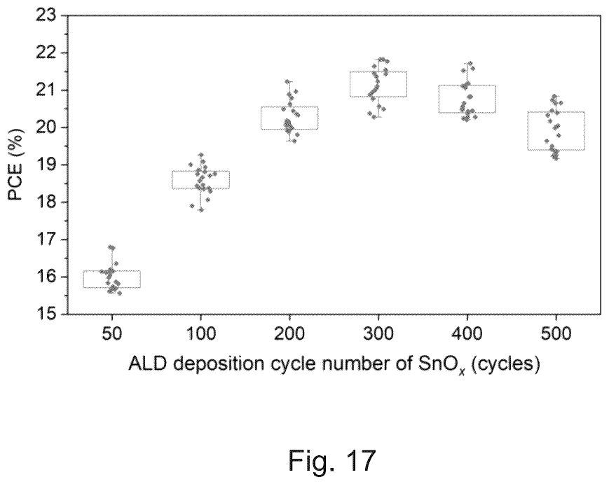

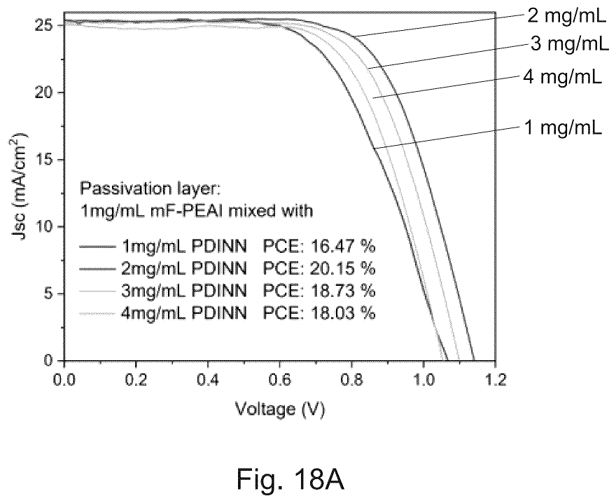

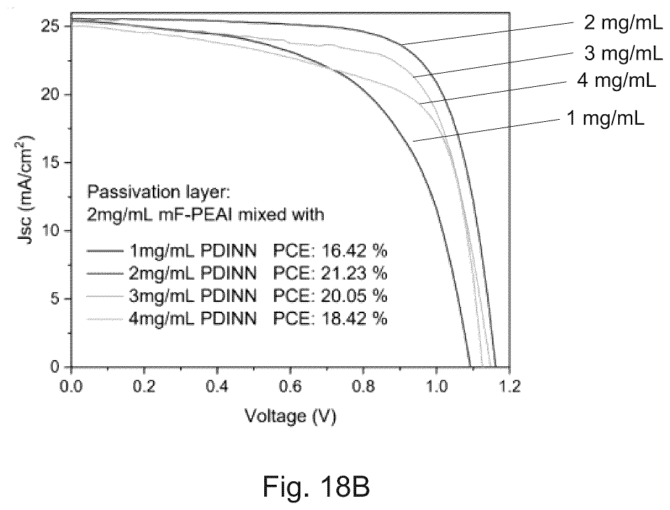

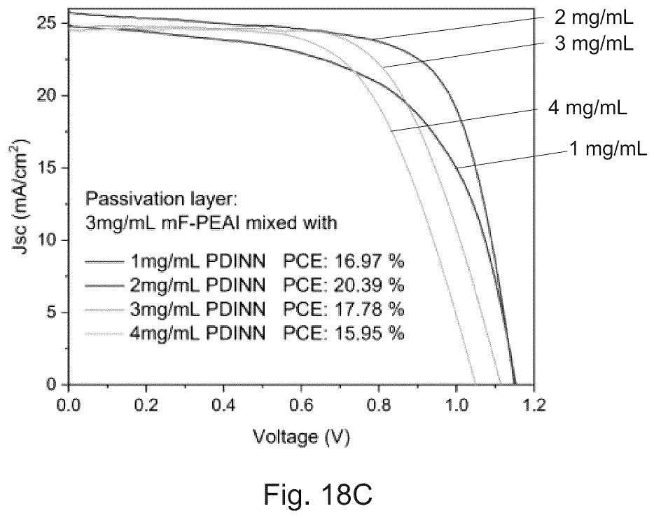

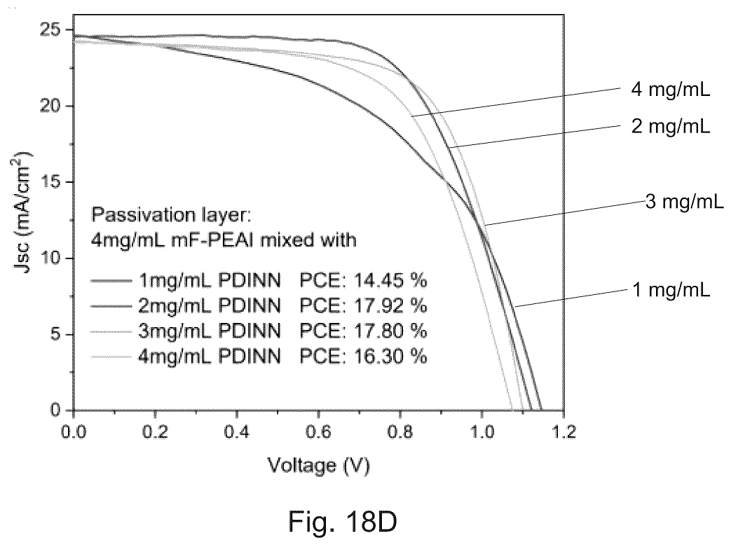

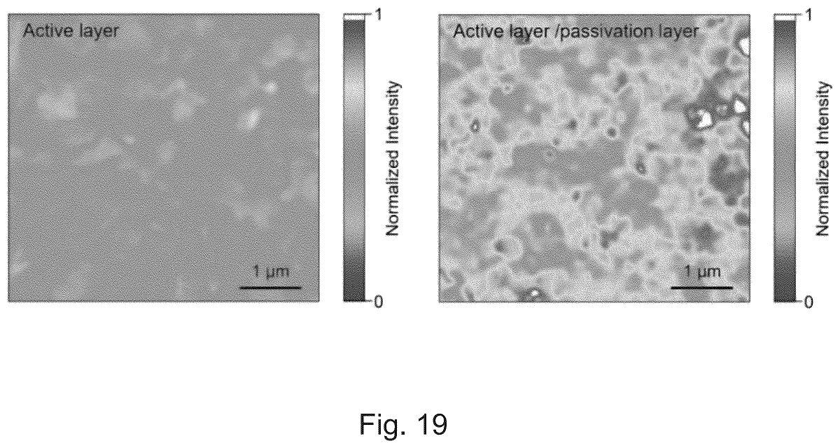

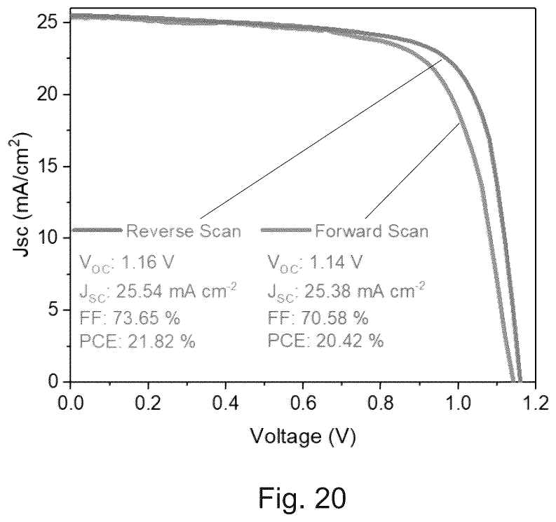

The device performance at different TDMASn:H₂O ratios with varying deposition cycles (FIG. 8, FIGS. 9A to 9C, FIGS. 10A to 10C, FIGS. 11A to 11C, FIGS. 12A to 12C, FIGS. 13A to 13C, FIGS. 14A to 14C, FIGS. 15 to 17) were studied, and the passivation layer was also optimized (FIGS. 18A to 18D and FIG. 19). The investigation revealed an optimized performance with an ALD TDMASn:H₂O dose ratio of 50:20 and a deposition of 300 cycles. Specifically, glass/ITO/active layers/300 cycles SnOₓ (Sn:O=50:20)/Ag, achieved a PCE of 21.8% (as shown in FIG. 20; open-circuit voltage (VOC) of 1.16 V, short-circuit current density (J_{SC}) of 25.5 mA/cm², and fill factor (FF) of 73.7%).

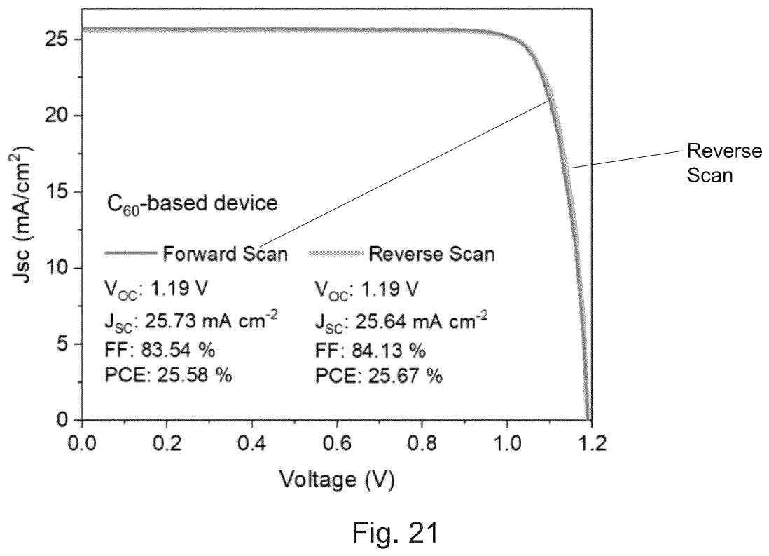

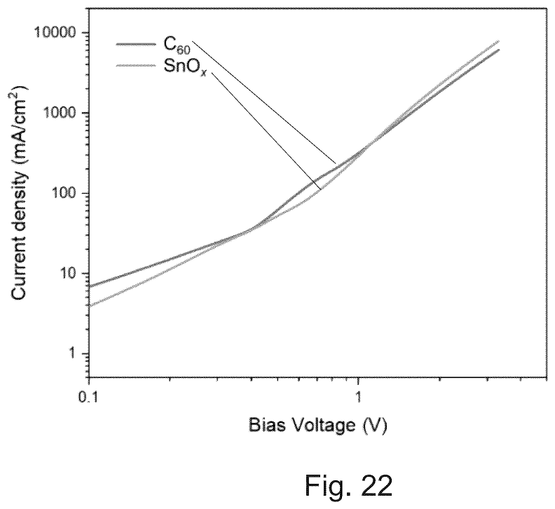

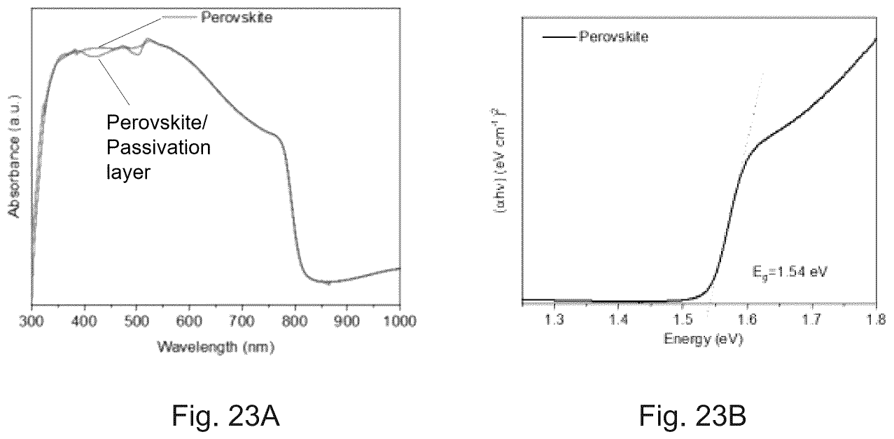

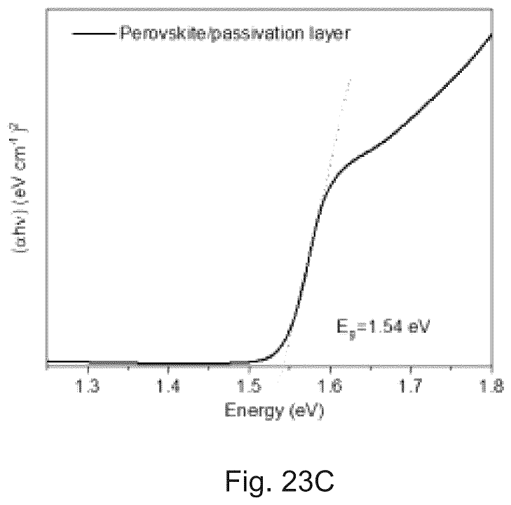

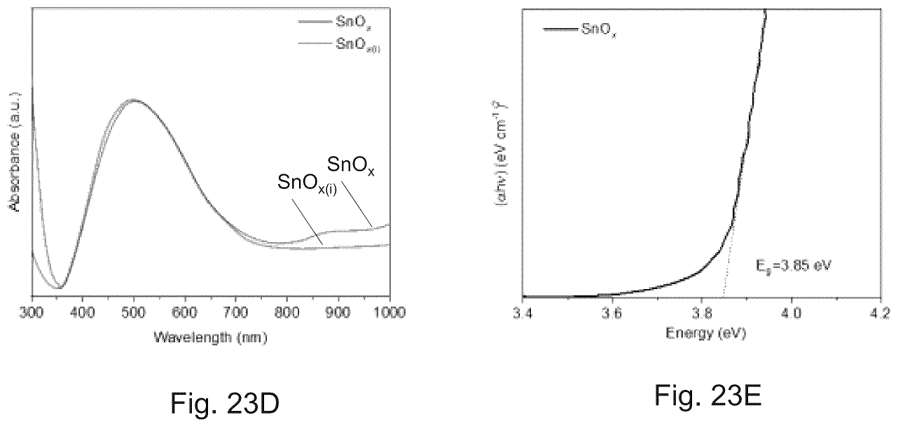

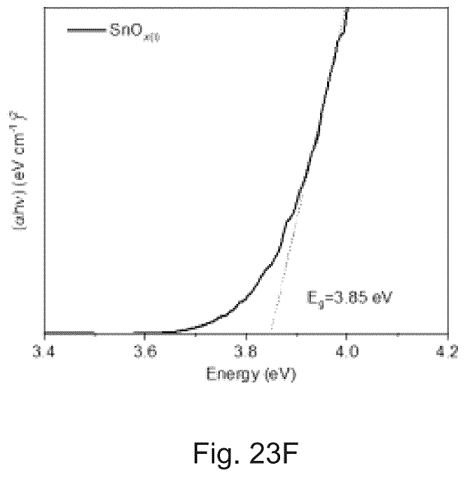

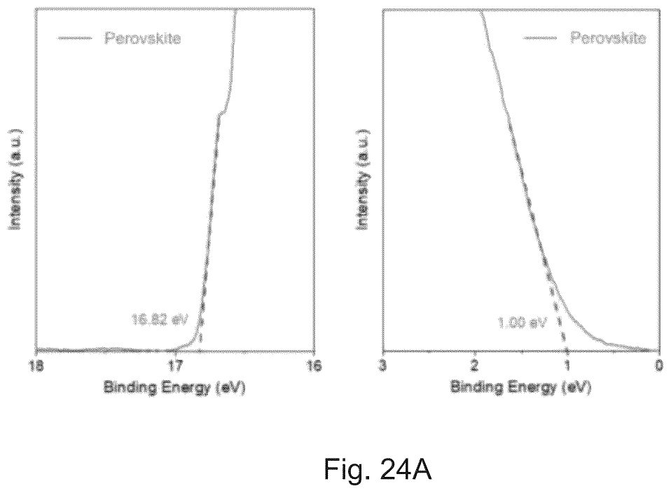

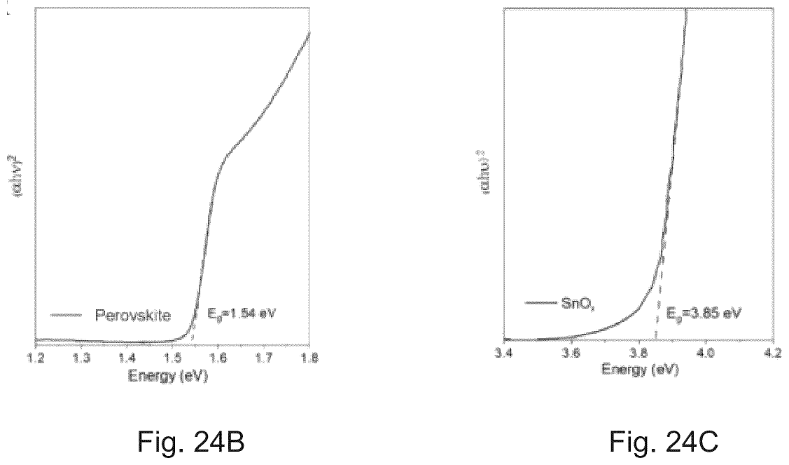

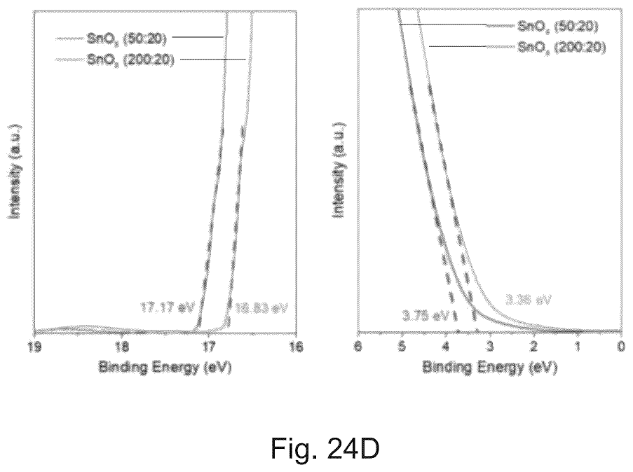

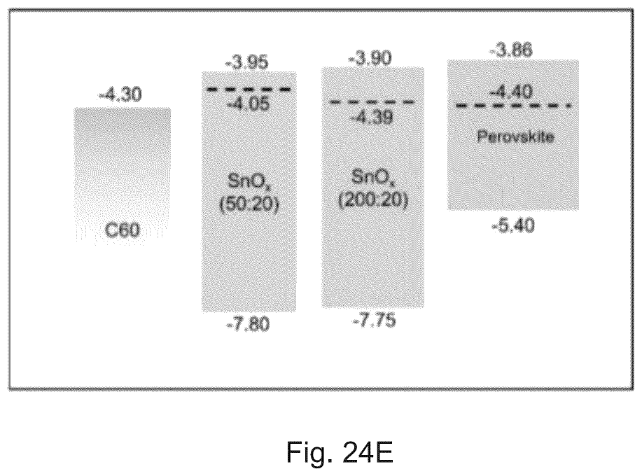

It is noticed a FF deficit for the device using SnOₓ as the ETL compared with the C₆₀-based device (FIG. 21). It is believed that a potential cause of the FF loss may be the transport resistance, although it appears that the difference between the conductivity of C₆₀ and SnOₓ is not significant (FIG. 22). Moreover, ultraviolet-visible (UV-vis) spectroscopy and ultraviolet photoelectron spectroscopy (UPS) in FIGS. 23A to 23F and FIGS. 24A to 24E showed that the conduction band minimum (CBM) of SnOₓ matched that of the active layers better compared with commercial C₆₀, which suggests that the FF loss was independent of the energy misalignment between the ETL and the perovskite active layer.

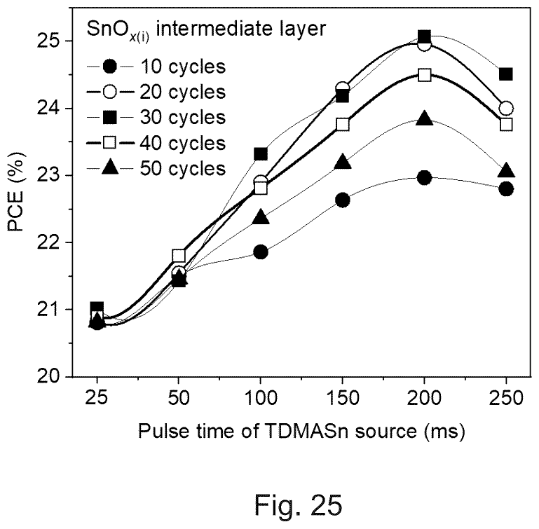

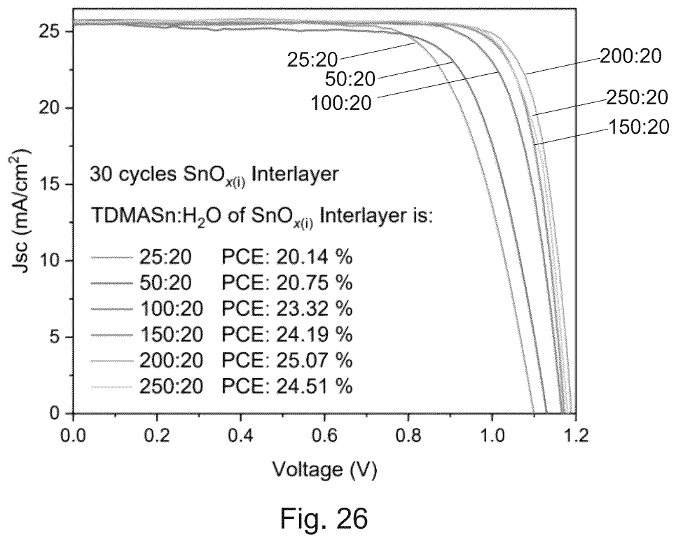

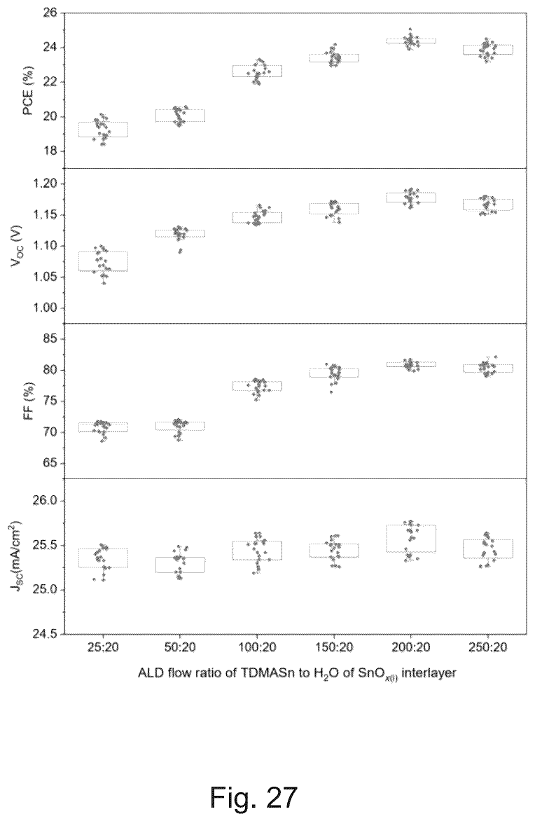

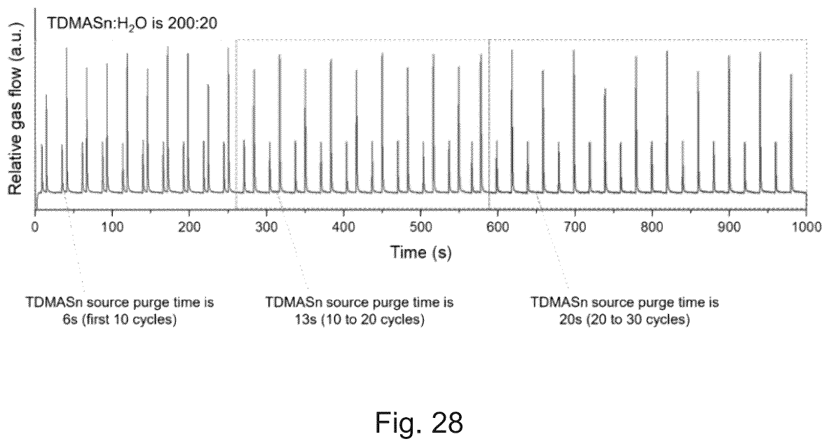

In addition to energy level alignment and transport capabilities, it is believed that the interface between the perovskite and ETL can also determine device performance by affecting carrier extraction efficiency and interfacial defect chemistry. In this case, the interface of SnOₓ in contact with the perovskite was further reengineered. In particular, before preparing the SnOₓ ETL, an interlayer, named SnOₓ₍ᵢ₎, was deposited with different TDMASn:H₂O ratios and cycle numbers for 10 to 50 cycles. When the TDMASn:H₂O ratio of the SnOₓ₍ᵢ₎ interlayer is 200:20 and the deposition 30 cycles (FIGS. 25 to 27; specific process curve shown in FIG. 28), the device achieved the highest PCE of 25.1%.

Without wising to be bound by theory, it is unexpectedly found that, in addition to the Sn source to O source feed ratio (i.e., TDMASn:H₂O ratio), the oxygen vacancies of the interlayer may also be achieved by adjusting the Sn source purge time. In particular, it is believed that the shorter the Sn source purge time, the higher the likelihood of oxygen vacancies in SnOₓ. Specifically, shortening the purge time (from 20 seconds to 6 seconds and 13 seconds) means that the excess TDMASn not involved in the reaction after the previous layer deposition cannot be completely removed. During the next layer deposition, excess Sn deposition occurs, forming Sn-rich/O-vacancy SnOₓ films. in this example, a three-step gradient setting of different Sn source purge times (first 10 cycles-6s; 10-20 cycles: 13s; 20-30 cycles: 20s) was used to achieve the oxygen defect gradient variation in the SnOₓ₍ᵢ₎ intermediate layer.

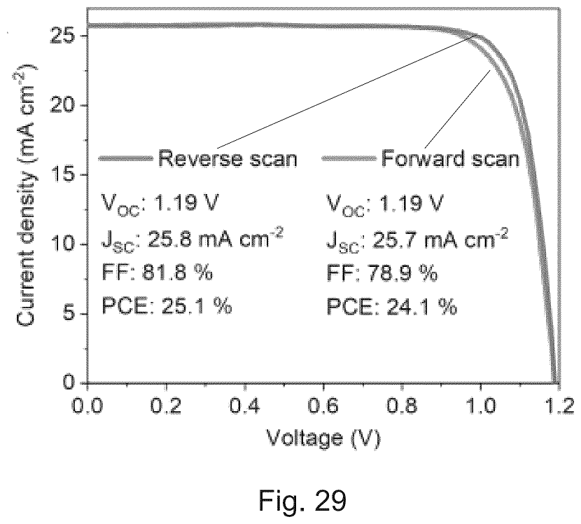

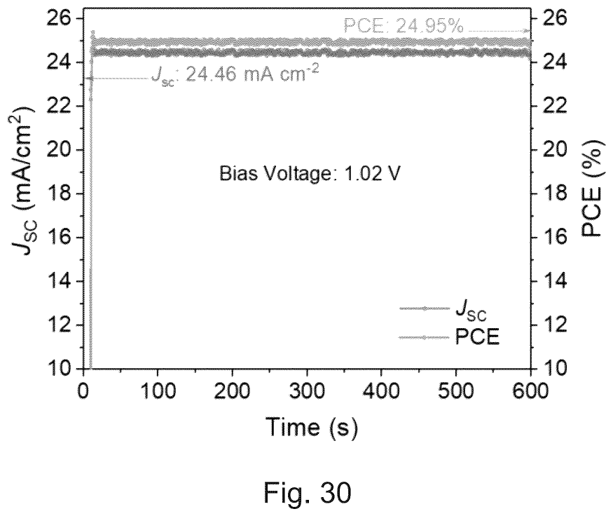

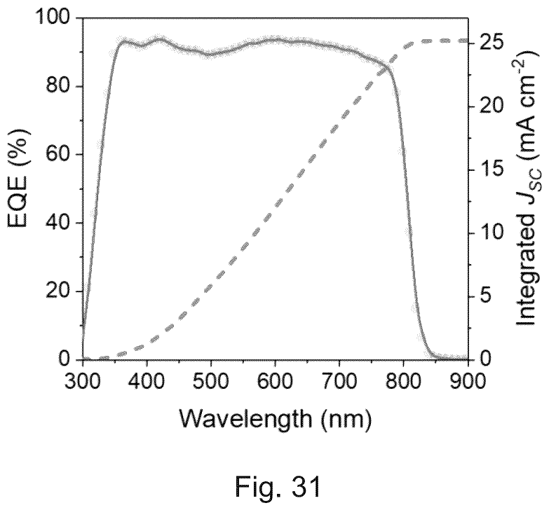

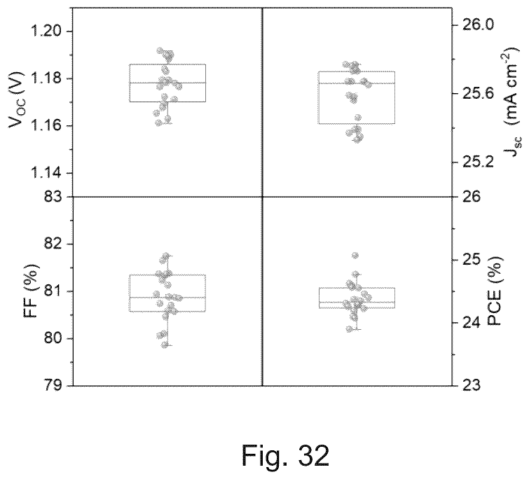

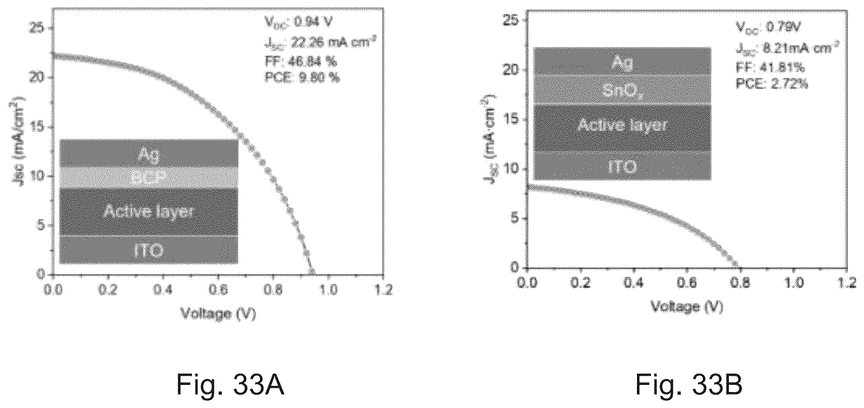

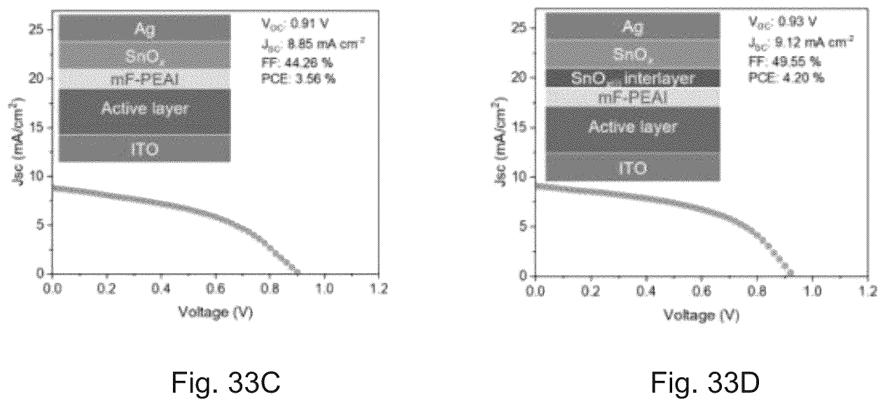

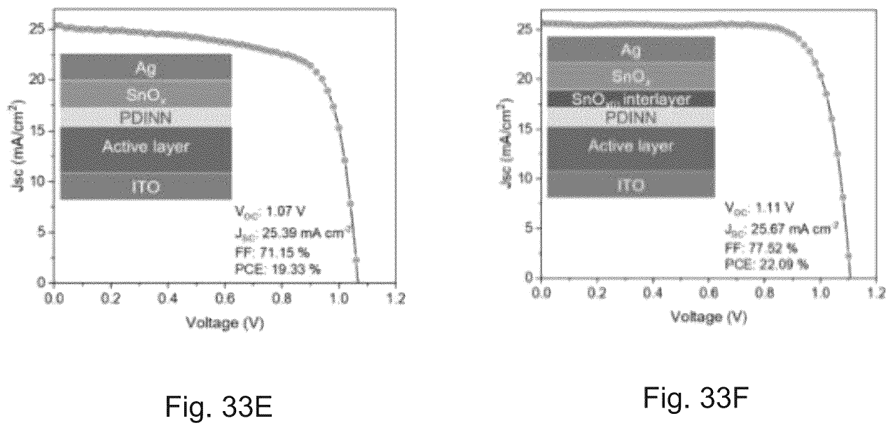

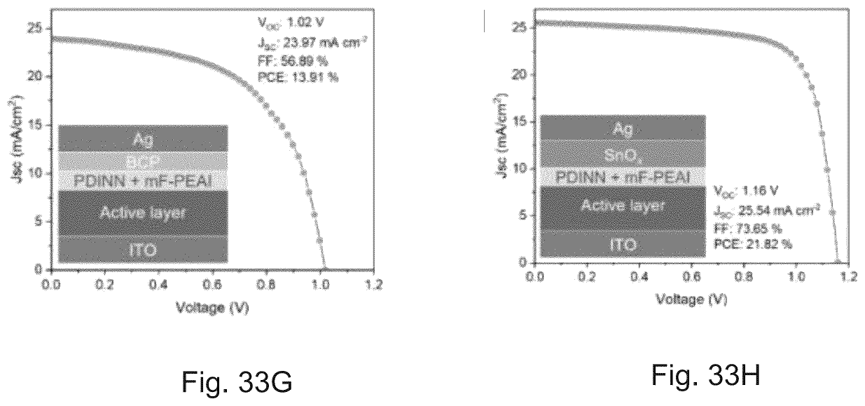

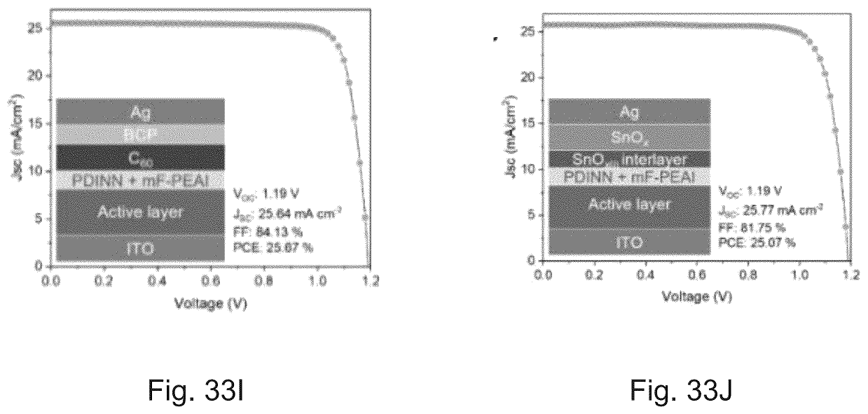

The current density-voltage (J-V) characteristics of the optimized device (FIG. 29) with reverse and forward scans yielded PCEs of 25.1% (V_{OC} of 1.19 V, J_{SC} of 25.8 mA/cm², and FF of 81.8%) and 24.1% (V_{OC} of 1.19 V, J_{SC} of 25.7 mA/cm², and FF of 78.9%), respectively. The corresponding stable power output reached up to 24.95% (as shown in FIG. 30). Corresponding external quantum efficiency (EQE) spectra in FIG. 31 yielded integrated J_{SC} with negligible variation from the values obtained from J-V measurements. Moreover, the process was reproducible, as can be seen from the statistical distribution of all photovoltaic parameters for 20 devices in FIG. 32. The performance comparison of different structural devices involved in this study is shown in FIGS. 33A to 33J.

### Example 9

### Interlayer Characterization

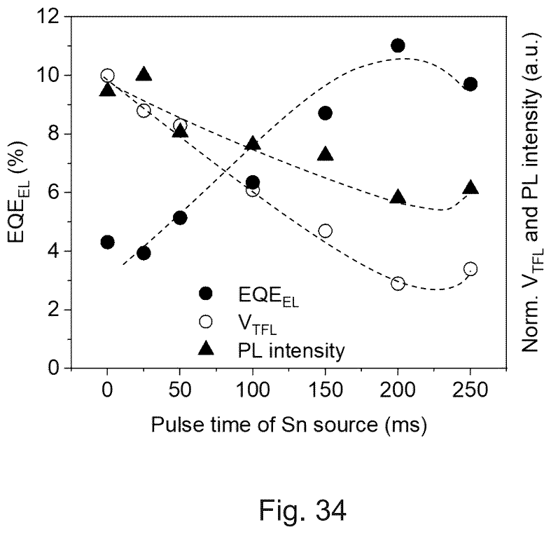

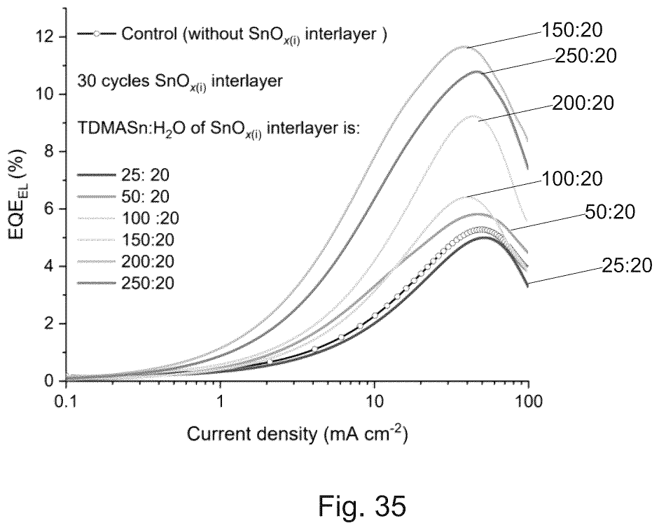

To study the specific effects of the interlayer, electroluminescence quantum efficiency (EQE-EL) and defect density measurements were performed on the devices obtained by depositing the SnOₓ₍ᵢ₎ interlayer with different TDMASn:H₂O ratios, as well as photoluminescence (PL) characterization on the active layer/ETL films (FIG. 34). Compared with the device without the interlayer, the EQE-EL value increased with the increase of the TDMASn:H₂O ratio of the SnOₓ₍ᵢ₎ interlayer, from 3.9% at the TDMASn:H₂O ratio of 25:20 to 11.0% at the TDMASn:H₂O ratio of 200:20 (FIG. 35), which is believed to be attributed to reduced nonradiative recombination and energy loss.

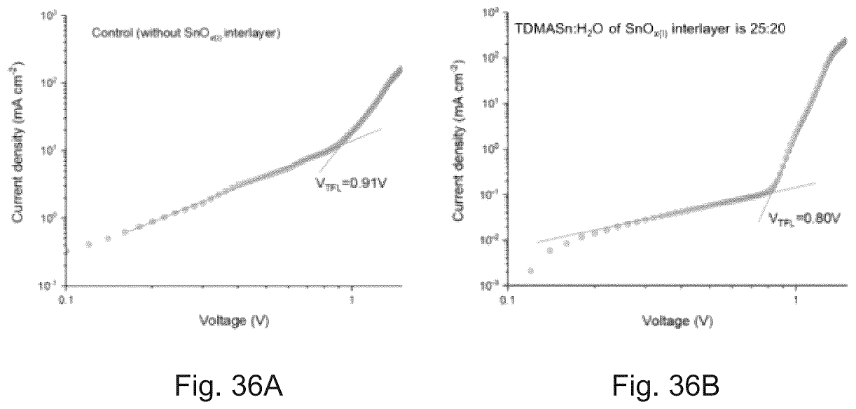

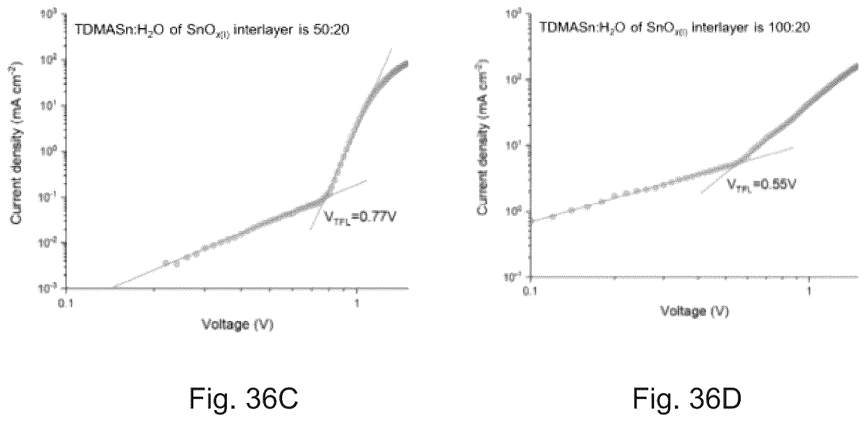

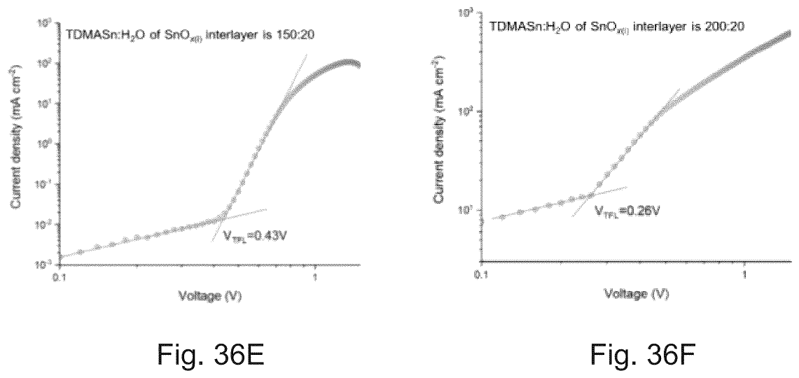

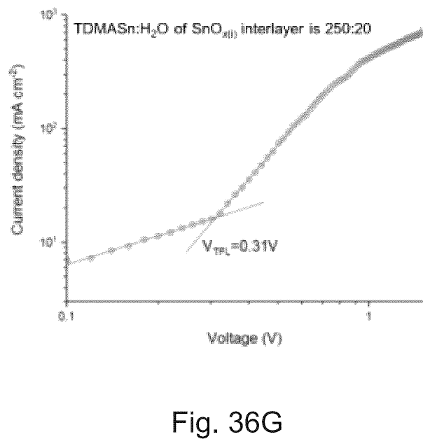

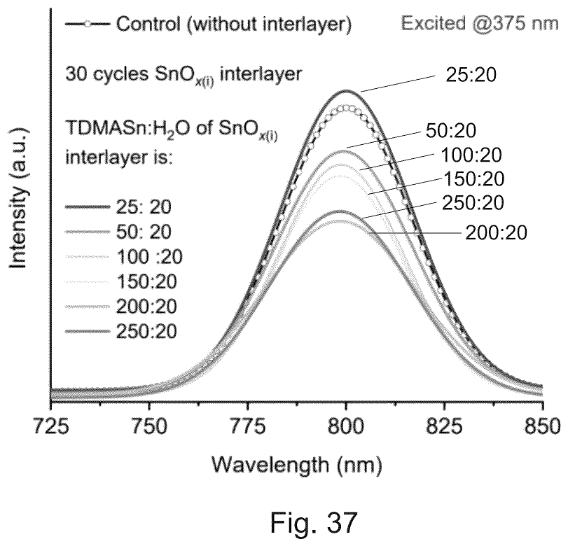

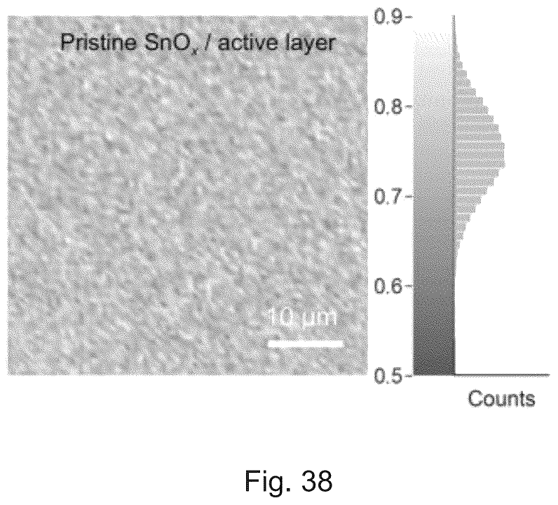

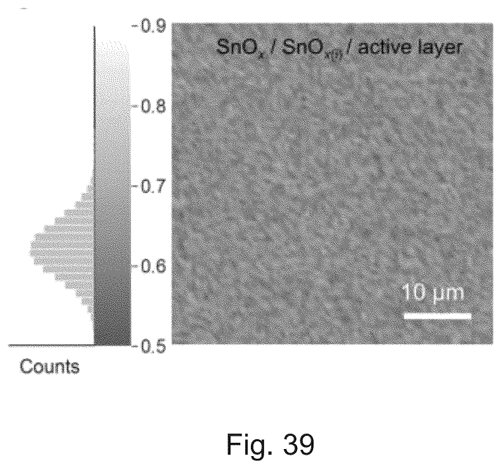

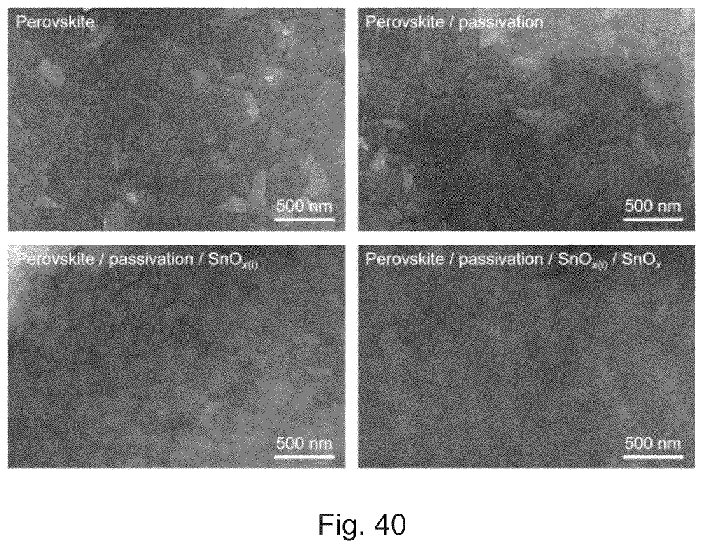

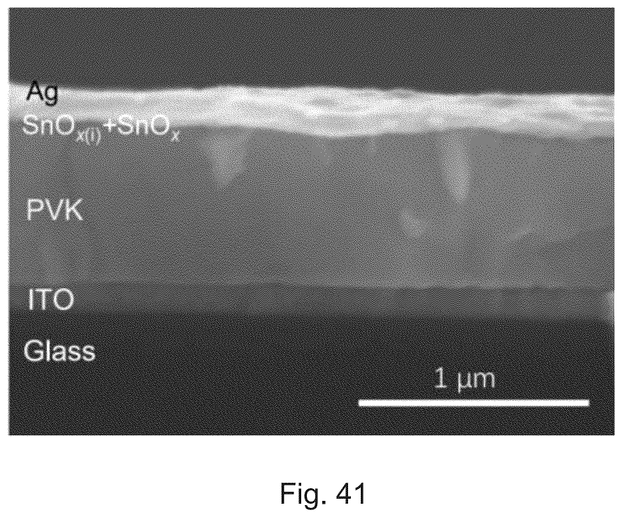

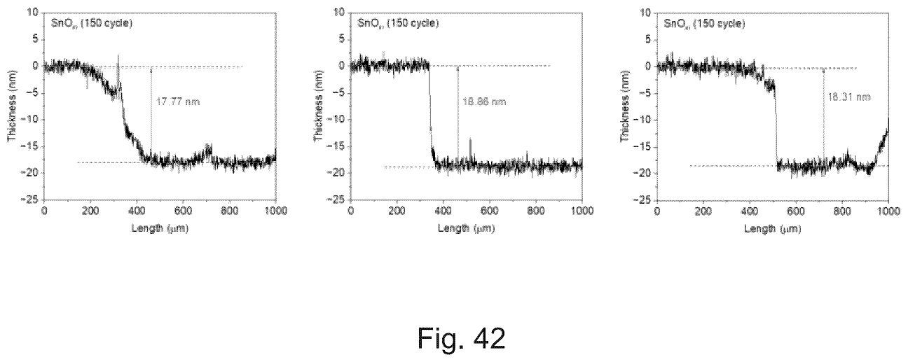

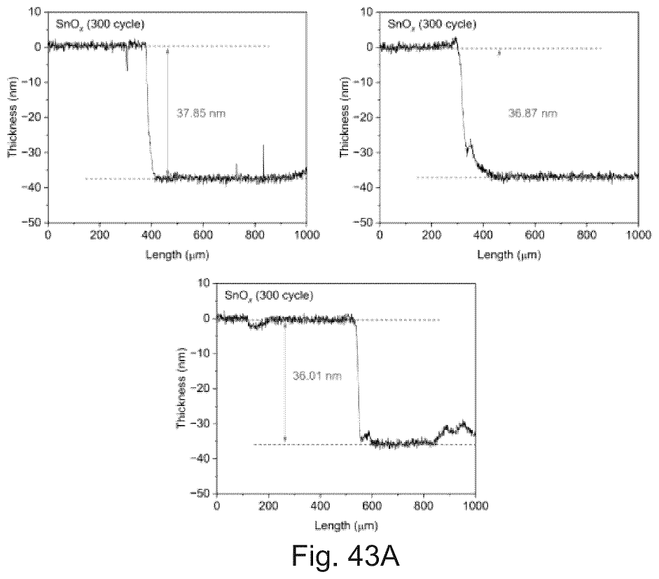

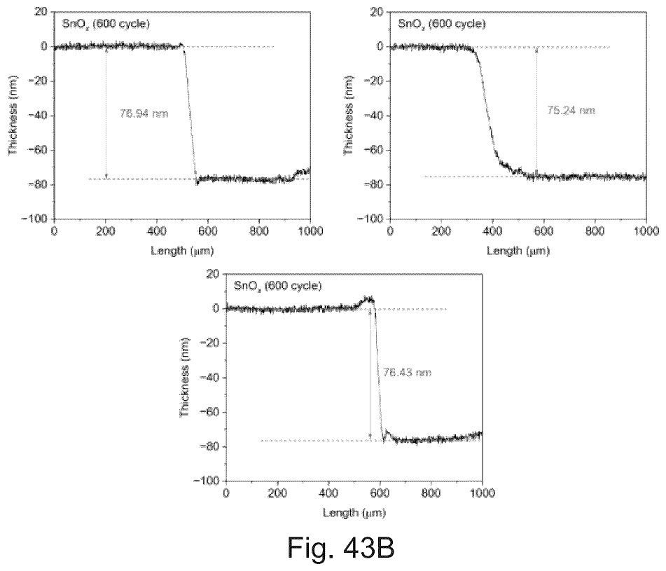

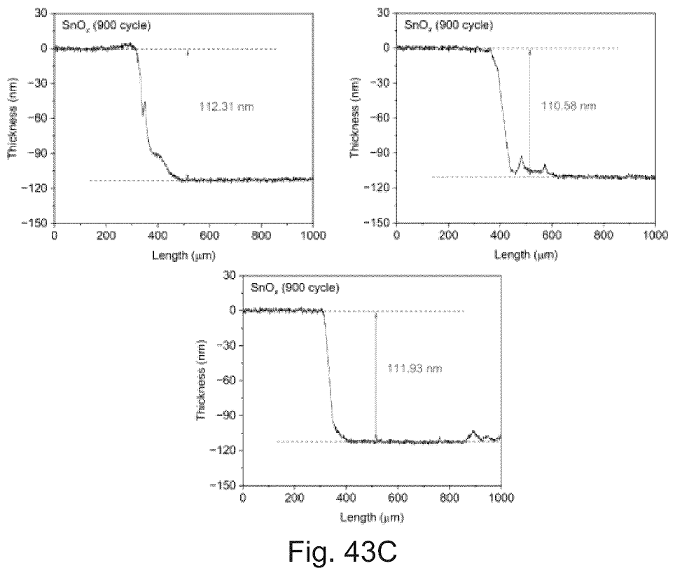

Moreover, the trap-filled limit voltage (V_{TFL}) and PL intensity showed opposite trends. Both decreased gradually with the increase of the TDMASn:H₂O ratio of the SnOₓ₍ᵢ₎ interlayer (specific results are shown in FIGS. 36A to 36G and FIG. 37), which suggests that the oxygen-deficient condition in the SnOₓ₍ᵢ₎ interlayer suppressed defects and promoted carrier extraction. Additionally, PL mapping on the SnOₓ/active layers film and the SnOₓ/SnOₓ₍ᵢ₎/active layers film, respectively (FIGS. 38 and 39), revealed a wide PL intensity distribution for the SnOₓ/active layers indicative of uneven charge extraction. By contrast, the introduction of the SnOₓ₍ᵢ₎ interlayer led to a decrease in PL intensity, and the film showed more uniform PL emission, which further verifies that the carrier extraction in SnOₓ/SnOₓ₍ᵢ₎/active layers was improved and homogenized. The surface morphology of the films treated with SnOₓ and SnOₓ₍ᵢ₎, the cross-section image of the device, and the thickness of the SnOₓ and SnOₓ₍ᵢ₎ films are shown in FIGS. 40 to 42 and FIGS. 43A to 43C.

### Example 10

### Theoretical Studies

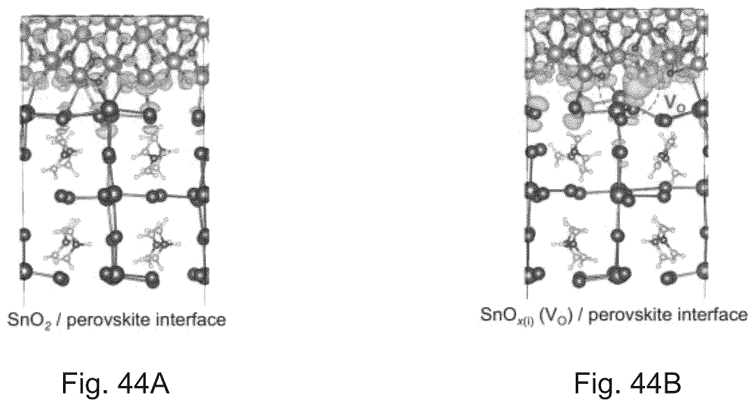

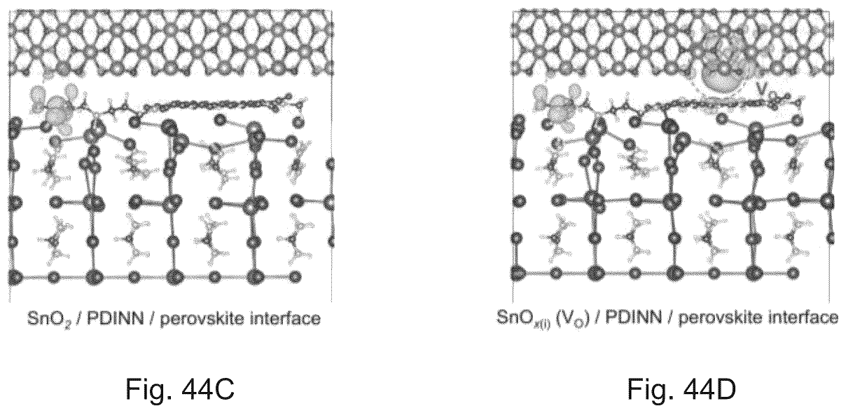

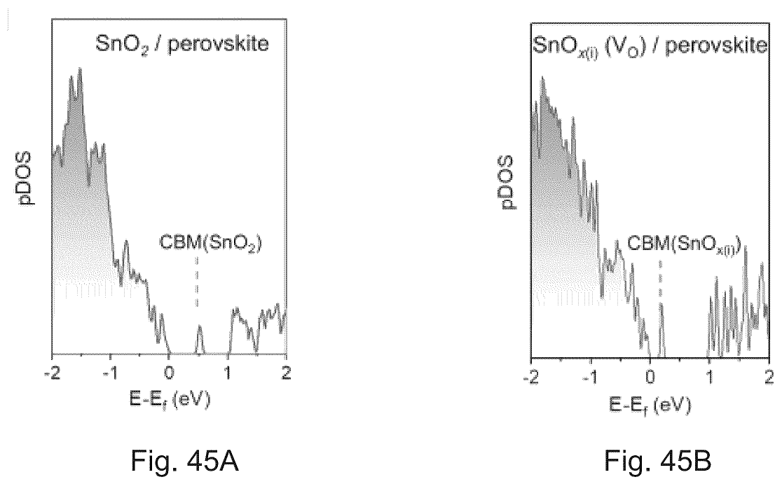

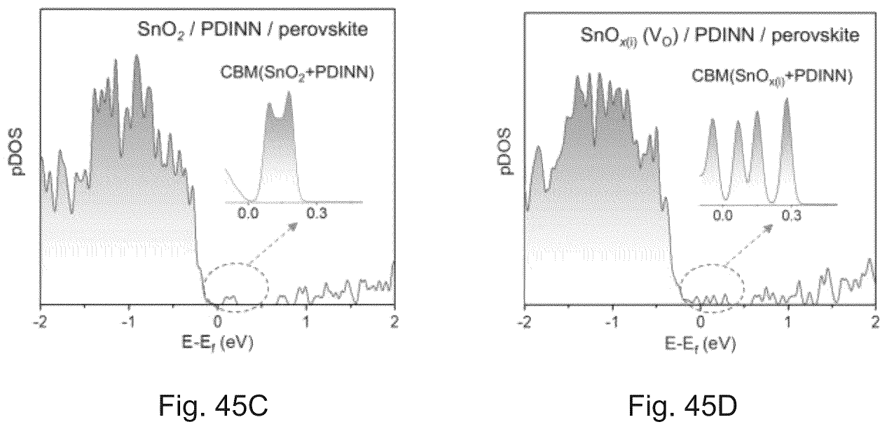

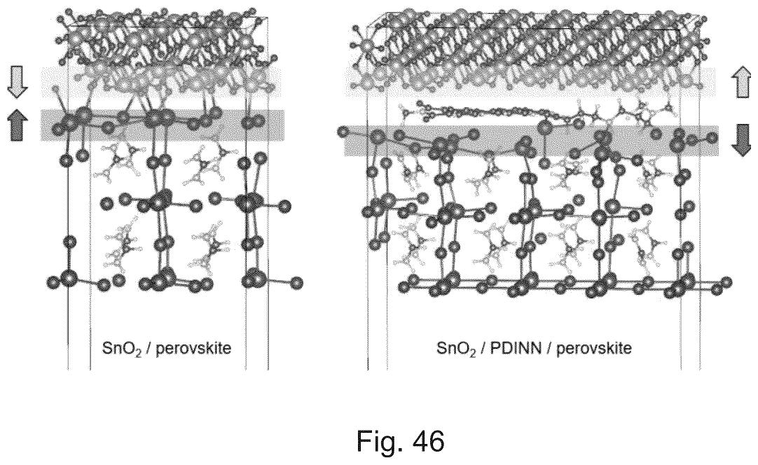

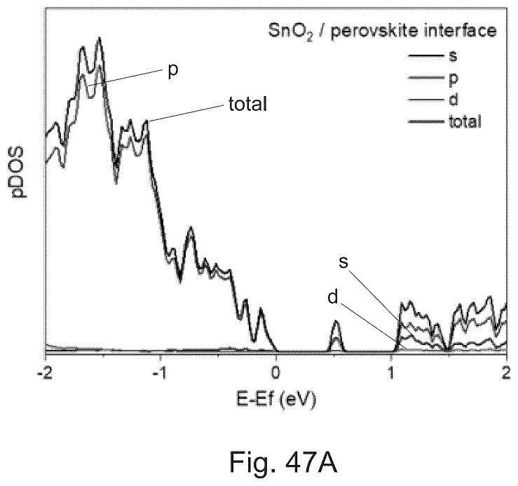

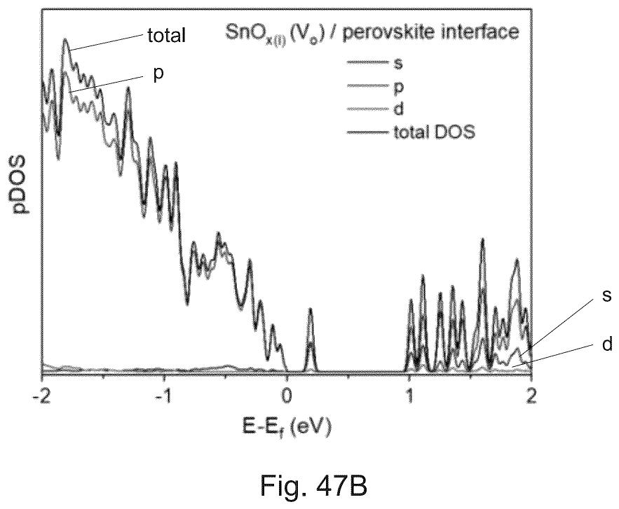

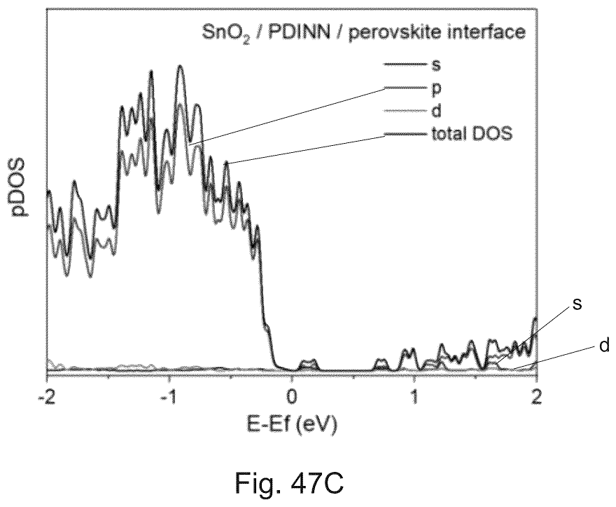

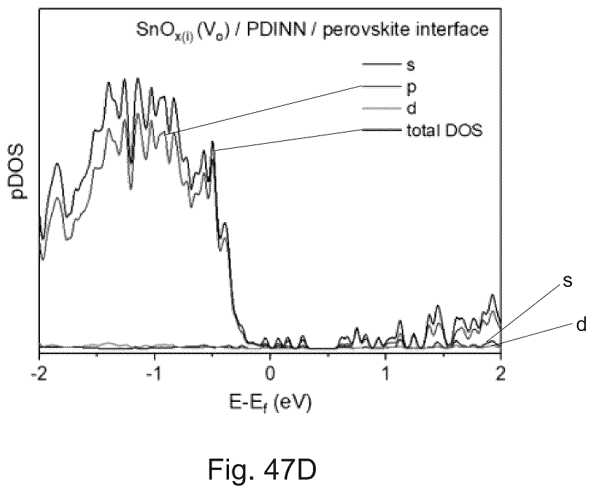

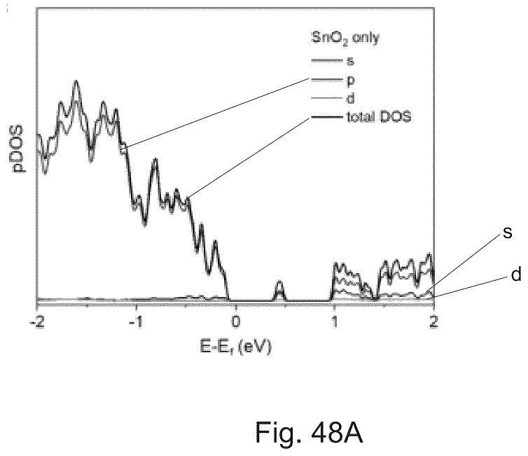

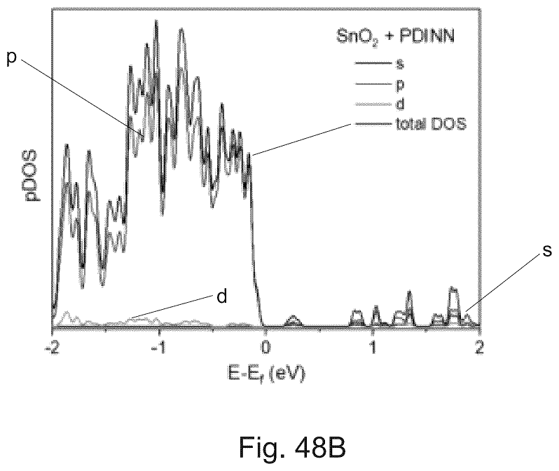

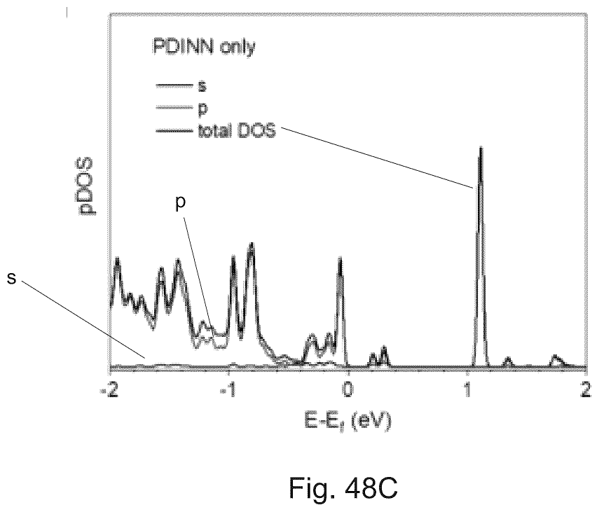

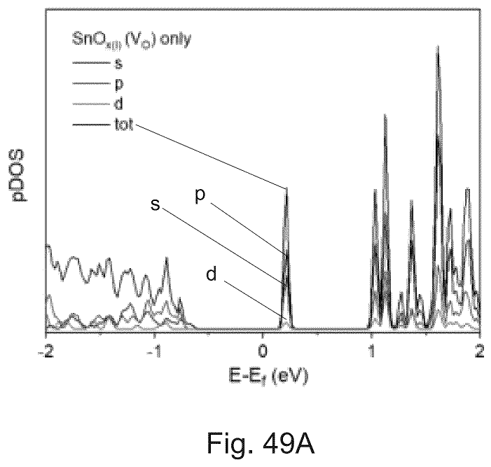

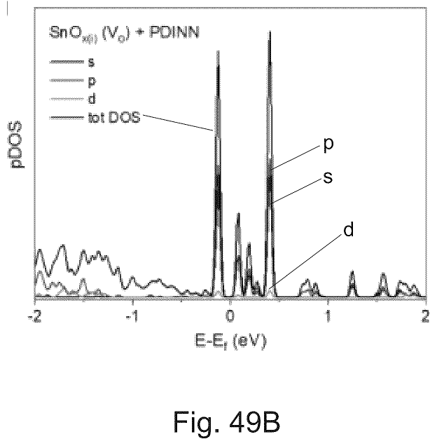

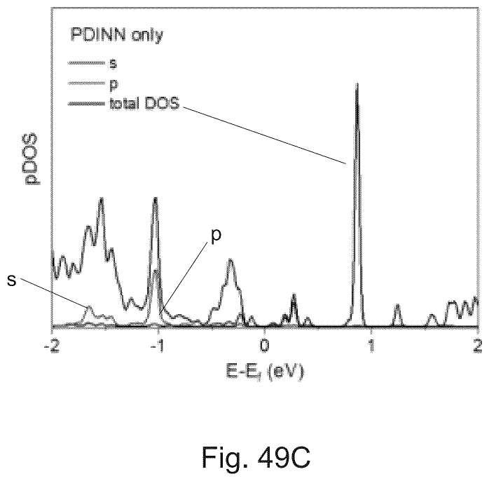

Density functional theory (DFT) calculations were performed on various interfaces involving SnOₓ and perovskite. The calculations were based on the uncharged heterostructures at the level of Perdew-Burke-Ernzerhof (PBE)+spin-orbit coupling (SOC) as implemented in Vienna Ab initio Simulation Package (VASP) 6.4. The results are presented in FIGS. 44A to 44D and FIGS. 45A to 45D, and the detailed data are shown in FIG. 46, FIGS. 47A to 47D, FIGS. 48A to 48C, and FIGS. 49A to 49C, where the charge distribution and partial density of states (pDOS) at the interfaces were compared, both with and without the SnOₓ₍ᵢ₎ (V_{O}) slab and the PDINN buffering layer (where V_{O} refers to the oxygen vacancy). The selection of both pristine SnO₂ and SnOₓ₍ᵢ₎ (V_{O}) with oxygen vacancies is to clarify the effect of the formation of oxygen vacancies (i.e., TDMASn:H₂O ratios from 25:20 to 200:20) on the charge carriers. For the PDINN molecule, which may give very large supercell and strong lattice mismatch, only one amino side chain was kept instead of the two side chains in the original designation—on the other side, a methyl group was adopted instead.

The external-adjacent Sn⁴⁺ and I⁻ usually have a high degree of chemical reactivity, especially when they are directly combined with hetero components at interface. The formation of V_{O} structure (FIG. 44B) can be considered a result of partial reduction of Sn⁴⁺ cations, which exhibits higher spatial charge density distribution at the conducting band (CB) edge compared with the pristine SnO₂ (FIG. 44A). With the strong interaction between the perovskite and SnO₂ layers, the fiercely distorted Pb—I frameworks tend to directly bind with the SnO₂ layer (as shown in FIG. 46). As such, the interfacial perovskite structures bonded with SnO₂ have the same CB edge level as SnO₂ (FIGS. 44A, 45A, 47A, and 48A), removing the band offset between SnO₂ and perovskite layers while weakening the carrier transfer trend between the interface. Additionally, with the V_{O} defects, the strong surface interaction further induces the bandgap downshift between the CB edge of SnOₓ₍ᵢ₎ and the valence band (VB) edge of the perovskite (FIGS. 44B, 45B, 47B, and 49A). Conversely, in the SnO₂/PDINN/perovskite interface, due to the introduction of PDINN molecular layer, the SnO₂ and perovskite tend to move further apart, and the perovskite framework tends to shrink inward, thereby avoiding excessive interaction between the perovskite and SnO₂ surface.

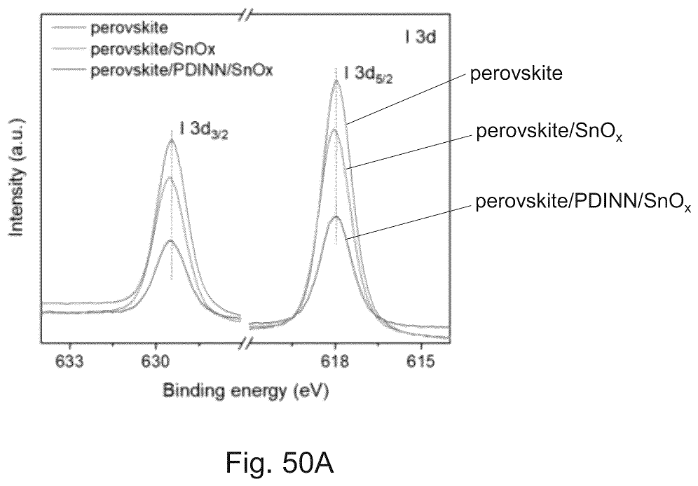

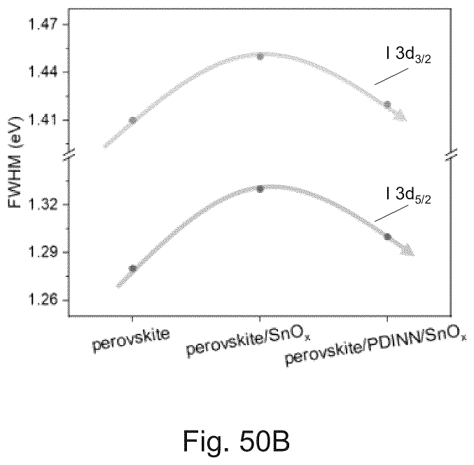

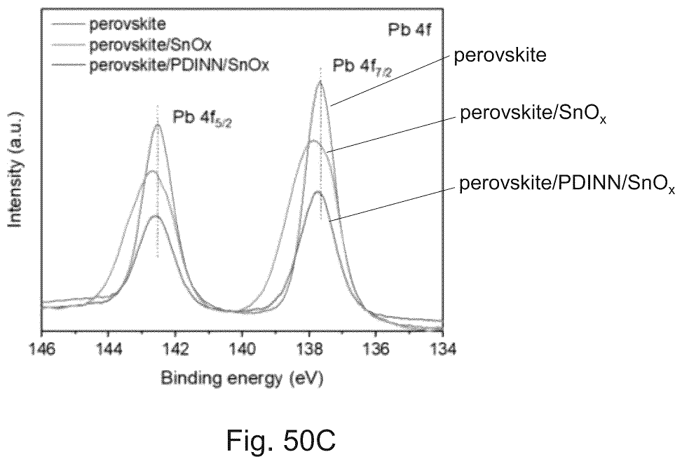

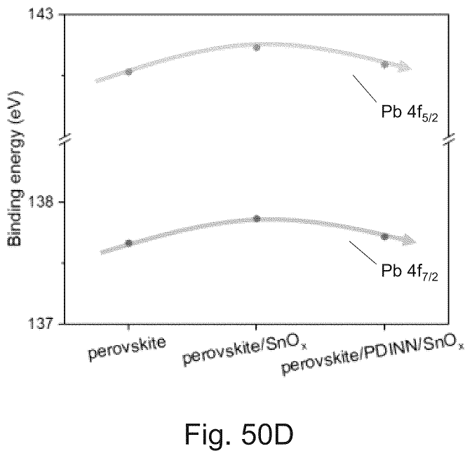

With the introduction of a PDINN molecular buffer layer (as shown in FIG. 44C), it is remarkable that there is no effective spatial charge distribution at the interface within the planar polycyclic aromatic backbone of PDINN in the vacancy-free structure while only partial effective spatial charge distribution arises at the amino side chains. Similarly, the pDOS in FIGS. 45C and 47C, and FIGS. 48A to 48C shows a substantial decrease in the DOS peak at the edge of the CBM, indicating a reduced possibility of carrier distribution in this region. This result suggests that polycyclic aromatic backbones of PDINN do not promote charge transport but rather act as a buffering agent for the ALD process owing to its hydrophobic properties, which can prevent H₂O from directly contacting and reacting with the halide perovskite as demonstrated by XPS analyses in FIGS. 50A to 50D. In particular, compared to pristine perovskite, the I3d peaks in the perovskite/SnOx interface exhibit broadening (FIGS. 50A and 50B), which can be attributed to new chemical species or just increased disorder at the interface. The introduction of PDINN mitigated this chemical change. Furthermore, in FIGS. 50C and 50D, the Pb 4f peaks in the perovskite/SnOₓ samples show significant shifts and broadening, which could be related to the formation of Pb oxides. In contrast, the Pb peaks in the samples with the PDINN interfacial layer show very minimal shifts compared to the pristine perovskite (PVK) surface, which may be due to the electron-withdrawing effect of the aromatic structure of PDINN, leading to a decrease in the electron cloud density on the perovskite surface. These results suggest that PDINN helps prevent interfacial chemical interactions.

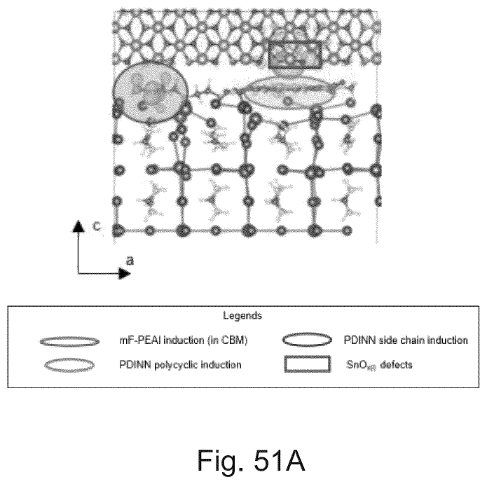

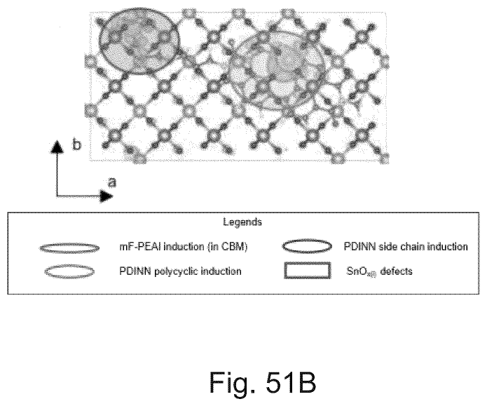

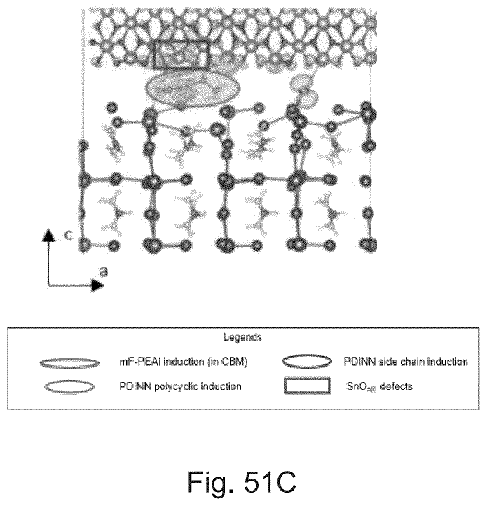

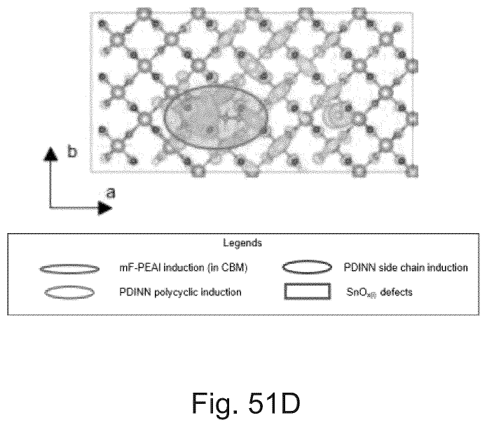

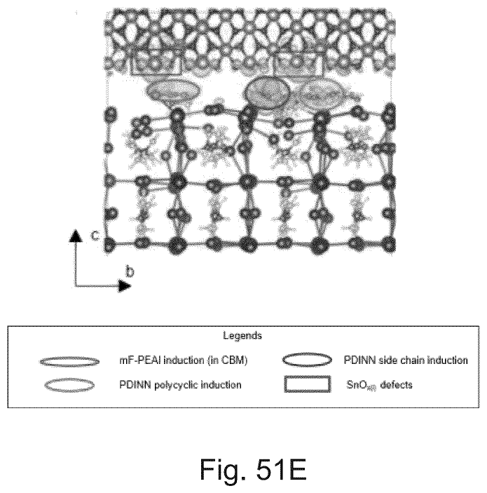

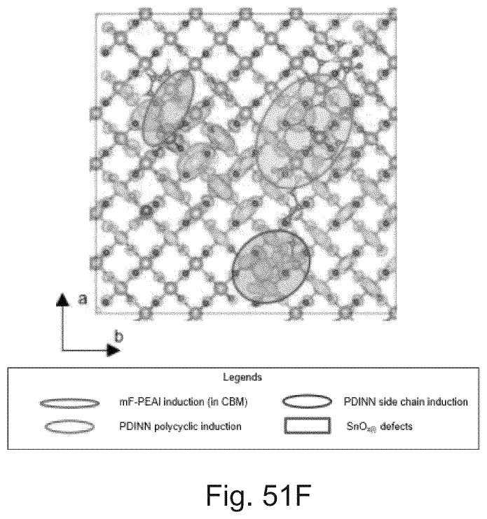

For the V_{O}-existence SnOₓ₍ᵢ₎/PDINN/perovskite interface (FIG. 44D), the presence of oxygen vacancies leads to an appearance of spatial charge density contribution of SnOₓ₍ᵢ₎ adjacent with the polycyclic aromatic part of PDINN. Similarly, the CBM peaks in pDOS (FIGS. 45D and 47D, and FIGS. 49A to 49C) exhibit stronger dispersion than those in the vacancy-free benchmark. Without the direct contact between the SnOₓ₍ᵢ₎ and perovskite layers due to the PDINN layer, the strongly dispersed CBM peak ranges result in the reduction of the negative “cliff-like” band offset compared with the benchmark (FIGS. 44C and 45C), which further reduces the energy loss during carrier extraction and transfer. These first-principles computational results collectively suggest that the appearance of the V_{O} defects increased the carrier transfer, thereby activating the SnOₓ₍ᵢ₎/PDINN/perovskite interface by inducing carrier distribution into the polycyclic aromatic backbone parts of the PDINN layer. It is believed that this conclusion is also applicable to the mF-PEAI and PDINN dual-additive interface because PDINN dominates the charge density contribution owing to its stronger conjugation effect compared with the isolated single aromatic ring of mF-PEAI, as proven in FIGS. 51A to 51F. In particular, it is believed that the primary role of mF-PEAI is to passivate the perovskite surface, forming a molecule passivation layer or 2D perovskite layer to prevent direct interaction with defect-bearing SnOₓ₍ᵢ₎. This layer optimizes interfacial charge transfer and prevents structural mismatch. The strongly conjugated polycyclic aromatic backbones of PDINN can lead to a stronger optimization of the spatial range of carrier transfer contribution from SnOₓ₍ᵢ₎ adjacent to the polycyclic aromatic part of PDINN, especially in the presence of oxygen vacancy defects, due to their stronger conjugation effect compared to the isolated single aromatic ring of mF-PEAI. Without oxygen vacancies, both PDINN and mF-PEAI act as buffering agents and passivation layers during the ALD process.

### Example 11

### Operational Stability

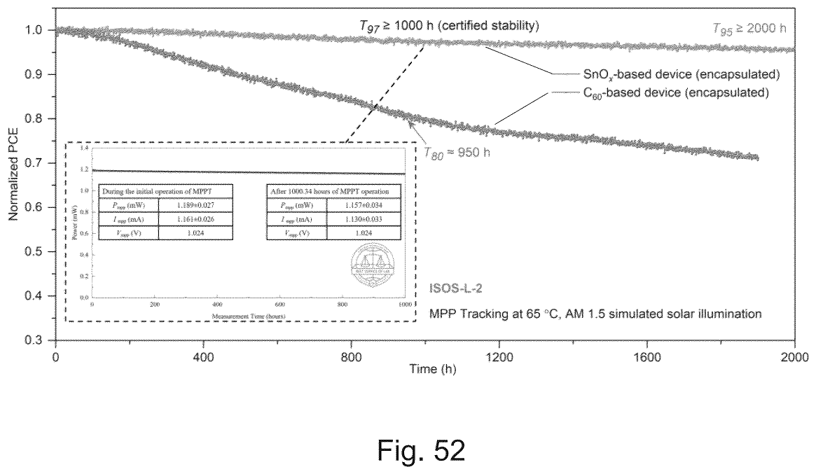

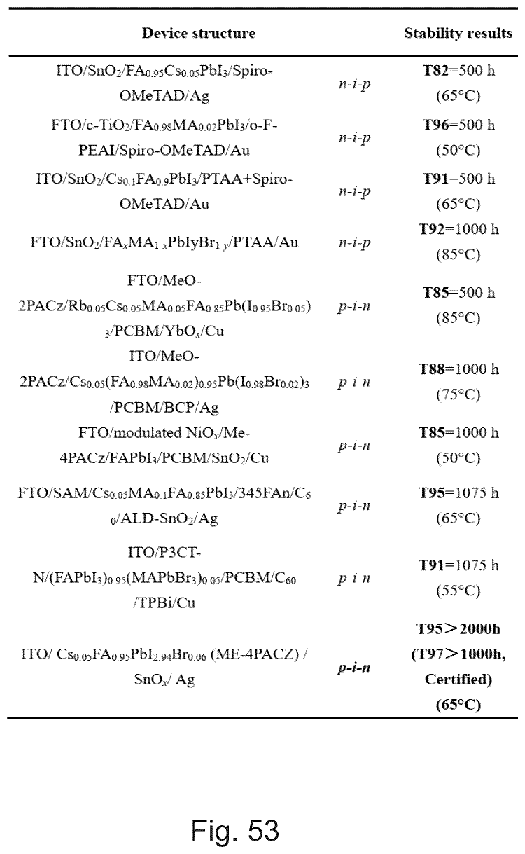

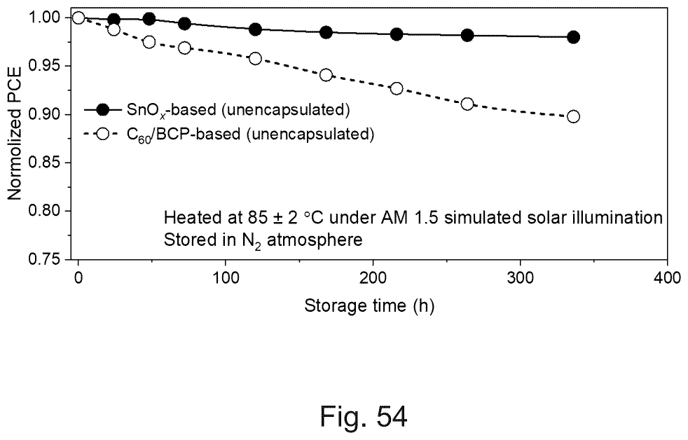

The encapsulated devices were placed in air under continuous 1-sun illumination (following the ISOS-L-2 protocol), and the performance of the devices was monitored at 65° C. under MPPT. The SnOₓ-based devices show excellent stability, maintaining >95% of the initial PCE after 2000 hours of continuous operation (T₉₅≥2000 hours; FIG. 52). Moreover, to obtain certified stability results, the SnOₓ-based devices were sent to a third-party institution for stability testing and demonstrated an exceptional stability of >97% of the initial PCE after 1000 hours of continuous operation (shown in the dashed box in FIG. 52). FIG. 53 details a comparison with some reported stability results. By contrast, the control device maintains a relatively stable performance in the first 100 hours, but the PCE dropped to 80% of the initial value after 950 hours of continuous operation. Similar trends were observed even during accelerated testing at 85° C. and under 1-sun illumination (FIG. 54).

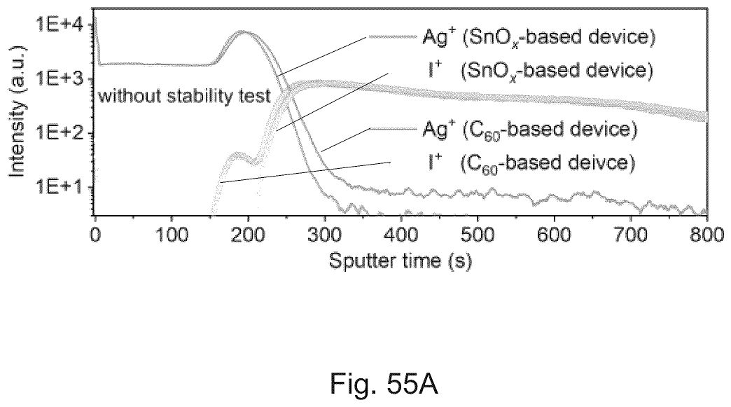

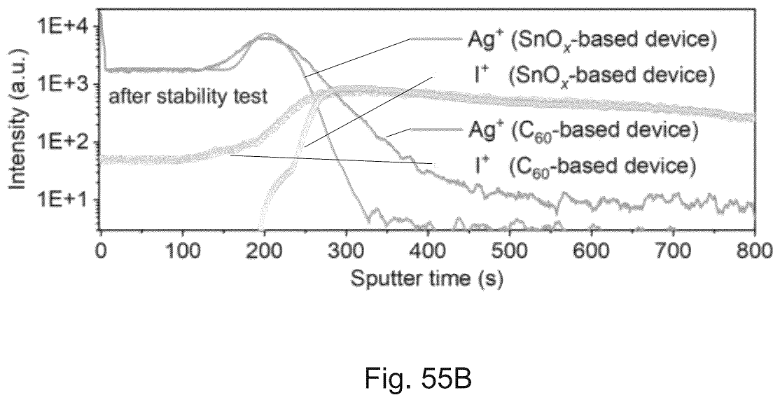

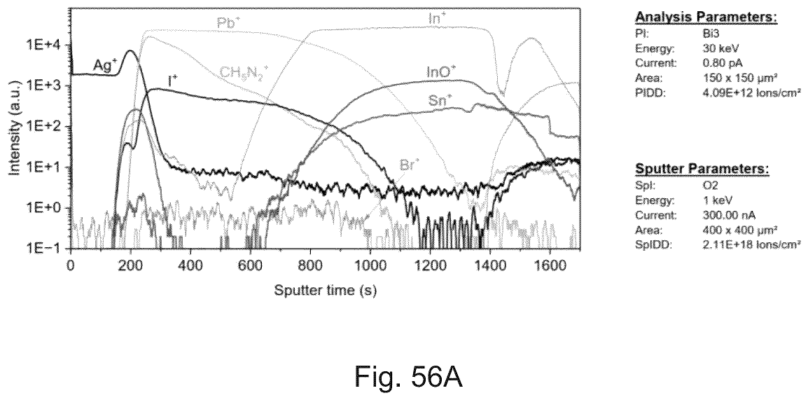

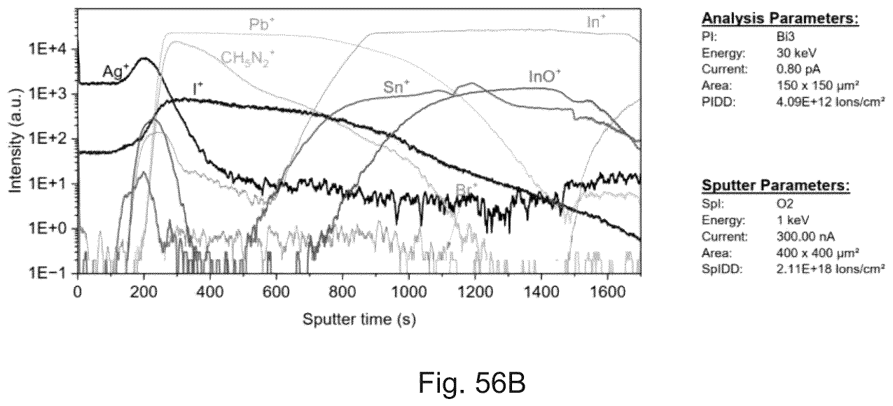

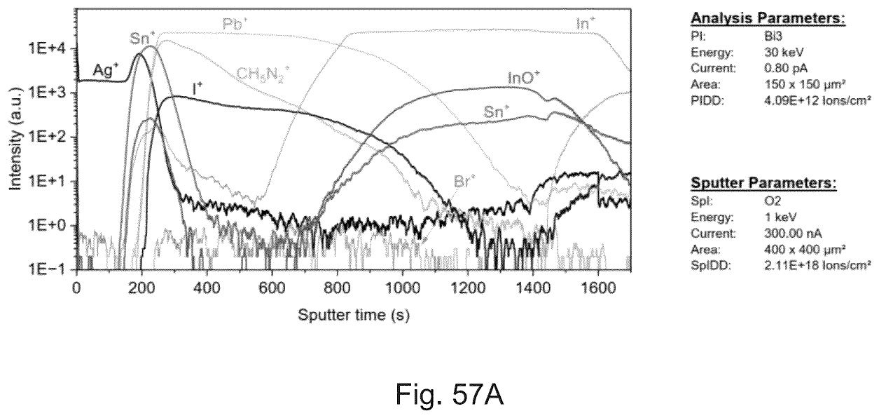

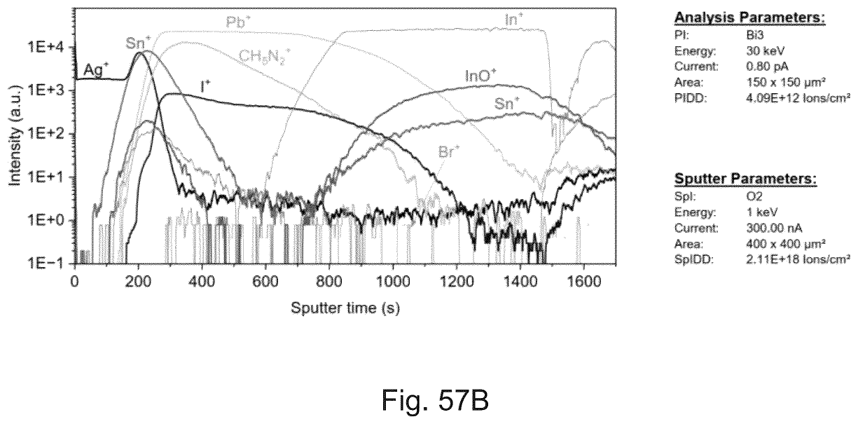

To gain insight into the difference in device operational stability, time-of-flight secondary ion mass spectrometry (TOF-SIMS) tests were performed on the devices before and after the stability tests. In FIGS. 55A and 55B, for the untested control device, a small amount of I⁻ ions penetrated into the C₆₀/BCP layer and contacted the Ag electrode. After the stability test, the diffusion of I⁻ ions intensified, manifested as a large number of I⁻ ions penetrating into the C₆₀/BCP layer and entering the Ag electrode (FIGS. 56A and 56B). For the SnOₓ-based device, under the protection of SnOₓ, I⁻ ions did not show any obvious diffusion in the device before and after aging (FIGS. 57A and 57B). This result indicates that the photothermal stability of the SnOₓ-based device comes from the protection of the SnOₓ layer to the perovskite layer, which makes it difficult to undergo ion diffusion and potential phase separation under the dual influence of high temperature and light.

Further referring to FIGS. 56A and 56B, and FIGS. 57A and 57B, it is observed that there are differences in the distribution signals of Sn⁺ and CH₅N₂⁺ before and after stability test. The possible reasons for this change might be the thermal decomposition of organic cations (such as CH₅N₂⁺) and the chemical reaction of its decomposition products with Sn ions. Under prolonged heating and light exposure for 2000 hours, the organic cations may decompose, which would first change its distribution at the interface, thereby affecting its TOF-SIMS signal. Additionally, the decomposition products of the organic cations may react with Sn⁺, altering the chemical environment or oxidation state of Sn, thus changing the emission efficiency of Sn⁺ secondary ions. This might be the main reason for the 5% efficiency loss observed in the SnOₓ-based device devices after 2000 hours of aging.

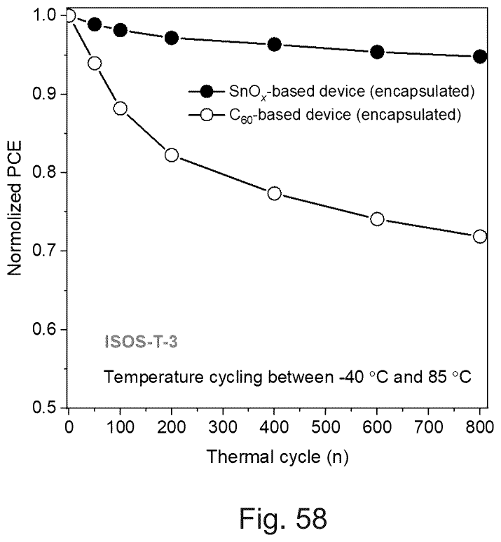

The thermal cycling test, which is a common test used by the International Electrotechnical Commission (IEC) for outdoor conditions and commercialization, was also performed. For the test (−40° C. to 85° C., dark; ISOS-T-3), the SnOₓ-based devices showed an average degradation of ˜4.7% after 800 thermal cycles (as shown in FIG. 58), which exceeded the 200 thermal cycles usually performed by this test protocol. The control devices showed an average efficiency reduction of 28.1% after experiencing the same conditions.

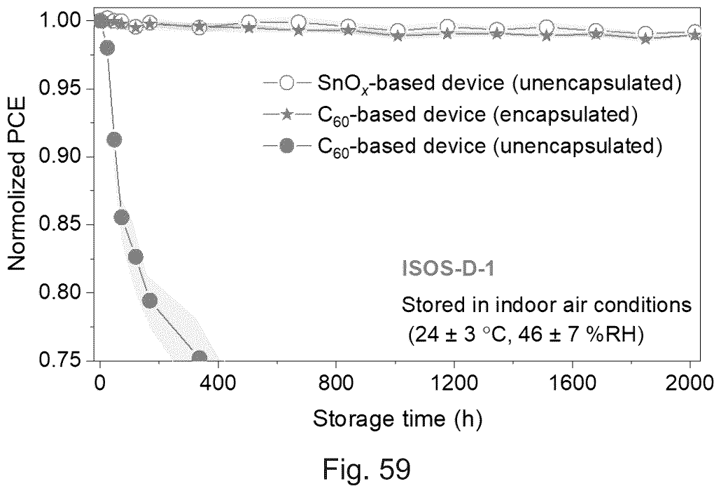

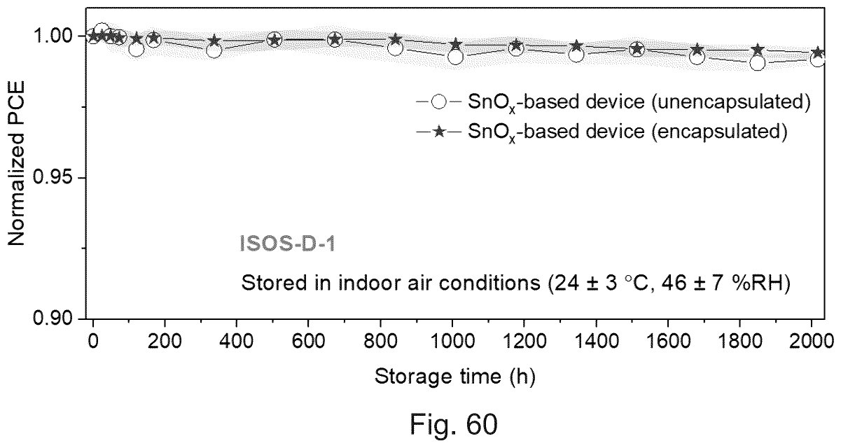

Environmental stabilities were studied on the SnOₓ-based PSCs and conventional inverted PSCs (referred to as control devices) according to multiple sets of standard environmental stability tests, including ISOS-D-1, ISOS-D-3, ISOS-LC-1, and ISOS-O-1. For the ISOS-D-1 stability test shown in FIGS. 59 and 60, after storing for 2000 hours at 23°+4° C. and 46±7% relative humidity (RH), both encapsulated and unencapsulated SnOₓ-based devices showed almost no performance degradation and maintained >99.1% of their initial PCE for 2000 hours. The unencapsulated control device exhibited obvious performance degradation (the PCE dropped to 76.4% of the initial value after 300 hours), whereas the encapsulated control device maintained 98.9% of the initial PCE after storing for 2000 hours. The result indicates that the SnOₓ layer can effectively diminish water and oxygen damage around the perovskite, effectively achieving self-encapsulation of the devices.

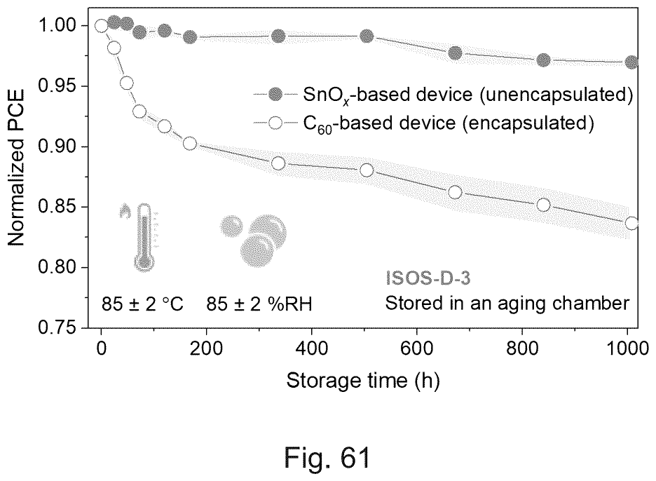

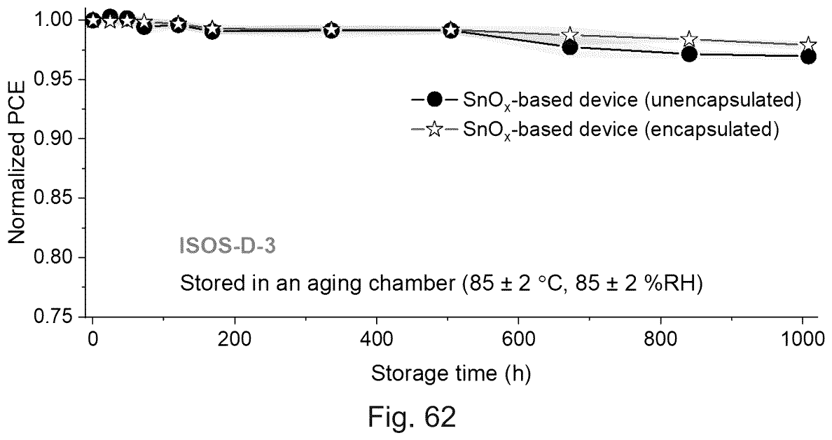

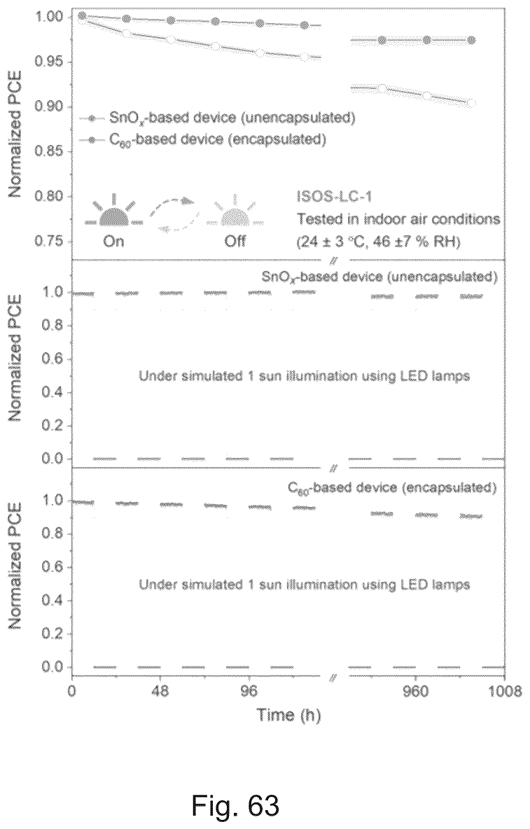

High-temperature and high-humidity storage (ISOS-D-3) at 85° C. and 85% RH were further performed. As shown in FIG. 61, after storing for 1000 hours, the unencapsulated SnOₓ-based device showed a decay of <3.0%. Moreover, encapsulating it did not appreciably improve its stability (the attenuation was reduced from 3.0% to 2.1% in FIG. 62). In comparison, the encapsulated control device showed a decay of >16.4%, indicating that external encapsulation alone was insufficient to resist the invasion of extreme environments. In addition, light on-off stability experiments (ISOS-LC-1) were performed in indoor environments. As shown in FIG. 63, after 42 cycles of 12 hours-12 hours light on-off test at 23° C.±4° C. and 46±7% RH, the unencapsulated SnOₓ-based device showed a PCE decay of 2.5%, whereas the encapsulated control device attenuates by 9.7%.

### Example 12

### Operational Stability

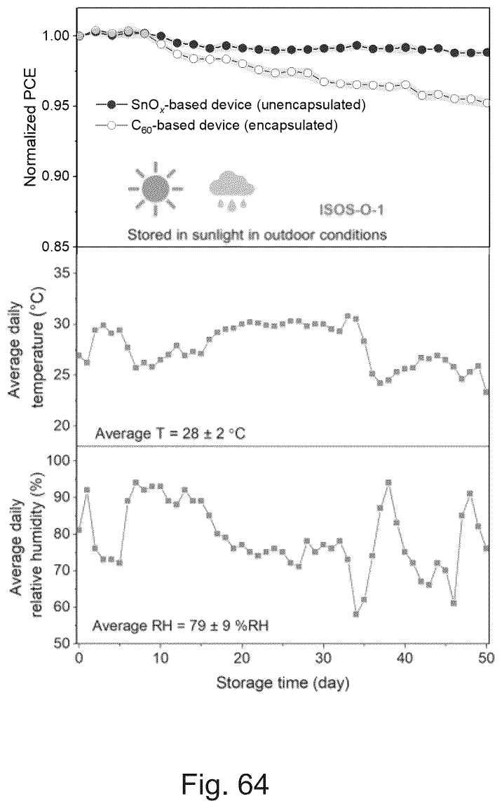

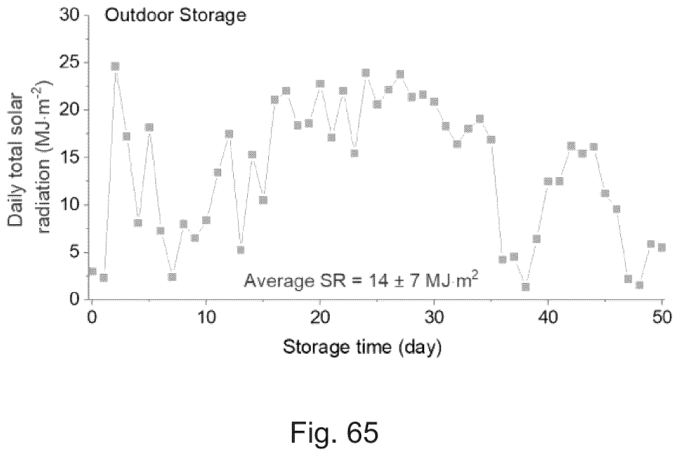

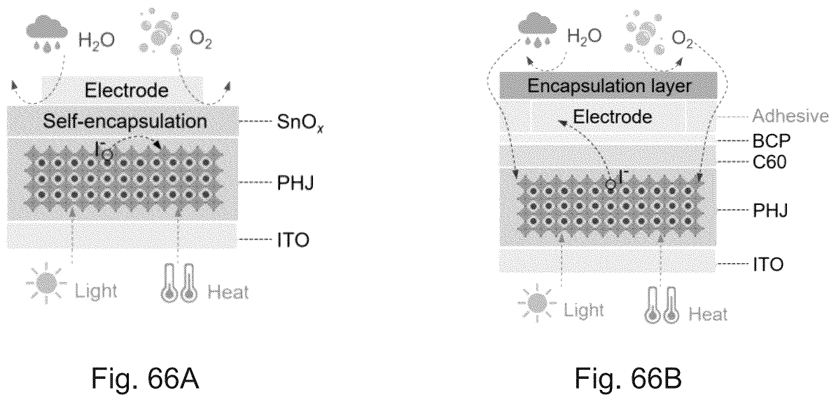

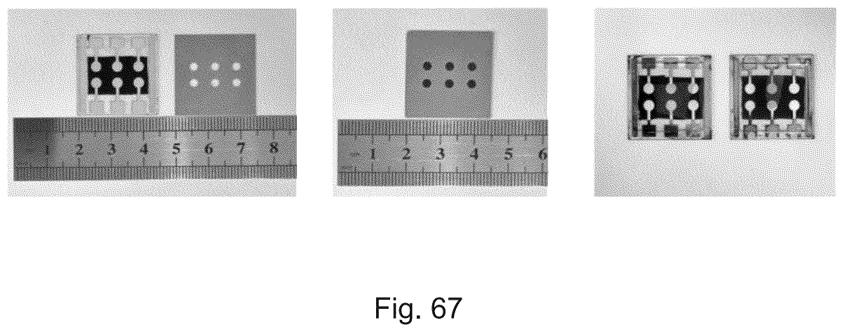

The stability of the devices under outdoor aging conditions (ISOS-O-1) was studied. Because outdoor temperature, relative humidity, and solar radiation intensity all affect the stability of the devices, we tracked the changes of these parameters during the outdoor aging test (FIGS. 64 and 65). After placing in the outdoor environment for 50 days, the unencapsulated SnOₓ-based device shows a decay of only 1.1%, indicating that the self-encapsulated SnOₓ-based device is almost unaffected by the outdoor environment. In comparison, the encapsulated control device shows a relatively large attenuation of 4.8%. The stability results validate the self-encapsulation mechanism of SnOₓ devices. It inhibits external moisture and oxygen penetration, extending device lifetime. It also suppresses ion diffusion from the perovskite layer to the ETL or electrode, maintaining device performance (FIG. 66A). By contrast, control devices with an additional encapsulation layer experience adhesive aging, potentially leading to encapsulation failure (FIG. 66B). The photos of the original device and the encapsulated device are shown in FIG. 67. The encapsulation layer above the electrode fails to prevent ion diffusion that may occur during long-term operation.

The invention has been given by way of example only, and various other modifications of and/or alterations to the described embodiment may be made by persons skilled in the art without departing from the scope of the invention as specified in the appended claims.

1. A perovskite solar cell comprising an electron transport layer between an anode and a cathode, wherein the electron transport layer comprises of first and second portions of tin oxide (SnOₓ).

2. The perovskite solar cell as claimed in claim 1, wherein the first and the second portions of tin oxide (SnOₓ) have different stoichiometry.

3. The perovskite solar cell as claimed in claim 2, wherein the x of SnOₓ in the first and second portions is from about 1.81 to 1.98.

4. The perovskite solar cell as claimed in claim 1, wherein the first portion of tin oxide is arranged on the second portion of tin oxide.

5. The perovskite solar cell as claimed in claim 4, wherein the first and second portions of tin oxide have different thickness.

6. The perovskite solar cell as claimed in claim 5, wherein the thickness of the first and second portions of tin oxide is in the range from about 2 nm to about 50 nm.

7. The perovskite solar cell as claimed in claim 4, wherein the thickness of the first portion of tin oxide is less than that of the second portion.

8. The perovskite solar cell as claimed in claim 4, wherein x of SnOₓ in the first portion is smaller than that of the second portion.

9. The perovskite solar cell as claimed in claim 8, wherein x of SnOₓ in the first portion is about 1.83 and x of SnOₓ in the second portion is about 1.96.

10. The perovskite solar cell as claimed in 7, wherein the thickness of the first portion is about 2 nm to about 10 nm and the thickness of the second portion is about 15 nm to about 50 nm.

11. The perovskite solar cell as claimed in claim 1 further comprising a passivation layer between the electron transport layer and a perovskite active layer.

12. The perovskite solar cell as claimed in claim 11, wherein the passivation layer is arranged under the first portion of the electron transport layer.

13. The perovskite solar cell as claimed in claim 11, wherein the passivation layer comprises phenylethylamine salt and perylene diimide-based compound.

14. The perovskite solar cell as claimed in claim 13, wherein the phenylethylamine salt is selected from the group consisting of PEAI (phenylethylammonium iodide), PEABr (phenylethylammonium bromide), PEACl (phenylethylammonium chloride), mF-PEAI (meta-fluorophenylethylammonium iodide), o-F-PEAI (ortho-fluorophenylethylammonium iodide), CF₃-PEAI (trifluoromethylphenylethylammonium iodide), CH₃O-PEAI (4-methoxyphenylethylammonium iodide), and 4F-PEAI (4-fluorophenylethylammonium iodide), and a combination thereof.

15. The perovskite solar cell as claimed in claim 13, wherein the perylene diimide-based compound is selected from the group consisting of PDINN (N,N′-bis{3-[3-(dimethylamino)propylamino]propyl}perylene-3,4,9,10-tetracarboxylic diimide), PDIN (N,N′-bis{3-[3-(dimethylamino)propyl]amino}perylene-3,4,9,10-tetracarboxylic diimide), PDINO (N,N′-bis{3-[3-(dimethylamino)propyl]amino}perylene-3,4,9,10-tetracarboxylic diimide N-oxide), NDI-N(N,N′-bis{3-[3-(dimethylamino)propyl]amino}naphthalene-1,4,5,8-tetracarboxylic diimide), and a combination thereof.

16. The perovskite solar cell as claimed in claim 13, wherein the phenylethylamine salt and the perylene diimide-based compound have a molar concentration ratio from about 4:1 to about 1:4.

17. The perovskite solar cell as claimed in claim 11, wherein the perovskite active layer comprises a perovskite material having a formula of CsₓMA_{y}FA_{1-x-y}Sn_{z}Pb_{1-z}I₃₋ₘBrₘ, with x being 0-0.5, y being 0-0.5, z being 0-0.5, m being 0-1.5.

18. The perovskite solar cell as claimed in claim 17, wherein the perovskite material is doped with a hole transport material selected from the group consisting of 2PACz, MeO-2PACz (methoxy-2PACz), Me-4PACz (methyl-4PACz), Br-2PACz (bromo-2PACz), CbzBF, 4PADBC, and CbzBT, and a combination thereof.

19. The perovskite solar cell as claimed in claim 1, wherein the anode comprises a conductive material deposited on a transparent substrate, the conductive material is selected from the group consisting of indium tin oxide (ITO), fluorine-doped tin oxide (FTO), niobium-doped titanium dioxide (NTO), aluminum-doped zinc oxide (AZO), gallium-doped zinc oxide (GZO), and a combination thereof.

20. The perovskite solar cell as claimed in claim 1, wherein the cathode comprises a metal selected from the group consisting of gold, silver, copper, aluminium, nickel, and a combination thereof.

21. The perovskite solar cell as claimed in claim 1 is an inverted perovskite solar cell.

22. A method for preparing the perovskite solar cell as claimed in claim 1, comprising the step of depositing an electron transport layer which comprises of first and second portions of tin oxide (SnOₓ) on a surface passivated perovskite active layer.

23. The method as claimed in claim 22, wherein the deposition is conducted by way of atomic layer deposition.

24. The method as claimed in claim 23, wherein the atomic layer deposition comprises the steps of:
(a) contacting the surface passivated perovskite active layer with a pulse of tin in vapor phase in a reaction space followed by contacting the surface passivated perovskite active layer with a pulse of oxygen in vapor phase in the reaction space to form the first portion of tin oxide; and
(b) contacting the first portion of tin oxide with a pulse of tin in vapor phase in the reaction space followed by contacting the first portion of tin oxide with a pulse of oxygen in vapor phase in the reaction space to form the second portion of tin oxide.

25. The method as claimed in claim 24, wherein step (a) is repeated for 10 to 50 cycles.

26. The method as claimed in claim 24, wherein step (b) is repeated for 50 cycles to 500 cycles.

27. The method as claimed in claim 24, wherein the pulse of tin in vapor phase is in contact with the surface passivated perovskite active layer in step (a) for about 120 ms to about 400 ms.

28. The method as claimed in claim 24, wherein the pulse of oxygen in vapor phase is in contact with the surface passivated perovskite active layer in step (a) for about 5 ms to about 20 ms.

29. The method as claimed in claim 24, wherein the pulse of tin in vapor phase is in contact with the first portion of tin oxide in step (b) for about 20 ms to about 100 ms.

30. The method as claimed in claim 24, wherein the pulse of oxygen in vapor phase is in contact with the first portion of tin oxide in step (b) for about 10 ms to about 40 ms.

31. The method as claimed in claim 24, wherein each of step (a) and step (b) further includes the step of purging the reaction space.

32. The method as claimed in claim 31, wherein the step of purging the reaction space comprises of performing purging after application of the pulse of tin in vapor phase and before application of the pulse of oxygen in vapor phase; and performing purging after the application of the pulse of oxygen in vapor phase.

33. The method as claimed in claim 25, wherein purging the reaction space in step (a) is different between a first cycle and a second cycle.

34. The method as claimed in claim 33, wherein the number of cycles is divided into a first set, a second set and a third set, the time for purging the reaction space increases from the first set to the third set.

35. The method as claimed in claim 31, wherein time for purging the reaction space after application of the pulse of tin in vapor phase in step (a) is about 20 seconds.

36. The method as claimed in claim 24, wherein the atomic layer deposition is conducted at a temperature from about 85° C. to about 125° C.

37. The method as claimed in claim 24, wherein the tin in vapor phase comprises tetrakis(dimethylamino)tin and the oxygen in vapor phase comprises water.

38. The method as claimed in claim 31 further comprising the steps of:
(i) providing an anode including a conductive material;
(ii) depositing a perovskite active layer on the anode;
(iii) subjecting the perovskite active layer to surface passivation treatment; and
(iv) providing the cathode on the electron transport layer by way of thermal evaporation.

39. The method as claimed in claim 38, wherein step (ii) includes the steps of:
providing a precursor solution comprising CsI, FAI, MAI, MABr, PbBr₂, PbI₂, and SnI₂ according to the formula of CsₓMA_{y}FA_{1-x-y}Sn_{z}Pb_{1-z}I₃₋ₘBrₘ, with x being 0-0.5, y being 0-0.5, z being 0-0.5, m being 0-1.5, and a hole transport material;
spin-coating the precursor solution on the anode; and
annealing the spin-coated anode to form the perovskite active layer thereon.

40. The method as claimed in claim 39, wherein the hole transport material has a concentration of about 0.15 mg/mL to about 1.2 mg/mL in the precursor solution.

41. The method as claimed in claim 38, wherein step (iii) comprising the steps of:
spin-coating a surface passivating solution including a phenylethylamine salt and a perylene diimide-based compound on the perovskite active layer obtained in step (ii); and
annealing the spin-coated perovskite active layer to form a passivation layer thereon.

42. The method as claimed in claim 41, wherein the phenylethylamine salt has an initial concentration of about 0.5 mg/mL to about 4 mg/mL, and the perylene diimide-based compound has an initial concentration of about 0.5 mg/mL to about 8 mg/mL.

43. The method as claimed in claim 42, wherein the phenylethylamine salt and the perylene diimide-based compound have a volume ratio of 1:1.
